(19) United States
(12) Patent Application Publication
(10) Pub. No.: US 2022/0119687 A1
(43) Pub. Date: Apr. 21, 2022

(54) LAMINATE, LIQUID CRYSTAL DISPLAY DEVICE, AND ORGANIC ELECTROLUMINESCENT DISPLAY DEVICE

(71) Applicant: FUJIFILM Corporation, Tokyo (JP)

(72) Inventors: Naoya SHIBATA, Kanagawa (JP); Takashi KATOU, Kanagawa (JP)

(73) Assignee: FUJIFILM Corporation, Tokyo (JP)

(21) Appl. No.: 17/563,625

(22) Filed: Dec. 28, 2021

Related U.S. Application Data
(63) Continuation of application No. PCT/JP2020/024962, filed on Jun. 25, 2020.

(30) Foreign Application Priority Data
Jul. 9, 2019 (JP) 2019-127944
Sep. 27, 2019 (JP) 2019-176684

(51) Int. Cl. C09J 7/38; G02B 5/30; C09J 133/10; C09J 11/06; C09K 19/04

(52) U.S. Cl. CPC C09J 7/385; G02B 5/3016; C09J 133/10; C09K 2019/0448; C09K 19/04; C09J 2203/326; C09J 2203/318; C09J 11/06

(57) ABSTRACT

Provided is a laminate which is suppressed in crystal precipitation in a pressure sensitive adhesive layer containing an ultraviolet absorber and which has an optically anisotropic layer exhibiting excellent light resistance; a liquid crystal display device; and an organic EL display device. The laminate includes a pressure sensitive adhesive layer and an optically anisotropic layer, in which the pressure sensitive adhesive layer contains a (meth)acrylic pressure sensitive adhesive and a compound represented by Formula (I), and the optically anisotropic layer is a layer formed of a composition containing a polymerizable liquid crystal compound exhibiting reverse wavelength dispersibility.

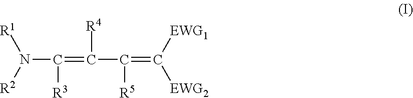

### CROSS-REFERENCE TO RELATED APPLICATIONS

This application is a Continuation of PCT International Application No. PCT/JP2020/024962 filed on Jun. 25, 2020, which claims priority under 35 U.S.C. § 119(a) to Japanese Patent Application No. 2019-127944 filed on Jul. 9, 2019 and Japanese Patent Application No. 2019-176684 filed on Sep. 27, 2019. Each of the above applications is hereby expressly incorporated by reference, in its entirety, into the present application.

### BACKGROUND OF THE INVENTION

### 1. Field of the Invention

The present invention relates to a laminate, a liquid crystal display device, and an organic electroluminescent display device.

### 2. Description of the Related Art

A variety of members including a display element such as an organic electroluminescent (hereinafter, referred to simply as “EL”) display element or a liquid crystal cell, and an optical film such as a polarizing plate are used in a display device (flat panel display: FPD) such as an organic EL display device or a liquid crystal display device. Since an organic EL compound, a liquid crystal compound, or the like used for these members is an organic substance, deterioration thereof due to ultraviolet rays (UV) tends to be a problem. In particular, a liquid crystal compound exhibiting reverse wavelength dispersibility is inferior in light resistance and therefore tends to be easily decomposed by ultraviolet rays.

For example, JP2006-308936A discloses a polarizing plate to which an ultraviolet absorber having an excellent ability to absorb ultraviolet rays in a wavelength range of 370 nm or shorter, but having a small absorption of visible light of 400 nm or longer is added so as not to affect the display.

In addition, with the progress of thinning of display devices in recent years, there are cases where a thinned protective film is used and cases where an optical film having a polarizing plate without a protective film is used.

In such a protective film and such an optical film, it is necessary to formulate an ultraviolet absorber, which has been conventionally added to the protective film, into another member. For example, it is conceivable to apply an ultraviolet absorber to a pressure sensitive adhesive layer.

On the other hand, JP2017-119700A discloses that a light selective absorption compound having a merocyanine structure (corresponding to an ultraviolet absorber) has a high absorbance for light in a short wavelength range of 370 to 410 nm, exhibits an excellent affinity in a composition for forming a pressure sensitive adhesive layer, and is difficult to bleed out.

### SUMMARY OF THE INVENTION

It has conventionally been considered that various members constituting a display device are deteriorated by ultraviolet rays in a wavelength range of 370 nm or shorter, but it has become clear that the performance deterioration progresses even with light in a wavelength range of 370 to 400 nm, in addition to ultraviolet rays having a wavelength of 370 nm or shorter. Therefore, an optical film such as a polarizing plate containing an optically anisotropic layer is required to have absorption characteristics particularly for light in the vicinity of 370 to 400 nm, in addition to ultraviolet rays having a wavelength of 370 nm or shorter.

On the other hand, according to the studies by the present inventors, the polarizing plate disclosed in JP2006-308936A had low absorption characteristics for light in the vicinity of 370 to 400 nm, and was not always satisfactory in the light resistance of a member (particularly, an optically anisotropic layer).

Further, as described above, it is required to formulate the ultraviolet absorber at a high concentration in the pressure sensitive adhesive layer, in response to the demand for thinning of a display device.

On the other hand, according to the studies by the present inventors, in a case where a light selective absorption compound (ultraviolet absorber) having high absorbance for light in a short wavelength range of 370 to 410 nm described in JP2017-119700A is formulated at a high concentration in the pressure sensitive adhesive layer, this may result in crystal precipitation over time of the ultraviolet absorber. In a case where crystals are precipitated, haze will occur, making it difficult to apply to display devices. In addition, in a case where the amount of the ultraviolet absorber used is reduced in order to suppress crystal precipitation, the ultraviolet absorption characteristics themselves are deteriorated. Therefore, in a case where the pressure sensitive adhesive layer and the optically anisotropic layer are arranged together, and the optically anisotropic layer is irradiated with ultraviolet rays through the pressure sensitive adhesive layer, the light resistance of the optically anisotropic layer deteriorates.

In view of the above circumstances, an object of the present invention is to provide a laminate which is suppressed in crystal precipitation in a pressure sensitive adhesive layer containing an ultraviolet absorber and which has an optically anisotropic layer exhibiting excellent light resistance.

Another object of the present invention is to provide a liquid crystal display device and an organic EL display device.

As a result of extensive studies, the present inventors have found that the foregoing objects can be achieved by the following configurations.

(1) A laminate having a pressure sensitive adhesive layer and an optically anisotropic layer,

in which the pressure sensitive adhesive layer contains a (meth)acrylic pressure sensitive adhesive and a compound represented by Formula (I) which will be described later, and

the optically anisotropic layer is a layer formed of a composition containing a polymerizable liquid crystal compound exhibiting reverse wavelength dispersibility.

(2) The laminate according to (1), in which the polymerizable liquid crystal compound includes a polymerizable liquid crystal compound having a partial structure represented by Formula (II) which will be described later.

(3) The laminate according to (1) or (2), in which a content of the compound represented by Formula (I) is 2.5% to 30% by mass with respect to a total mass of the (meth)acrylic pressure sensitive adhesive.

(4) The laminate according to any one of (1) to (3), in which a content of the compound represented by Formula (I) is 5.3% to 30% by mass with respect to a total mass of the (meth)acrylic pressure sensitive adhesive.

(5) The laminate according to any one of (1) to (4), in which the (meth)acrylic pressure sensitive adhesive is obtained by reacting a copolymer having a repeating unit derived from a (meth)acrylic acid ester monomer represented by Formula (A-1) which will be described later and a repeating unit derived from an unsaturated monomer having a polar functional group with a crosslinking agent having a functional group capable of reacting with the polar functional group,

a content of the repeating unit derived from the (meth)acrylic acid ester monomer represented by Formula (A-1) is 50% to 99.9% by mass with respect to all the repeating units of the copolymer,

a content of the repeating unit derived from the unsaturated monomer having a polar functional group is 0.1% to 50% by mass with respect to all the repeating units of the copolymer,

a weight-average molecular weight of the copolymer is 500,000 to 2,000,000, and

a content of the crosslinking agent with respect to 100 parts by mass of the copolymer is 0.01 to 10 parts by mass.

(6) The laminate according to any one of (1) to (5), in which a thickness of the pressure sensitive adhesive layer is less than 20 μm.

(7) The laminate according to any one of (1) to (6), in which a thickness of the pressure sensitive adhesive layer is less than 10 μm.

(8) The laminate according to any one of (1) to (7), in which a thickness of the pressure sensitive adhesive layer is 5 μm or less.

(9) The laminate according to any one of (1) to (8), further having a polarizer layer.

(10) The laminate according to (9), in which the laminate has the polarizer layer, the pressure sensitive adhesive layer, and the optically anisotropic layer in this order.

(11) The laminate according to (9) or (10), in which the polarizer layer is a polarizer layer having a dichroic coloring agent.

(12) The laminate according to any one of (9) to (11), in which the laminate has a first pressure sensitive adhesive layer, the polarizer layer, a second pressure sensitive adhesive layer, and the optically anisotropic layer in this order, and

at least one of the first pressure sensitive adhesive layer or the second pressure sensitive adhesive layer is the pressure sensitive adhesive layer.

(13) A display device having the laminate according to any one of (1) to (12).

(14) An organic electroluminescent display device having the laminate according to any one of (1) to (12).

According to an aspect of the present invention, it is possible to provide a laminate which is suppressed in crystal precipitation in a pressure sensitive adhesive layer containing an ultraviolet absorber and which has an optically anisotropic layer exhibiting excellent light resistance.

In addition, according to another aspect of the present invention, it is possible to provide a liquid crystal display device and an organic EL display device.

### BRIEF DESCRIPTION OF THE DRAWINGS

FIG. 1 is a schematic cross-sectional view showing an example of a laminate of the present invention.

FIG. 2 is a schematic cross-sectional view showing an example of a laminate of the present invention.

FIG. 3 is a schematic cross-sectional view showing an example of a laminate of the present invention.

### DESCRIPTION OF THE PREFERRED EMBODIMENTS

Hereinafter, the present invention will be described in more detail.

The description of configuration requirements described below may be made based on representative embodiments of the present invention, but the present invention is not limited to such embodiments.

In the present specification, the numerical range expressed by using “to” means a range including numerical values described before and after “to” as a lower limit value and an upper limit value, respectively.

In addition, in the present specification, parallel and orthogonal do not mean parallel and orthogonal in a strict sense, but mean a range of ±5° from parallel or orthogonal, respectively.

In addition, in the present specification, “(meth)acrylic” is a generic term for acrylic and methacrylic.

In addition, in the present specification, the liquid crystal composition and the liquid crystal compound also include, as a concept, those which no longer exhibit liquid crystallinity due to curing or the like.

A feature point of the present invention is that a predetermined ultraviolet absorber (a compound represented by Formula (I) which will be described later) is used.

According to the studies by the present inventors, the compound represented by Formula (I) which will be described later (hereinafter, also simply referred to as “specific compound”) has high compatibility with a (meth)acrylic pressure sensitive adhesive, and even in a case where the specific compound is mixed with the (meth)acrylic pressure sensitive adhesive at a high concentration, crystal precipitation is unlikely to occur. In addition, since the specific compound is particularly excellent in absorption characteristics in a wavelength range of 370 to 400 nm, deterioration of the optically anisotropic layer is unlikely to occur in a case where the optically anisotropic layer is irradiated with ultraviolet rays through the pressure sensitive adhesive layer, and the optically anisotropic layer is also excellent in light resistance. In particular, a polymerizable liquid crystal compound having a partial structure represented by Formula (II) which will be described later corresponds to a liquid crystal compound exhibiting so-called reverse wavelength dispersibility, and is inferior in light resistance to ordinary liquid crystal compounds. In the present invention, the light resistance of the optically anisotropic layer is improved since the pressure sensitive adhesive layer absorbs a predetermined ultraviolet ray to suppress the irradiation of the optically anisotropic layer with ultraviolet rays, by using the pressure sensitive adhesive layer containing a specific compound together with the optically anisotropic layer, even in a case where such a liquid crystal compound having inferior light resistance and exhibiting reverse wavelength dispersibility is used.

As described above, the present invention is characterized in that crystals are unlikely to precipitate even in a case where a specific compound is present in a high concentration in the pressure sensitive adhesive layer.

The details of this reason have not been clarified yet, but the present inventors speculate that it is due to the following reasons.

It is considered that the pressure sensitive adhesive layer is often designed to have an elastic modulus of several MPa or less due to the restriction of ensuring pressure sensitive adhesiveness through pressurization and is therefore susceptible to mass transfer within the layer, so that the added compounds are likely to aggregate with time even in a case where the affinity of the pressure sensitive adhesive layer with a binder is increased. Therefore, it is considered that, in a case where the added compound is present in a high concentration, the probability of the added compounds approaching each other increases and therefore crystallization is further promoted.

A structural feature point of the specific compound is that an aryl sulfone group and an ester group are present in the vicinity. It is presumed that, since the aryl moiety of the aryl sulfone group is twisted with respect to a conjugated plane, that part causes a steric hindrance to suppress crystallization. In particular, this effect is effective for crystallization over time in a binder, and crystallization is significantly suppressed particularly in a binder which is a (meth)acrylic pressure sensitive adhesive. Further, this effect becomes significant in a case where the specific compound is present in a high concentration in the (meth)acrylic pressure sensitive adhesive. As a result, it is considered that crystal growth is suppressed even in a case where the specific compounds approach each other over time in the (meth)acrylic pressure sensitive adhesive.

The laminate according to the embodiment of the present invention is a laminate having a pressure sensitive adhesive layer and an optically anisotropic layer, in which the pressure sensitive adhesive layer contains a (meth)acrylic pressure sensitive adhesive and a specific compound, and the optically anisotropic layer is a layer formed of a composition containing a polymerizable liquid crystal compound having a partial structure represented by Formula (II) which will be described later.

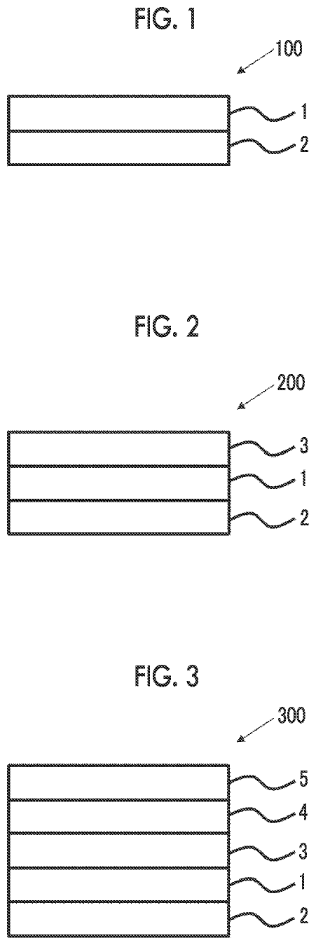

FIG. 1, FIG. 2, and FIG. 3 show a schematic cross-sectional view showing an example of the laminate according to the embodiment of the present invention.

Here, a laminate 100 shown in FIG. 1 is a laminate with a layer configuration having a pressure sensitive adhesive layer 1 and an optically anisotropic layer 2 in this order.

In addition, a laminate 200 shown in FIG. 2 is a laminate with a layer configuration having a polarizer layer 3, the pressure sensitive adhesive layer 1, and the optically anisotropic layer 2 in this order.

In addition, a laminate 300 shown in FIG. 3 is a laminate with a layer configuration having a surface protective layer 5, a pressure sensitive adhesive layer 4, the polarizer layer 3, the pressure sensitive adhesive layer 1, and the optically anisotropic layer 2 in this order. That is, the laminate may take an aspect having a first pressure sensitive adhesive layer, a polarizer layer, a second pressure sensitive adhesive layer, and an optically anisotropic layer in this order.

In FIGS. 1 to 3, the pressure sensitive adhesive layers 1 and 4 correspond to a pressure sensitive adhesive layer containing the compound represented by Formula (I) which will be described later. The above is an aspect in which the pressure sensitive adhesive layers 1 and 4 are both pressure sensitive adhesive layers containing a specific compound, but the present invention is not limited to such an aspect, and one of the pressure sensitive adhesive layers 1 and 4 may be a pressure sensitive adhesive layer containing a specific compound.

The laminate according to the embodiment of the present invention includes at least a pressure sensitive adhesive layer and an optically anisotropic layer.

Hereinafter, each member included in the laminate will be described in detail.

<Pressure Sensitive Adhesive Layer>

The pressure sensitive adhesive layer used in the present invention contains a (meth)acrylic pressure sensitive adhesive and a compound represented by Formula (I) (light selective absorption compound).

In the pressure sensitive adhesive layer, crystals are unlikely to precipitate even in a case where a specific compound is present at a high concentration. As a result, high absorption of UV light can be realized even in a case where the pressure sensitive adhesive layer is thinned, and deterioration of the optical performance of the optically anisotropic layer due to UV light irradiation can be suppressed.

The pressure sensitive adhesive layer is usually arranged on the side irradiated with light (particularly, ultraviolet light) rather than the optically anisotropic layer, which suppresses the irradiation of the optically anisotropic layer with ultraviolet rays.

(Compound Represented by Formula (I) (Specific Compound))

The specific compound is a compound having an ability to absorb ultraviolet rays, which is capable of absorbing blue light in a wavelength range of 370 to 400 nm.

Incorporation of the specific compound makes it possible for the pressure sensitive adhesive layer to block blue light in a wavelength range of at least 370 to 400 nm. In addition, the pressure sensitive adhesive layer is less likely to haze, has excellent light resistance, is less likely to be yellowish, and has sufficient suitability as a pressure sensitive adhesive layer.

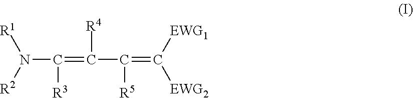

In Formula (I), one of EWG₁ and EWG₂ represents COOR⁶, the other of EWG₁ and EWG₂ represents SO₂R⁷, R⁶ represents an alkyl group, an aryl group, or a heteroaryl group, and R⁷ represents an aryl group or a heteroaryl group. R¹ and R² each independently represent an alkyl group, an aryl group, or a heteroaryl group. R³, R⁴, and R⁵ each independently represent a hydrogen atom or a substituent.

First, a “substituent” (that is, a substituent represented by R³, R⁴, and R in Formula (I)) will be described in detail.

The type of “substituent” in the present invention is not particularly limited, and examples thereof include known substituents. Examples of the substituent include the groups exemplified in Substituent Group shown below.

Substituent Group: a halogen atom, an alkyl group, an alkenyl group, an alkynyl group, an aryl group, a heterocyclic group, a cyano group, a hydroxyl group, a nitro group, a carboxyl group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group, an acylamino group, an aminocarbonylamino group, an alkoxycarbonylamino group, an aryloxycarbonylamino group, a sulfamoylamino group, an alkylsulfonylamino group, an arylsulfonylamino group, a mercapto group, an alkylthio group, an arylthio group, a heterocyclic thio group, a sulfamoyl group, a sulfo group, an alkylsulfinyl group, an arylsulfinyl group, an alkylsulfonyl group, an arylsulfonyl group, an acyl group, an aryloxycarbonyl group, an alkoxycarbonyl group, a carbamoyl group, an arylazo group, a heterocyclic azo group, an imide group, a phosphino group, a phosphinyl group, a phosphinyloxy group, a phosphinylamino group, a silyl group, and a group obtained by combining these groups.

The above-mentioned substituent may be further substituted with a substituent.

The substituent is preferably an alkyl group, an alkenyl group, an alkynyl group, an aryl group, or an aralkyl group.

The alkyl group may be an unsubstituted alkyl group or a substituted alkyl group.

The “substituted alkyl group” means an alkyl group in which the hydrogen atom of the alkyl group is substituted with the other substituent. Similarly, a substituted alkenyl group, a substituted alkynyl group, and a substituted aralkyl group, which will be described later, also mean that the hydrogen atom of each group is substituted with the other substituent. Examples of the “other substituent” include the groups exemplified in the Substituent Group.

The alkyl group may have a linear, branched, or cyclic molecular structure.

The number of carbon atoms in the alkyl group is preferably 1 to 20, more preferably 1 to 18, still more preferably 1 to 10, and particularly preferably 1 to 5. It should be noted that the number of carbon atoms does not include the number of carbon atoms in a substituent in a case where the alkyl group further has such a substituent.

The alkenyl group may be an unsubstituted alkenyl group or a substituted alkenyl group.

The alkenyl group may have a linear, branched, or cyclic molecular structure.

The number of carbon atoms in the alkenyl group is preferably 2 to 20 and more preferably 2 to 18. It should be noted that the number of carbon atoms does not include the number of carbon atoms in a substituent in a case where the alkenyl group further has such a substituent.

The alkynyl group may be an unsubstituted alkynyl group or a substituted alkynyl group.

The alkynyl group may have a linear, branched, or cyclic molecular structure.

The number of carbon atoms in the alkynyl group is preferably 2 to 20 and more preferably 2 to 18. It should be noted that the number of carbon atoms does not include the number of carbon atoms in a substituent in a case where the alkynyl group further has such a substituent.

The aryl group may be an unsubstituted aryl group or a substituted aryl group.

The number of carbon atoms in the aryl group is preferably 6 to 20 and more preferably 6 to 10. It should be noted that the number of carbon atoms does not include the number of carbon atoms in a substituent in a case where the aryl group further has such a substituent.

The aralkyl group may be an unsubstituted aralkyl group or a substituted aralkyl group.

The alkyl moiety of the aralkyl group is the same as the alkyl group which is the above-mentioned substituent.

The aryl moiety of the aralkyl group may be condensed with an aliphatic ring, another aromatic ring, or a heterocyclic ring.

The aryl moiety of the aralkyl group is the same as the aryl group which is the above-mentioned substituent.

The substituent (that is, the other substituent) contained in the substituted alkyl group, the substituted alkenyl group, the substituted alkynyl group, the substituted aryl group, and the substituted aralkyl group can be selected from the Substituent Group.

Reference can be made to the description in JP2007-262165A for details of examples of the substituent contained in the substituted alkyl group, the substituted alkenyl group, the substituted alkynyl group, and the substituted aralkyl group.

One of EWG₁ and EWG₂ represents COOR⁶, the other of EWG₁ and EWG₂ represents SO₂R⁷, R⁶ represents an alkyl group, an aryl group, or a heteroaryl group, and R¹ represents an aryl group or a heteroaryl group.

The alkyl group represented by R⁶ may be an unsubstituted alkyl group or a substituted alkyl group. The substituent contained in the substituted alkyl group can be selected from, for example, the Substituent Group. Suitable aspects of the alkyl group represented by R⁶ include suitable aspects of the alkyl group represented by R¹ and R², which will be described later.

The aryl group represented by R⁶ and R⁷ may be an unsubstituted aryl group or a substituted aryl group. The substituent contained in the substituted aryl group can be selected from, for example, the Substituent Group. Suitable aspects of the aryl group represented by R⁶ and R⁷ include suitable aspects of the aryl group represented by R¹ and R², which will be described later.

The heteroaryl group represented by R⁶ and R⁷ may be an unsubstituted heteroaryl group or a substituted heteroaryl group. The substituent contained in the substituted heteroaryl group can be selected from, for example, the Substituent Group. Suitable aspects of the heteroaryl group represented by R⁶ and R⁷ include suitable aspects of the heteroaryl group represented by R¹ and R², which will be described later.

A preferred aspect of EWG₁ and EWG₂ in Formula (I) may be, for example, an aspect in which R⁶ represents an alkyl group and R⁷ represents an aryl group, from the viewpoint of obtaining at least one of a point where the crystal precipitation in the pressure sensitive adhesive layer is further suppressed or a point where the optically anisotropic layer is more excellent in light resistance (hereinafter, also simply referred to as “the point where the effect of the present invention is more excellent”).

According to such an aspect, the shielding property of blue light in a wavelength range of 370 to 400 nm is significantly excellent, and an increase in haze over time is further suppressed.

It is preferable that, in Formula (I), EWG₁ represents SO₂R⁷ and EWG₂ represents COOR⁶.

R¹ and R² in Formula (I) each independently represent an alkyl group, an aryl group, or a heteroaryl group, preferably an alkyl group or an aryl group, and more preferably an alkyl group.

The alkyl group represented by R¹ and R² may be an unsubstituted alkyl group or a substituted alkyl group. In addition, the alkyl group represented by R¹ and R² may have a linear, branched, or cyclic molecular structure.

The number of carbon atoms in the alkyl group represented by R¹ and R² is not particularly limited, and is preferably 1 to 20, more preferably 1 to 15, and still more preferably 1 to 10.

The substituent contained in the substituted alkyl group can be selected from, for example, the Substituent Group.

The aryl group represented by R¹ and R² may be an unsubstituted aryl group or a substituted aryl group. In addition, the aryl group represented by R¹ and R² may be condensed with an aliphatic ring, another aromatic ring, or a heterocyclic ring.

The number of carbon atoms in the aryl group represented by R¹ and R² is not particularly limited, and is preferably 6 to 30, more preferably 6 to 20, and still more preferably 6 to 15.

The aryl group represented by R¹ and R² is preferably a phenyl group or a naphthyl group, and more preferably a phenyl group.

The aryl moiety of the substituted aryl group is the same as the above-mentioned aryl group.

The substituent contained in the substituted aryl group can be selected from, for example, the Substituent Group.

The heteroaryl group represented by R¹ and R² may be an unsubstituted heteroaryl group or a substituted heteroaryl group. In addition, the heteroaryl group represented by R¹ and R² may be condensed with an aliphatic ring, an aromatic ring, or another heterocyclic ring.

The heteroaryl group represented by R¹ and R² preferably contains a 5- or 6-membered unsaturated heterocyclic ring.

Examples of the heteroatom in the heteroaryl group represented by R¹ and R² include B, N, O, S, Se, and Te, among which N, O, or S is preferable.

In the heteroaryl group represented by R¹ and R², it is preferable that the carbon atom has a free valence (monovalent) (that is, the heteroaryl group is bonded at the carbon atom).

The number of carbon atoms in the heteroaryl group represented by R¹ and R² is not particularly limited, and is preferably 1 to 40, more preferably 1 to 30, and still more preferably 1 to 20.

Examples of the unsaturated heterocyclic ring contained in the heteroaryl group include imidazole, thiazole, benzothiazole, benzoxazole, benzotriazole, benzoselenazole, pyridine, pyrimidine, and quinoline.

The heteroaryl moiety of the substituted heteroaryl group is the same as the above-mentioned heteroaryl group.

The substituent contained in the substituted heteroaryl group can be selected from, for example, the Substituent Group.

From the viewpoint of the light resistance of the compound itself, it is preferable that R¹ and R² are not bonded to each other to form a ring structure.

R³, R⁴, and R⁵ in Formula (I) each independently represent a hydrogen atom or a substituent, preferably a hydrogen atom, an alkyl group having 1 to 10 carbon atoms, or an aryl group having 6 to 10 carbon atoms, and more preferably a hydrogen atom or an alkyl group having 1 to 5 carbon atoms, and all of R³, R⁴, and R⁵ still more preferably represent a hydrogen atom.

Specific examples of the specific compound include Exemplary Compounds (I-1) to (I-7). However, the compound represented by Formula (I) is not limited to these exemplary compounds (Log P values and maximal absorption wavelengths are described under the structures).

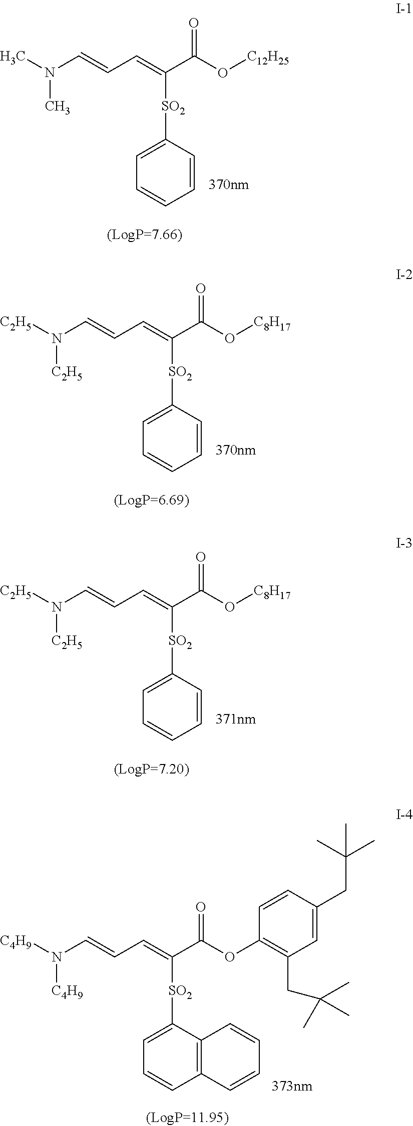

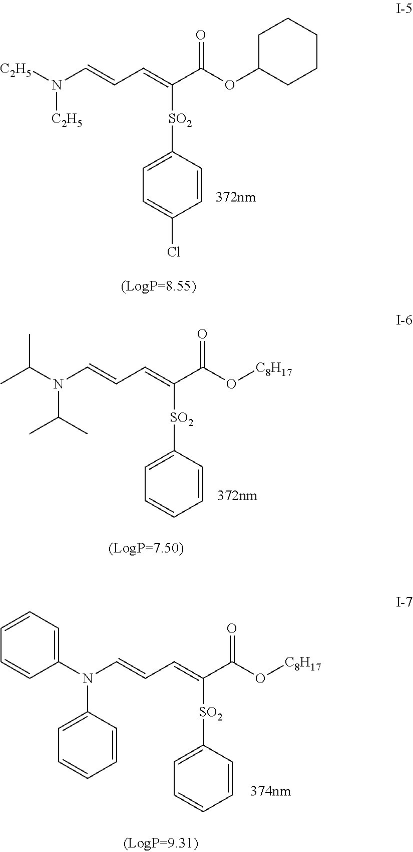

The maximum absorption wavelength of the specific compound is preferably located in a range of 365 to 380 nm. In a case where the maximum absorption wavelength of the specific compound is within the above range, the yellow coloring of the pressure sensitive adhesive layer can be suppressed even in a case where the specific compound is added at a high concentration.

The pressure sensitive adhesive layer may contain only one type of the specific compound, or may contain two or more types of the specific compounds.

The pressure sensitive adhesive layer may contain an ultraviolet absorber other than the specific compound as long as the effect of the present invention is not impaired.

Examples of the other ultraviolet absorber include organic ultraviolet absorbers such as an oxybenzophenone-based ultraviolet absorber, a benzotriazole-based ultraviolet absorber, a salicylate ester-based ultraviolet absorber, a benzophenone-based ultraviolet absorber, a cyanoacrylate-based ultraviolet absorber, and a triazine-based ultraviolet absorber. More specific examples of the other ultraviolet absorber include 5-chloro-2-(3,5-di-sec-butyl-2-hydroxyphenyl)-2H-benzotriazole, (2-2H-benzotriazol-2-yl)-6-(linear and side chain dodecyl)-4-methylphenol, 2-hydroxy-4-benzyloxybenzophenone, and 2,4-benzyloxybenzophenone.

A commercially available product may be used as the other ultraviolet absorber. Examples of a triazine-based ultraviolet absorber include “KEMISORB 102” (trade name, manufactured by Chemipro Kasei Kaisha, Ltd.), “ADEKA STAB LA 46” and “ADEKA STAB LA F70” (both trade names, manufactured by ADEKA Corporation), and “TINUVIN 109”, “TINUVIN 171”, “TINUVIN 234”, “TINUVIN 326”, “TINUVIN 327”, “TINUVIN 328”, “TINUVIN 928”, “TINUVIN 400”, “TINUVIN 460”, “TINUVIN 405”, and “TINUVIN 477” (all trade name, manufactured by BASF Japan Ltd.). Examples of a benzotriazole-based ultraviolet absorber include “ADEKA STAB LA 31” and “ADEKA STAB LA 36” (both trade names, manufactured by ADEKA Corporation), “SUMISORB 200”, “SUMISORB 250”, “SUMISORB 300”, “SUMISORB 340”, and “SUMISORB 350” (all trade names, manufactured by Sumika Chemtex Co., Ltd.), “KEMISORB 74”, “KEMISORB 79”, and “KEMISORB 279” (all trade names, manufactured by Chemipro Kasei Kaisha, Ltd.), and “TINUVIN 99-2”, “TINUVIN 900”, and “TINUVIN 928” (all trade names, manufactured by BASF SE).

The content of the specific compound in the pressure sensitive adhesive layer is not particularly limited, and is preferably 1.0% by mass or more, more preferably 2.5% by mass or more, and still more preferably 5.3% by mass or more with respect to the total mass of the (meth)acrylic pressure sensitive adhesive, from the viewpoint that sufficient absorption characteristics can be obtained even with a thin pressure sensitive adhesive layer. In addition, the upper limit of the content of the specific compound is preferably 30% by mass or less, more preferably 15% by mass or less, and still more preferably 10% by mass or less with respect to the total mass of the (meth)acrylic pressure sensitive adhesive, from the viewpoint that the pressure sensitive adhesive properties of the pressure sensitive adhesive layer are more excellent.

In a case where the content of the specific compound in the pressure sensitive adhesive layer is within the above range, the compatibility with the (meth)acrylic pressure sensitive adhesive is favorable, and therefore the specific compound is less likely to precipitate and haze is less likely to occur. Since the specific compound has a high molar absorption coefficient in a wavelength range of 370 to 400 nm, blue light in this wavelength range can be satisfactorily blocked even in a case where the content of the specific compound in the pressure sensitive adhesive layer is within the above range.

In one suitable embodiment of the present invention, the specific compound may be contained in another member such as a transparent resin film used as a support, in addition to the pressure sensitive adhesive layer.

((Meth)Acrylic Pressure Sensitive Adhesive)

The pressure sensitive adhesive layer contains a (meth)acrylic pressure sensitive adhesive. The (meth)acrylic pressure sensitive adhesive means a pressure sensitive adhesive using a (meth)acrylic polymer as a base polymer. The (meth)acrylic polymer refers to a polymer whose main component is a repeating unit derived from a monomer having at least one (meth)acryloyl group in one molecule (hereinafter, this may be referred to as “(meth)acrylic monomer”). The “main component” means that the content of the repeating unit derived from the (meth)acrylic monomer is 50% by mass or more with respect to all the repeating units constituting the (meth)acrylic polymer.

A known (meth)acrylic pressure sensitive adhesive can be used as the (meth)acrylic pressure sensitive adhesive.

From the viewpoint that the effect of the present invention is more excellent, the (meth)acrylic pressure sensitive adhesive is preferably a compound (pressure sensitive adhesive) obtained by reacting a copolymer having a repeating unit derived from a (meth)acrylic acid ester monomer represented by Formula (A-1) and a repeating unit derived from an unsaturated monomer having a polar functional group with a crosslinking agent.

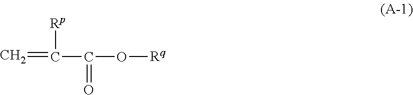

In Formula (A-1), R^{p} is a hydrogen atom or a methyl group.

R^{q} represents an alkyl group having 1 to 20 carbon atoms or an aralkyl group having 1 to 20 carbon atoms, among which an alkyl group having 1 to 10 carbon atoms or an aralkyl group having 1 to 10 carbon atoms is preferable.

The hydrogen atom constituting the alkyl group and the aralkyl group may be substituted with —O—(C₂H₄O)ₙ—R^{r}.

n represents an integer of 0 to 4 and preferably an integer of 0 to 3.

R^{r} represents an alkyl group having 1 to 12 carbon atoms or an aryl group having 1 to 12 carbon atoms, among which an alkyl group having 1 to 5 carbon atoms or an aryl group having 1 to 10 carbon atoms is preferable.

Examples of the (meth)acrylic acid ester monomer (A-1) represented by Formula (A-1) (hereinafter, also referred to as “monomer (A-1)”) include linear acrylic acid alkyl esters such as methyl acrylate, ethyl acrylate, propyl acrylate, n-butyl acrylate, n-octyl acrylate, and lauryl acrylate; branched acrylic acid alkyl esters such as isobutyl acrylate, 2-ethylhexyl acrylate, and isooctyl acrylate; linear methacrylic acid alkyl esters such as methyl methacrylate, ethyl methacrylate, propyl methacrylate, n-butyl methacrylate, n-octyl methacrylate, and lauryl methacrylate; branched methacrylic acid alkyl esters such as isobutyl methacrylate, 2-ethylhexyl methacrylate, and isooctyl methacrylate; acrylic acid esters having an aromatic group such as acrylic acid phenyl ester and acrylic acid benzyl ester; and methacrylic acid esters having an aromatic group, such as acrylic acid phenoxy ester, methacrylic acid phenyl ester, and methacrylic acid benzyl ester.

The monomer (A-1) may be used alone or in combination of two or more thereof. Above all, n-butyl acrylate is preferable from the viewpoint of developing pressure sensitive adhesiveness.

In the unsaturated monomer (A-2) having a polar functional group (hereinafter, also referred to as “monomer (A-2)”), the type of the polar functional group is not particularly limited, and examples thereof include a free carboxyl group, a hydroxyl group, an amino group, and a heterocyclic group including an epoxy ring.

The monomer (A-2) is preferably a (meth)acrylic acid-based compound having a polar functional group. Examples of the monomer (A-2) include unsaturated monomers having a free carboxyl group such as acrylic acid, methacrylic acid, and β-carboxyethyl acrylate; unsaturated monomers having a hydroxyl group such as 2-hydroxyethyl (meth)acrylate, 2-hydroxypropyl (meth)acrylate, 2- or 3-chloro-2-hydroxypropyl (meth)acrylate, and diethylene glycol mono(meth)acrylate; unsaturated monomers having a heterocyclic group such as acryloylmorpholin, vinyl caprolactam, N-vinyl-2-pyrrolidone, tetrahydrofurfuryl (meth)acrylate, caprolactone-modified tetrahydrofurfuryl acrylate, 3,4-epoxycyclohexylmethyl (meth)acrylate, glycidyl (meth)acrylate, and 2,5-dihydrofuran; and unsaturated monomers having an amino group different from that of a heterocyclic ring such as N,N-dimethylaminoethyl (meth)acrylate.

The monomer (A-2) may be used alone or in combination of two or more thereof.

The monomer (A-2) is preferably an unsaturated monomer having a hydroxyl group, from the viewpoint of increasing the adhesive force of the pressure sensitive adhesive layer to further improve the durability.

In a copolymer having a repeating unit derived from the monomer (A-1) and a repeating unit derived from the monomer (A-2) (hereinafter, also referred to as “copolymer (A)”), the content of the repeating unit derived from the monomer (A-1) is preferably 50% to 99.9% by mass and more preferably 70% to 99.9% by mass with respect to all the repeating units of the copolymer (A).

In addition, the content of the repeating unit derived from the monomer (A-2) is preferably 0.1% to 50% by mass and more preferably 0.1% to 30% by mass with respect to all the repeating units of the copolymer (A).

In a case where the content of each of the repeating unit derived from the monomer (A-1) and the repeating unit derived from the monomer (A-2) is within the above range, the effect of the present invention is more excellent and a pressure sensitive adhesive layer having more excellent workability can be obtained.

Further, the copolymer (A) may contain a repeating unit derived from another monomer (hereinafter, also referred to as “monomer (A-3)”) other than the repeating unit derived from the monomer (A-1) and the repeating unit derived from the monomer (A-2).

Examples of the other monomer include a (meth)acrylic acid ester having an alicyclic structure in a molecule thereof, a styrene-based monomer, a vinyl-based monomer, a monomer having a plurality of (meth)acryloyl groups in a molecule thereof, and a (meth)acrylamide derivative.

The alicyclic structure is a cycloparaffin structure having usually 5 or more carbon atoms, preferably about 5 to 7 carbon atoms.

Examples of the acrylic acid ester having an alicyclic structure include isobornyl acrylate, cyclohexyl acrylate, dicyclopentanyl acrylate, cyclododecyl acrylate, methyl cyclohexyl acrylate, trimethylcyclohexyl acrylate, tert-butyl cyclohexyl acrylate, cyclohexyl α-ethoxyacrylate, and cyclohexylphenyl acrylate.

Examples of the methacrylic acid ester having an alicyclic structure include isobornyl methacrylate, cyclohexyl methacrylate, dicyclopentanyl methacrylate, cyclododecyl methacrylate, methylcyclohexyl methacrylate, trimethylcyclohexyl methacrylate, tert-butylcyclohexyl methacrylate, and cyclohexylphenyl methacrylate.

Examples of the styrene-based monomer include styrene; alkyl styrenes such as methyl styrene, dimethyl styrene, trimethyl styrene, ethyl styrene, diethyl styrene, triethyl styrene, propyl styrene, butyl styrene, hexyl styrene, heptyl styrene, and octyl styrene; halogenated styrenes such as fluorostyrene, chlorostyrene, bromostyrene, dibromostyrene, and iodostyrene; nitrostyrene; acetylstyrene; methoxystyrene; and divinylbenzene.

Examples of the vinyl-based monomer include fatty acid vinyl esters such as vinyl acetate, vinyl propionate, vinyl butyrate, vinyl 2-ethylhexanate, and vinyl laurate; vinyl halides such as vinyl chloride and vinyl bromide; vinylidene halides such as vinylidene chloride; nitrogen-containing aromatic vinyls such as vinylpyridine, vinylpyrrolidone, and vinylcarbazole; conjugated diene monomers such as butadiene, isoprene, and chloroprene; acrylonitrile; and methacrylonitrile.

Examples of the monomer having a plurality of (meth)acryloyl groups in a molecule thereof include monomers having two (meth)acryloyl groups in a molecule thereof, such as 1,4-butanediol di(meth)acrylate, 1,6-hexanediol di(meth)acrylate, 1,9-nonanediol di(meth)acrylate, ethylene glycol di(meth)acrylate, diethylene glycol di(meth)acrylate, tetraethylene glycol di(meth)acrylate, and tripropylene glycol di(meth)acrylate; and monomers having three (meth)acryloyl groups in a molecule thereof, such as trimethylolpropane tri(meth)acrylate.

Examples of the (meth)acrylamide derivative include N-methylol (meth)acrylamide, 2-hydroxyethyl (meth)acrylamide, 3-hydroxypropyl (meth)acrylamide, 4-hydroxybutyl (meth)acrylamide, 5-hydroxypentyl (meth)acrylamide, 6-hydroxyhexyl (meth)acrylamide, N-methoxymethyl (meth)acrylamide, N-ethoxymethyl (meth)acrylamide, N-propoxymethyl (meth)acrylamide, N-butoxymethyl (meth)acrylamide, N,N-dimethyl (meth)acrylamide, N,N-diethyl (meth)acrylamide, N-isopropyl (meth)acrylamide, N-dimethylaminopropyl (meth)acrylamide, N-(1,1-dimethyl-3-oxobutyl)(meth)acrylamide, N-[2-(2-oxo-1-imidazolidinyl)ethyl] (meth)acrylamide, and 2-acryloylamino-2-methyl-1-propane sulfonic acid.

The monomer (A-3) may be used alone or in combination of two or more thereof.

The content of the repeating unit derived from the monomer (A-3) is preferably 0 to 20% by mass and more preferably 0 to 10% by mass with respect to all the repeating units of the copolymer (A).

The copolymer (A) may be used alone or in combination of two or more thereof.

The weight-average molecular weight (Mw) of the copolymer (A) in terms of standard polystyrene by gel permeation chromatography (GPC) is not particularly limited, and is preferably 500,000 to 2,000,000, more preferably 600,000 to 1,800,000, and still more preferably 700,000 to 1,700,000.

In a case where the weight-average molecular weight is 500,000 or more, the adhesiveness of the pressure sensitive adhesive layer under high temperature and high humidity is improved, the possibility of floating or peeling between the glass substrate (image display element) and the pressure sensitive adhesive layer tends to decrease, and the peeling property in reworking process tends to improve, which is preferable. In addition, in a case where the weight-average molecular weight is 2,000,000 or less, the pressure sensitive adhesive layer can change according to the dimensional changes of an optical film even in a case where the dimensions of the optical film change in a case where the pressure sensitive adhesive layer is bonded to the optical film or the like. Therefore, there is no difference between brightness of a peripheral portion and brightness of a central portion of an image display element such as a liquid crystal cell, and white spots and color unevenness tend to be suppressed, which is preferable.

The molecular weight distribution represented by a ratio (Mw/Mn) of the weight-average molecular weight (Mw) to the number average molecular weight (Mn) is preferably 2 to 10.

The copolymer (A) can be produced by various known methods such as a solution polymerization method, an emulsion polymerization method, a bulk polymerization method, and a suspension polymerization method.

It is preferable to use a polymerization initiator in the production of the copolymer (A). The amount of the polymerization initiator used is preferably 0.001 to 5 parts by mass with respect to 100 parts by mass in total of all the monomers used in the production of the copolymer (A).

Examples of the polymerization initiator include a thermal polymerization initiator and a photopolymerization initiator.

Examples of the photopolymerization initiator include 4-(2-hydroxyethoxy)phenyl(2-hydroxy-2-propyl)ketone.

Examples of the thermal polymerization initiator include azo-based compounds such as 2,2′-azobisisobutyronitrile, 2,2′-azobis(2-methylbutyronitrile), 1,1′-azobis(cyclohexane-1-carbonitrile), 2,2′-azobis(2,4-dimethylvaleronitrile), 2,2′-azobis(2,4-dimethyl-4-methoxyvaleronitrile), dimethyl-2,2′-azobis(2-methylpropionate), and 2,2′-azobis(2-hydroxymethylpropionitrile); organic peroxides such as lauryl peroxide, tert-butyl hydroperoxide, benzoyl peroxide, tert-butyl peroxybenzoate, cumene hydroperoxide, diisopropylperoxydicarbonate, dipropylperoxydicarbonate, tert-butylperoxyneodecanoate, tert-butylperoxypivalate, and (3,5,5-trimethylhexanoyl) peroxide; and inorganic peroxides such as potassium persulfate, ammonium persulfate, and hydrogen peroxide.

In addition, for example, a redox-based initiator in which a peroxide and a reducing agent are used in combination can also be used as the polymerization initiator.

As the method for producing the copolymer (A), the solution polymerization method is preferable among the methods shown above. A specific method of the solution polymerization method may be, for example, a method in which a desired monomer and an organic solvent are mixed to prepare a reaction solution, and a thermal polymerization initiator is added to the reaction solution under a nitrogen atmosphere, followed by stirring at about 40° C. to 90° C. (preferably about 50° C. to 80° C.) for about 3 to 20 hours.

In addition, in order to control the reaction, the monomer and the thermal polymerization initiator may be added continuously or intermittently during the polymerization, or may be added in a state of being dissolved in an organic solvent.

Examples of the organic solvent include aromatic hydrocarbons such as toluene and xylene; esters such as ethyl acetate and butyl acetate; aliphatic alcohols such as propyl alcohol and isopropyl alcohol; and ketones such as acetone, 2-butanone, and methyl isobutyl ketone.

(Crosslinking Agent)

The crosslinking agent is a compound that reacts with the polar functional group in the copolymer (A) to crosslink the copolymer (A).

The crosslinking agent has a functional group capable of reacting with the polar functional group in the copolymer (A). The number of functional groups capable of reacting with the polar functional group is not particularly limited, and is preferably 2 or more, more preferably 2 to 10, and still more preferably 2 to 6.

Examples of the crosslinking agent include an isocyanate-based compound, an epoxy-based compound, an aziridine-based compound, and a metal chelate compound.

The isocyanate-based compound, the epoxy-based compound, and the aziridine-based compound preferably each has at least two functional groups capable of reacting with the polar functional group in the copolymer (A), in a molecule thereof.

The crosslinking agent may be used alone or in combination of two or more thereof.

The isocyanate-based compound is preferably a compound having at least two isocyanato groups (—NCO) in a molecule thereof.

Examples of the isocyanate-based compound include tolylene diisocyanate, hexamethylene diisocyanate, isophorone diisocyanate, xylylene diisocyanate, hydrogenated xylylene diisocyanate, diphenylmethane diisocyanate, hydrogenated diphenylmethane diisocyanate, naphthalene diisocyanate, and triphenylmethane triisocyanate. In addition, an adduct obtained by reacting such an isocyanate-based compound with a polyol such as glycerol or trimethylolpropane, and a compound obtained by converting the isocyanate-based compound into a dimer, a trimer, or the like can also serve as the crosslinking agent.

The epoxy-based compound is preferably a compound having at least two epoxy groups in a molecule thereof.

Examples of the epoxy-based compound include bisphenol A type epoxy resin, ethylene glycol diglycidyl ether, polyethylene glycol diglycidyl ether, glycerin diglycidyl ether, glycerin triglycidyl ether, 1,6-hexanediol diglycidyl ether, trimethylolpropane triglycidyl ether, N,N-diglycidyl aniline, N,N,N′,N′-tetraglycidyl-m-xylene diamine, and 1,3-bis(N,N′-diglycidylaminomethyl)cyclohexane.

The aziridine-based compound is preferably a compound having at least two 3-membered ring skeletons consisting of one nitrogen atom and two carbon atoms in a molecule thereof, which is also referred to as ethyleneimine.

Examples of the aziridine-based compound include diphenylmethane-4,4′-bis(1-aziridinecarboxamide), toluene-2,4-bis(1-aziridinecarboxamide), triethylenemelamine, isophthaloylbis-1-(2-methylaziridine), tris-1-aziridinylphosphine oxide, hexamethylene-1,6-bis(1-aziridinecarboxamide), trimethylolpropane-tri-β-aziridinylpropionate, and tetramethylolmethane-tri-β-aziridinylpropionate.

Examples of the metal chelate compound include a compound in which acetylacetone or ethyl acetoacetate is coordinated with a polyvalent metal such as aluminum, iron, copper, zinc, tin, titanium, nickel, antimony, magnesium, vanadium, chromium, or zirconium.

The crosslinking agent is preferably an isocyanate-based compound, among which xylylene diisocyanate, tolylene diisocyanate, hexamethylene diisocyanate, or an adduct obtained by reacting such an isocyanate-based compound with a polyol such as glycerol or trimethylolpropane is preferable. In addition, the crosslinking agent is also preferably a mixture of a dimer, a trimer, or the like of an isocyanate-based compound.

Examples of the isocyanate-based compound include tolylene diisocyanate, an adduct obtained by reacting tolylene diisocyanate with a polyol, a dimer of tolylene diisocyanate, a trimer of tolylene diisocyanate, hexamethylene diisocyanate, an adduct obtained by reacting hexamethylene diisocyanate with a polyol, a dimer of hexamethylene diisocyanate, and a trimer of hexamethylene diisocyanate.

The amount of the crosslinking agent used is preferably 0.01 to 10 parts by mass, more preferably 0.01 to 5 parts by mass, and still more preferably 0.01 to 2 parts by mass with respect to 100 parts by mass of the solid content of the copolymer (A). In a case where the amount of the crosslinking agent used is 0.01 parts by mass or more, the durability of the pressure sensitive adhesive layer is improved, and in a case where the amount of the crosslinking agent used is 10 parts by mass or less, the white spots in a case where the pressure sensitive adhesive layer is applied to a liquid crystal display device become less noticeable.

The method of reacting the copolymer (A) with the crosslinking agent is not particularly limited, and examples thereof include a method of mixing the copolymer (A) and the crosslinking agent. If necessary, a heat treatment may be carried out during the reaction. The conditions of the heat treatment are not particularly limited, and the heating temperature is preferably 60° C. to 170° C. and more preferably 60° C. to 150° C.

As will be described later, in a case of forming the pressure sensitive adhesive layer, there is a method of using a composition for forming a pressure sensitive adhesive layer containing a copolymer (A), a crosslinking agent, and a specific compound. In this method, in a case of forming the pressure sensitive adhesive layer, the copolymer (A) and the crosslinking agent can be reacted to form a pressure sensitive adhesive layer containing a (meth)acrylic pressure sensitive adhesive and a specific compound.

(Method for Forming Pressure Sensitive Adhesive Layer)

The method for forming a pressure sensitive adhesive layer is not particularly limited, and examples thereof include known methods. Above all, a method of forming a pressure sensitive adhesive layer using a composition for forming a pressure sensitive adhesive layer containing the copolymer (A), a crosslinking agent, and a specific compound is preferable.

More specifically, there is a method in which a composition for forming a pressure sensitive adhesive layer containing the copolymer (A), a crosslinking agent, and a specific compound is coated on a predetermined support, and if necessary, a drying treatment is carried out to form a pressure sensitive adhesive layer.

The composition for forming a pressure sensitive adhesive layer contains the copolymer (A), the crosslinking agent, and the specific compound described above, and may contain components other than the above components.

The composition for forming a pressure sensitive adhesive layer may contain another (meth)acrylic resin different from the copolymer (A).

Examples of the other (meth)acrylic resin include resins containing repeating units derived from (meth)acrylic acid esters.

The weight-average molecular weight of the other (meth)acrylic resin is preferably 50,000 to 300,000.

Examples of the other (meth)acrylic resin include polymethyl (meth)acrylates.

In a case where the composition for forming a pressure sensitive adhesive layer contains another (meth)acrylic resin, the content of the other (meth)acrylic resin is preferably 50 parts by mass or less and more preferably 30 parts by mass or less with respect to 100 parts by mass of the copolymer (A).

The (meth)acrylic resin (a mixture of (meth)acrylic resins in a case where two or more types of (meth)acrylic resins are combined) contained in the composition for forming a pressure sensitive adhesive layer is such that a solution prepared by dissolving the (meth)acrylic resin in ethyl acetate to adjust a concentration of solid contents to 20% by mass preferably exhibits a viscosity of 20 Pa·s or less at 25° C., and more preferably a viscosity of 0.1 to 7 Pa·s at 25° C.

In a case where the viscosity is 20 Pa·s or less, the adhesiveness of the pressure sensitive adhesive layer under high temperature and high humidity is improved, the possibility of floating or peeling between the display element and the pressure sensitive adhesive layer tends to decrease, and the peeling property in reworking process tends to improve, which is preferable.

The viscosity can be measured with a Brookfield viscometer.

The composition for forming a pressure sensitive adhesive layer preferably contains a silane-based compound. The silane-based compound improves the pressure sensitive adhesive force of the pressure sensitive adhesive layer to the glass.

Examples of the silane-based compound include vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloyloxypropyltrimethoxysilane, 3-mercaptopropyltrimethoxysilane, 3-glycidoxypropyltrimethoxysilane, 3-glycidoxylpropyltriethoxysilane, 3-glycidoxypropyldimethoxymethylsilane, and 3-glycidoxypropylethoxydimethylsilane.

The silane-based compound may be of a silicone oligomer type. In a case where the silicone oligomer is shown in the form of a (monomer) oligomer, for example, the following can be mentioned.

Mercaptopropyl group-containing copolymers, such as 3-mercaptopropyltrimethoxysilane-tetramethoxysilane copolymer, 3-mercaptopropyltrimethoxysilane-tetraethoxysilane copolymer, 3-mercaptopropyltriethoxysilane-tetramethoxysilane copolymer, and 3-mercaptopropyltriethoxysilane-tetraethoxysilane copolymer;

Mercaptomethyl group-containing copolymers, such as mercaptomethyltrimethoxysilane-tetramethoxysilane copolymer, mercaptomethyltrimethoxysilane-tetraethoxysilane copolymer, mercaptomethyltriethoxysilane-tetramethoxysilane copolymer, and mercaptomethyltriethoxysilane-tetraethoxysilane copolymer;

Methacryloyloxypropyl group-containing copolymers such as 3-methacryloyloxypropyltrimethoxysilane-tetramethoxysilane copolymer, 3-methacryloyloxypropyltrimethoxysilane-tetraethoxysilane copolymer, 3-methacryloyloxypropyltriethoxysilane-tetramethoxysilane copolymer, 3-methacryloyloxypropyltriethoxysilane-tetraethoxysilane copolymer, 3-methacryloyloxypropylmethyldimethoxysilane-tetramethoxysilane copolymer, 3-methacryloyloxypropylmethyldimethoxysilane-tetraethoxysilane copolymer, 3-methacryloyloxypropylmethyldiethoxysilane-tetramethoxysilane copolymer, and 3-methacryloyloxypropylmethyldiethoxysilane-tetraethoxysilane copolymer;

Acryloyloxypropyl group-containing copolymers such as 3-acryloyloxypropyltrimethoxysilane-tetramethoxysilane copolymer, 3-acryloyloxypropyltrimethoxysilane-tetraethoxysilane copolymer, 3-acryloyloxypropyltriethoxysilane-tetramethoxysilane copolymer, 3-acryloyloxypropyltriethoxysilane-tetraethoxysilane copolymer, 3-acryloyloxypropylmethyldimethoxysilane-tetramethoxysilane copolymer, 3-acryloyloxypropylmethyldimethoxysilane-tetraethoxysilane copolymer, 3-acryloyloxypropylmethyldiethoxysilane-tetramethoxysilane copolymer, and 3-acryloyloxypropylmethyldiethoxysilane-tetraethoxysilane copolymer;

Vinyl group-containing copolymers such as vinyltrimethoxysilane-tetramethoxysilane copolymer, vinyltrimethoxysilane-tetraethoxysilane copolymer, vinyltriethoxysilane-tetramethoxysilane copolymer, vinyltriethoxysilane-tetraethoxysilane copolymer, vinylmethyldimethoxysilane-tetramethoxysilane copolymer, vinylmethyldimethoxysilane-tetraethoxysilane copolymer, vinylmethyldiethoxysilane-tetramethoxysilane copolymer, and vinylmethyldiethoxysilane-tetraethoxysilane copolymer;

Amino group-containing copolymers such as 3-aminopropyltrimethoxysilane-tetramethoxysilane copolymer, 3-aminopropyltrimethoxysilane-tetraethoxysilane copolymer, 3-aminopropyltriethoxysilane-tetramethoxysilane copolymer, 3-aminopropyltriethoxysilane-tetraethoxysilane copolymer, 3-aminopropylmethyldimethoxysilane-tetramethoxysilane copolymer, 3-aminopropylmethyldimethoxysilane-tetraethoxysilane copolymer, 3-aminopropylmethyldiethoxysilane-tetramethoxysilane copolymer, and 3-aminopropylmethyldiethoxysilane-tetraethoxysilane copolymer;

The content of the silane-based compound in the composition for forming a pressure sensitive adhesive layer is not particularly limited, and is preferably 0.01 to 10 parts by mass and more preferably 0.01 to 5 parts by mass with respect to 100 parts by mass of the solid content of the copolymer (A).

In a case where the content of the silane-based compound is 0.01 parts by mass or more, the adhesiveness between the pressure sensitive adhesive layer and the display element is further improved. In addition, in a case where the content of the silane-based compound is 10 parts by mass or less, bleeding out of the silane-based compound from the pressure sensitive adhesive layer is suppressed.

The silane-based compound may be used alone or in combination of two or more thereof.

The composition for forming a pressure sensitive adhesive layer may further contain a crosslinking catalyst, an antistatic agent, a weathering stabilizer, a tackifier, a plasticizer, a softener, a dye, a pigment, an inorganic filler, a resin other than an acrylic resin, and the like. In addition, it is also useful to formulate an ultraviolet curable compound in the composition for forming a pressure sensitive adhesive layer to form a pressure sensitive adhesive layer which is then cured by irradiation with ultraviolet rays to obtain a harder pressure sensitive adhesive layer. Above all, in a case where a crosslinking catalyst is formulated with a crosslinking agent in the composition for forming a pressure sensitive adhesive layer, the pressure sensitive adhesive layer can be prepared by aging in a short time, and therefore the occurrence of floating or peeling between the polarizing plate, the protective film, or the like and the pressure sensitive adhesive layer, and the occurrence of foaming in the pressure sensitive adhesive layer can be suppressed, and the peeling property in reworking process may be improved.

Examples of the crosslinking catalyst include amine-based compounds such as hexamethylenediamine, ethylenediamine, polyethyleneimine, hexamethylenetetramine, diethylenetriamine, triethylenetetramine, isophoronediamine, trimethylenediamine, a polyamino resin, and a melamine resin.

In a case where the amine-based compound is used as the crosslinking catalyst in the composition for forming a pressure sensitive adhesive layer, an isocyanate-based compound is suitable as the crosslinking agent.

The composition for forming a pressure sensitive adhesive layer may contain a solvent. Examples of the solvent include alcohol solvents such as methanol, ethanol, ethylene glycol, isopropyl alcohol, propylene glycol, methyl cellosolve, butyl cellosolve, and propylene glycol monomethyl ether; ester solvents such as ethyl acetate, butyl acetate, ethylene glycol methyl ether acetate, γ-butyrolactone, propylene glycol monomethyl ether acetate, and ethyl lactate; ketone solvents such as acetone, 2-butanone, cyclopentanone, cyclohexanone, methyl amyl ketone, and methyl isobutyl ketone; aliphatic hydrocarbon solvents such as pentane, hexane, and heptane; aromatic hydrocarbon solvents such as toluene and xylene; nitrile solvents such as acetonitrile; ether solvents such as tetrahydrofuran and dimethoxyethane; and chlorinated hydrocarbon solvents such as chloroform and chlorobenzene.

Among them, 2-butanone or methyl isobutyl ketone is preferable from the viewpoint of solubility of each component and reduction of environmental load.

The method for coating the composition for forming a pressure sensitive adhesive layer is not particularly limited, and a known method can be mentioned. For example, there is a method of coating on a predetermined support by a die coater or a gravure coater.

After the coating, the coating film may be subjected to a drying treatment if necessary. Examples of the drying treatment method include a heat treatment. The copolymer (A) may be reacted with the crosslinking agent during the drying treatment (preferably a heat treatment).

In addition, the composition for forming a pressure sensitive adhesive layer may be coated on a temporary support such as a plastic film that has been subjected to a release treatment to form a sheet-like pressure sensitive adhesive layer, and then the pressure sensitive adhesive layer may be transferred on a film or layer to be laminated.

The thickness of the pressure sensitive adhesive layer is not particularly limited, and is often 1 to 100 μm. From the viewpoint of thinning, the thickness of the adhesive layer is preferably less than 20 μm, more preferably less than 15 μm, still more preferably less than 10 μm, and most preferably 5 μm or less.

<Optically Anisotropic Layer>

The laminate has an optically anisotropic layer. The optically anisotropic layer is a layer formed of a composition containing a polymerizable liquid crystal compound exhibiting reverse wavelength dispersibility (hereinafter, also simply referred to as “liquid crystal composition”).

In the following, first, the components in the liquid crystal composition used for forming the optically anisotropic layer will be described in detail, and then the production method and characteristics of the optically anisotropic layer will be described in detail.

Here, the liquid crystal compound exhibiting “reverse wavelength dispersibility” in the present specification refers to a liquid crystal compound in which an in-plane retardation (Re) value corresponds to or becomes higher than an increase in a measurement wavelength in a case where the Re value at a specific wavelength (visible light range) of an optically anisotropic layer prepared using this compound is measured.

The polymerizable liquid crystal compound exhibiting reverse wavelength dispersibility is not particularly limited as long as it can form a film exhibiting reverse wavelength dispersibility as described above, and examples thereof include the compounds represented by General Formula (I) described in JP2008-297210A (particularly, the compounds described in paragraphs [0034] to [0039]), the compounds represented by General Formula (I) described in JP2010-084032A (particularly, the compounds described in paragraphs [0067] to [0073]), and the compounds represented by General Formula (I) described in JP2016-081035A (particularly, the compounds described in paragraphs [0043] to [0055]).

The polymerizable liquid crystal compound is preferably a polymerizable liquid crystal compound having a partial structure represented by Formula (II), from the viewpoint that the effect of the present invention is more excellent.

(Polymerizable liquid crystal compound having a partial structure represented by Formula (II))

Formula (II)

*-D₁-Ar-D₂-* (II)

Here, in Formula (II),

D₁ and D₂ each independently represent a single bond, —O—, —CO—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—.

R¹, R², R³, and R⁴ each independently represent a hydrogen atom, a fluorine atom, or an alkyl group having 1 to 4 carbon atoms. In a case where there are a plurality of each of R¹'s, R²'s, R³'s, and R⁴'s, the plurality of R¹'s, the plurality of R²'s, the plurality of R³'s, and the plurality of R⁴'s each may be the same as or different from each other.

Ar represents any aromatic ring selected from the group consisting of groups represented by Formulae (Ar-1) to (Ar-7).

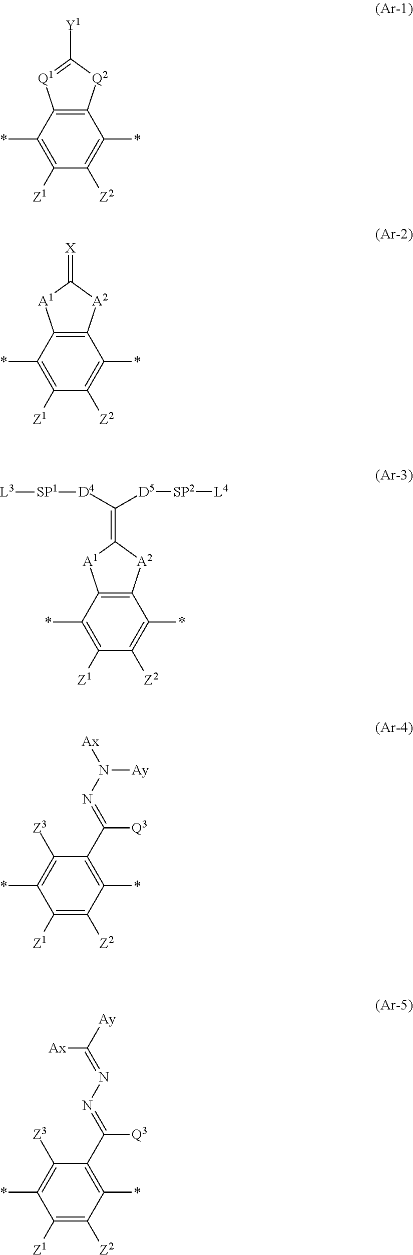

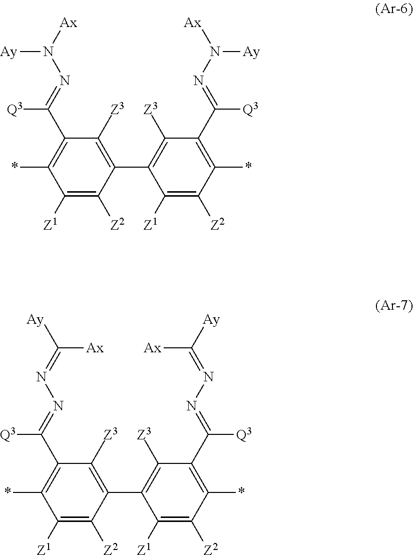

The polymerizable liquid crystal compound having a partial structure represented by Formula (II) is preferably a polymerizable liquid crystal compound represented by Formula (III).

The polymerizable liquid crystal compound represented by Formula (III) is a compound exhibiting liquid crystallinity.

L₁-G₁-D₁-Ar-D₂-G₂-L₂ (III)

In Formula (III), D₁ and D₂ each independently represent a single bond, —O—, —CO—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—.

R¹, R², R³, and R⁴ each independently represent a hydrogen atom, a fluorine atom, or an alkyl group having 1 to 4 carbon atoms. In a case where there are a plurality of each of R¹'s, R²'s, R³'s, and R⁴'s, the plurality of R¹'s, the plurality of R²'s, the plurality of R³'s, and the plurality of R⁴'s each may be the same as or different from each other.

G₁ and G₂ each independently represent a divalent alicyclic hydrocarbon group having 5 to 8 carbon atoms, a group in which a plurality of the alicyclic hydrocarbon groups are linked, an aromatic hydrocarbon group, or a group in which a plurality of the aromatic hydrocarbon groups are linked, and the methylene group contained in the alicyclic hydrocarbon group may be substituted with —O—, —S—, or —NH—.

The group in which a plurality of the alicyclic hydrocarbon groups are linked means a group in which divalent alicyclic hydrocarbon groups having 5 to 8 carbon atoms are linked by a single bond. In addition, the group in which a plurality of the aromatic hydrocarbon groups are linked means a group in which aromatic hydrocarbon groups are linked by a single bond.

L₁ and L₂ each independently represent a monovalent organic group, and at least one selected from the group consisting of L₁ and L₂ represents a monovalent group having a polymerizable group.

Ar represents any aromatic ring selected from the group consisting of groups represented by Formulae (Ar-1) to (Ar-7).

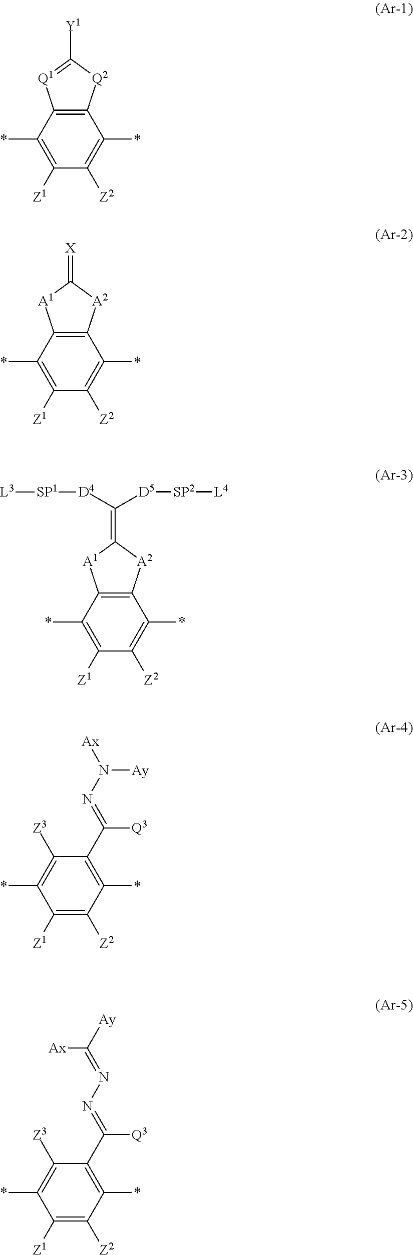

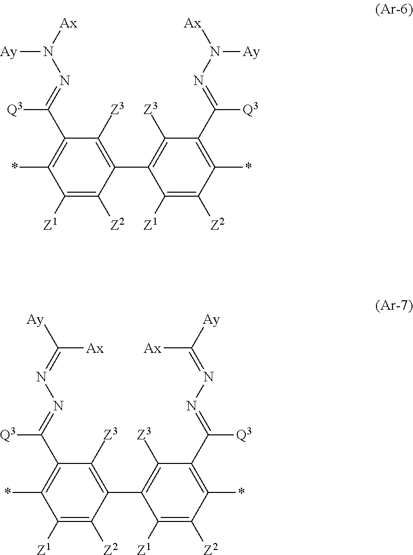

In Formula (Ar-1), Q¹ represents N or CH, Q² represents —S—, —O—, or —N(R⁷)—, R⁷ represents a hydrogen atom or an alkyl group having 1 to 6 carbon atoms, and Y¹ represents an aromatic hydrocarbon group having 6 to 12 carbon atoms or an aromatic heterocyclic group having 3 to 12 carbon atoms, each of which may have a substituent.

Examples of the alkyl group having 1 to 6 carbon atoms represented by R⁷ include a methyl group, an ethyl group, a propyl group, an isopropyl group, an n-butyl group, an isobutyl group, a sec-butyl group, a tert-butyl group, an n-pentyl group, and an n-hexyl group.

Examples of the aromatic hydrocarbon group having 6 to 12 carbon atoms represented by Y¹ include aryl groups of a phenyl group, a 2,6-diethylphenyl group, and a naphthyl group.

Examples of the aromatic heterocyclic group having 3 to 12 carbon atoms represented by Y¹ include heteroaryl groups of a thienyl group, a thiazolyl group, a furyl group, and a pyridyl group.

In addition, examples of the substituent that Y¹ may have include an alkyl group, an alkoxy group, and a halogen atom.

The alkyl group is preferably an alkyl group having 1 to 18 carbon atoms, more preferably an alkyl group having 1 to 8 carbon atoms (for example, a methyl group, an ethyl group, a propyl group, an isopropyl group, an n-butyl group, an isobutyl group, a sec-butyl group, a t-butyl group, and a cyclohexyl group), still more preferably an alkyl group having 1 to 4 carbon atoms, and particularly preferably a methyl group or an ethyl group. The alkyl group may be linear, branched, or cyclic.

The alkoxy group is, for example, preferably an alkoxy group having 1 to 18 carbon atoms, more preferably an alkoxy group having 1 to 8 carbon atoms (for example, a methoxy group, an ethoxy group, an n-butoxy group, and a methoxyethoxy group), still more preferably an alkoxy group having 1 to 4 carbon atoms, and particularly preferably a methoxy group or an ethoxy group.

Examples of the halogen atom include a fluorine atom, a chlorine atom, a bromine atom, and an iodine atom, and among them, a fluorine atom or a chlorine atom is preferable.

In addition, in Formulae (Ar-1) to (Ar-7), Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —OR⁸, —NR⁹R¹⁰, or —SR¹¹, R⁸ to R¹¹ each independently represent a hydrogen atom or an alkyl group having 1 to 6 carbon atoms, and Z¹ and Z² may be bonded to each other to form an aromatic ring.

The monovalent aliphatic hydrocarbon group having 1 to 20 carbon atoms is preferably an alkyl group having 1 to 15 carbon atoms, more preferably an alkyl group having 1 to 8 carbon atoms, still more preferably a methyl group, an ethyl group, an isopropyl group, a tert-pentyl group (1,1-dimethylpropyl group), a tert-butyl group, or a 1,1-dimethyl-3,3-dimethyl-butyl group, and particularly preferably a methyl group, an ethyl group, or a tert-butyl group.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group; monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and cyclodecadiene; and polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Examples of the monovalent aromatic hydrocarbon group having 6 to 20 carbon atoms include a phenyl group, a 2,6-diethylphenyl group, a naphthyl group, and a biphenyl group, among which an aryl group having 6 to 12 carbon atoms (particularly, a phenyl group) is preferable.

Examples of the halogen atom include a fluorine atom, a chlorine atom, a bromine atom and an iodine atom, and among them, a fluorine atom, a chlorine atom or a bromine atom is preferable.

Examples of the alkyl group having 1 to 6 carbon atoms represented by R⁸ to R¹¹ include a methyl group, an ethyl group, a propyl group, an isopropyl group, an n-butyl group, an isobutyl group, a sec-butyl group, a tert-butyl group, an n-pentyl group, and an n-hexyl group.

In addition, in Formulae (Ar-2) and (Ar-3), A¹ and A² each independently represent a group selected from the group consisting of —O—, —N(R¹²)—, —S—, and —CO—, and R¹² represents a hydrogen atom or a substituent.

Examples of the substituent represented by R¹² include the same substituents that Y¹ in Formula (Ar-1) may have.

In addition, in Formula (Ar-2), X represents a non-metal atom of Groups 14 to 16 to which a hydrogen atom or a substituent may be bonded.

In addition, examples of the non-metal atom of Groups 14 to 16 represented by X include an oxygen atom, a sulfur atom, a nitrogen atom having a hydrogen atom or a substituent, and a carbon atom having a hydrogen atom or a substituent (for example, ═C(CN)₂), and examples of the substituent include an alkyl group, an alkoxy group, an alkyl-substituted alkoxy group, a cyclic alkyl group, an aryl group (for example, a phenyl group or a naphthyl group), a cyano group, an amino group, a nitro group, an alkylcarbonyl group, a sulfo group, and a hydroxyl group.

In addition, in Formula (Ar-3), D⁴ and D⁵ each independently represent a single bond or —CO—, —O—, —S—, —C(═S)—, —CR^{1a}R^{2a}—, —CR^{3a}═CR^{4a}, —NR^{5a}—, or a divalent linking group consisting of two or more combinations of these groups, and R^{1a} to R^{5a} each independently represent a hydrogen atom, a fluorine atom, or an alkyl group having 1 to 4 carbon atoms.

Here, examples of the divalent linking group include —CO—, —O—, —CO—O—, —C(═S)O—, —CR^{1b}R^{2b}—, —CR^{1b}R^{2b}—CR^{1b}R^{2b}—, —O—CR^{1b}R^{2b}—, —CR^{1b}R^{2b}—O—CR^{1b}R^{2b}—, —CO—O—CR^{1b}R^{2b}—, —O—CO—CR^{1b}R^{2b}—, —CR^{1b}R^{2b}—O—CO—CR^{1b}R^{2b}—, —CR^{1b}R^{2b}—CO—O—CR^{1b}R^{2b}—, —NR^{3b}—CR^{1b}R^{2b}—, and —CO—NR^{3b}—. R^{1b}, R^{2b}, and R^{3b} each independently represent a hydrogen atom, a fluorine atom, or an alkyl group having 1 to 4 carbon atoms.

In addition, in Formula (Ar-3), SP¹ and SP² each independently represent a single bond, a linear or branched alkylene group having 1 to 12 carbon atoms, or a divalent linking group in which one or more of —CH₂— constituting a linear or branched alkylene group having 1 to 12 carbon atoms are substituted with —O—, —S—, —NH—, —N(Q)-, or —CO—, and Q represents a substituent. Examples of the substituent include the same substituents that Y¹ in Formula (Ar-1) may have.

Here, the linear or branched alkylene group having 1 to 12 carbon atoms is preferably, for example, a methylene group, an ethylene group, a propylene group, a butylene group, a pentylene group, a hexylene group, a methylhexylene group, or a heptylene group.

In addition, in Formula (Ar-3), L; and L₄ each independently represent a monovalent organic group.

Examples of the monovalent organic group include an alkyl group, an aryl group, and a heteroaryl group. The alkyl group may be linear, branched, or cyclic and is preferably linear. The number of carbon atoms in the alkyl group is preferably 1 to 30, more preferably 1 to 20, and still more preferably 1 to 10. In addition, the aryl group may be monocyclic or polycyclic and is preferably monocyclic. The number of carbon atoms in the aryl group is preferably 6 to 25 and more preferably 6 to 10. In addition, the heteroaryl group may be monocyclic or polycyclic. The number of heteroatoms constituting the heteroaryl group is preferably 1 to 3. The heteroatom constituting the heteroaryl group is preferably a nitrogen atom, a sulfur atom, or an oxygen atom. The number of carbon atoms in the heteroaryl group is preferably 6 to 18 and more preferably 6 to 12. In addition, the alkyl group, the aryl group, and the heteroaryl group may be unsubstituted or may have a substituent. Examples of the substituent include the same substituents that Y¹ in Formula (Ar-1) may have.

In addition, in Formulae (Ar-4) to (Ar-7), Ax represents an organic group having 2 to 30 carbon atoms which has at least one aromatic ring selected from the group consisting of an aromatic hydrocarbon ring and an aromatic heterocyclic ring.

In addition, in Formulae (Ar-4) to (Ar-7), Ay represents a hydrogen atom, an alkyl group having 1 to 12 carbon atoms which may have a substituent, or an organic group having 2 to 30 carbon atoms which has at least one aromatic ring selected from the group consisting of an aromatic hydrocarbon ring and an aromatic heterocyclic ring.

Here, the aromatic rings in Ax and Ay may have a substituent, and Ax and Ay may be bonded to each other to form a ring.

In addition, Q³ represents a hydrogen atom or an alkyl group having 1 to 6 carbon atoms which may have a substituent.

Examples of Ax and Ay include those described in paragraphs [0039] to [0095] of WO2014/010325A.

In addition, examples of the alkyl group having 1 to 6 carbon atoms represented by Q³ include a methyl group, an ethyl group, a propyl group, an isopropyl group, an n-butyl group, an isobutyl group, a sec-butyl group, a tert-butyl group, an N-pentyl group, and an n-hexyl group, and examples of the substituent include the same substituents that Y¹ in Formula (Ar-1) may have.

With regard to the definition and preferred range of each substituent of the liquid crystal compound represented by Formula (III), the descriptions regarding D¹, D², G¹, G₂, L¹, L², R⁴, R⁵, R⁶, R⁷, X¹, Y¹, Q¹, and Q² for Compound (A) described in JP2012-021068A can be referred to for D₁, D₂, G₁, G₂, L₁, L₂, R¹, R², R³, R⁴, Q₁, Y₁, Z₁, and Z₂, respectively; the descriptions regarding A₁, A2, and X for the compound represented by General Formula (I) described in JP2008-107767A can be referred to for A₁, A₂, and X, respectively; and the descriptions regarding Ax, Ay, and Q¹ for the compound represented by General Formula (I) described in WO 2013/018526A can be referred to for Ax, Ay, and Q³, respectively. The description of Q¹ for Compound (A) described in JP2012-021068A can be referred to for Z³.

In particular, the organic groups represented by L₁ and L₂ are each preferably a group represented by -D₃-G₃-Sp-P₃.

D₃ has the same definition as in D₁.

G₃ represents a single bond, a divalent aromatic ring group or heterocyclic group having 6 to 12 carbon atoms, a group in which a plurality of the aromatic ring groups or heterocyclic groups are linked, a divalent alicyclic hydrocarbon group having 5 to 8 carbon atoms, or a group in which a plurality of the alicyclic hydrocarbon groups are linked, and the methylene group contained in the alicyclic hydrocarbon group may be substituted with —O—, —S—, or —NR⁷— where R⁷ represents a hydrogen atom or an alkyl group having 1 to 6 carbon atoms.

The group in which a plurality of the aromatic ring groups or heterocyclic groups are linked means a group in which divalent aromatic ring groups or heterocyclic groups having 6 to 12 carbon atoms are linked by a single bond. In addition, the group in which a plurality of the alicyclic hydrocarbon groups are linked means a group in which divalent alicyclic hydrocarbon groups having 5 to 8 carbon atoms are linked by a single bond.

G₃ is also preferably a group in which two cyclohexane rings are bonded through a single bond.

Sp represents a spacer group represented by a single bond, —(CH₂)ₙ—, —(CH₂)ₙ—O—, —(CH₂—O—)ₙ—, —(CH₂CH₂—O—)ₘ, —O—(CH₂)ₙ—, —O—(CH₂)ₙ—O—, —O—(CH₂—O—)ₙ—, —O—(CH₂CH₂—O—)ₘ, —C(═O)—O—(CH₂)ₙ—, —C(═O)—O—(CH₂)ₙ—O—, —C(═O)—O—(CH₂—O—)ₙ—, —C(═O)—O—(CH₂CH₂—O—)ₘ, —C(═O)—N(R⁸)—(CH₂)ₙ—, —C(═O)—N(R⁸)—(CH₂)ₙ—O—, —C(═O)—N(R⁸)—(CH₂—O—)ₙ—, —C(═O)—N(R⁸)—(CH₂CH₂—O—)ₘ, or —(CH₂)ₙ—O—(C═O)—(CH₂)ₙ—C(═O)—O—(CH₂)ₙ—. Here, n represents an integer of 2 to 12, m represents an integer of 2 to 6, and R⁸ represents a hydrogen atom or an alkyl group having 1 to 6 carbon atoms. In addition, the hydrogen atom of —CH₂— in each of the above groups may be substituted with a methyl group.

P₃ represents a polymerizable group.

The polymerizable group is not particularly limited and is preferably a polymerizable group capable of radical polymerization or cationic polymerization.

Examples of the radically polymerizable group include known radically polymerizable groups, among which an acryloyl group or a methacryloyl group is preferable. The acryloyl group is generally known to have a high polymerization rate and therefore the acryloyl group is preferable from the viewpoint of improving productivity; whereas the methacryloyl group can also be used as the polymerizable group of a highly birefringent liquid crystal.

Examples of the cationically polymerizable group include known cationically polymerizable groups, examples of which include an alicyclic ether group, a cyclic acetal group, a cyclic lactone group, a cyclic thioether group, a spiroorthoester group, and a vinyloxy group. Of these, an alicyclic ether group or a vinyloxy group is preferable, and an epoxy group, an oxetanyl group, or a vinyloxy group is more preferable.

Particularly preferred examples of the polymerizable group include the following.

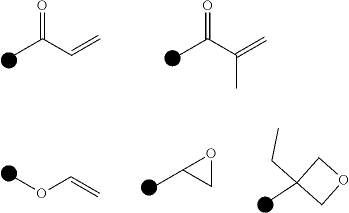

In the present specification, the “alkyl group” may be linear, branched, or cyclic, and examples thereof include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a 1,1-dimethylpropyl group, an n-hexyl group, an isohexyl group, a cyclopropyl group, a cyclobutyl group, a cyclopentyl group, and a cyclohexyl group.

Preferred examples of the liquid crystal compound represented by Formula (III) are shown below, but the present invention is not limited to these liquid crystal compounds.

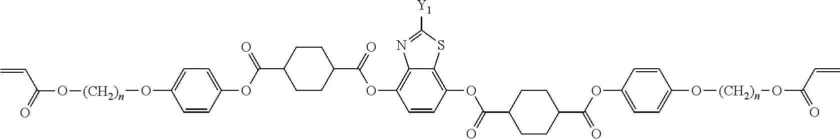

| No | Y1 | n |
|---|---|---|
| II-1-1 | 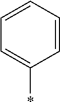 [SMILES: *c1ccccc1] | 6 |
| II-1-2 | 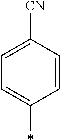 [SMILES: *c1ccc(C#N)cc1] | 6 |
| II-1-3 | 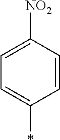 [SMILES: *c1ccc([N+](=O)[O-])cc1] | 6 |
| II-1-4 | 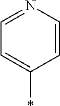 [SMILES: *c1ccncc1] | 6 |
| II-1-5 | 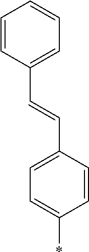 [SMILES: *c1ccc(/C=C/c2ccccc2)cc1] | 6 |
| II-1-6 | 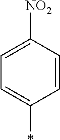 [SMILES: *c1ccc([N+](=O)[O-])cc1] | 11 |
| II-1-7 | 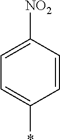 [SMILES: *c1ccc([N+](=O)[O-])cc1] | 8 |
| II-1-8 | 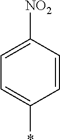 [SMILES: *c1ccc([N+](=O)[O-])cc1] | 4 |
| II-1-9 | 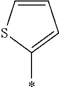 [SMILES: *c1cccs1] | 6 |
| II-1-10 | 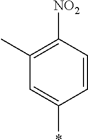 [SMILES: *c1ccc([N+](=O)[O-])c(C)c1] | 6 |
| II-1-11 | 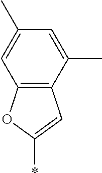 [SMILES: *c1cc2c(C)cc(C)cc2o1] | 6 |
| II-1-12 | 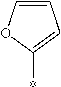 [SMILES: *c1ccco1] | 6 |
| II-1-13 | 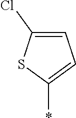 [SMILES: *c1ccc(Cl)s1] | 6 |
| II-1-14 | 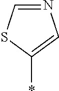 [SMILES: *c1cncs1] | 6 |
| II-1-15 | 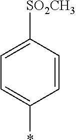 [SMILES: *c1ccc(S(C)(=O)=O)cc1] | 6 |

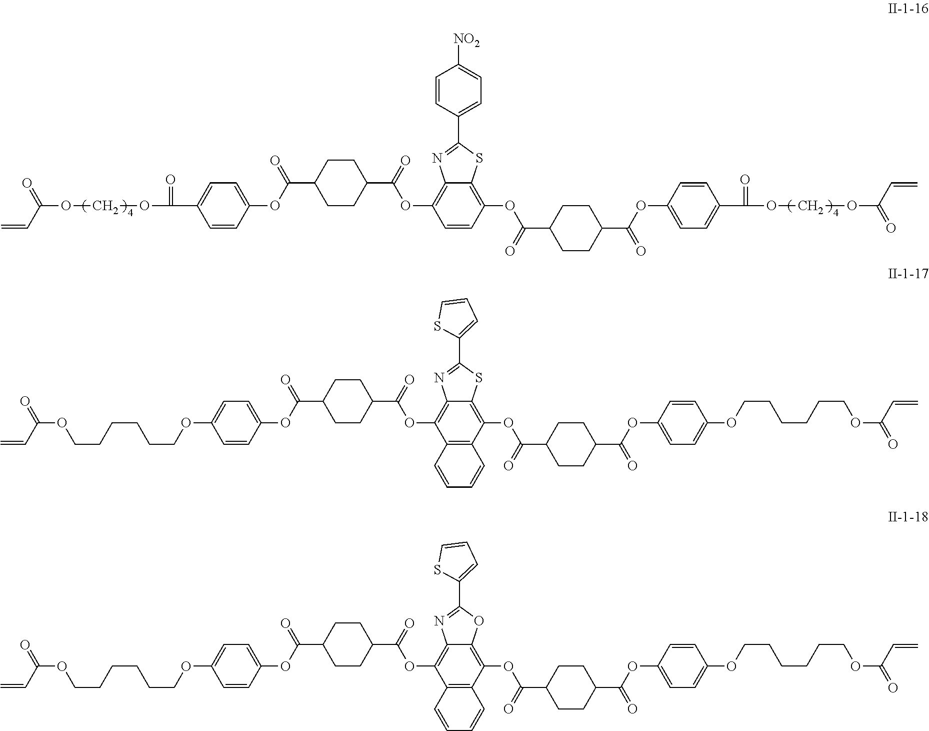

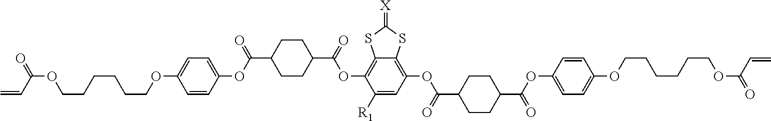

| No | X | R1 |
|---|---|---|
| II-2-1 | 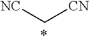 | H |
| II-2-2 | 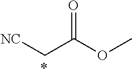 | H |
| II-2-3 | 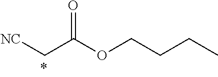 | H |
| II-2-4 | 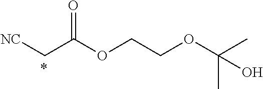 | H |
| II-2-5 | 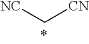 | CH₃ |
| II-2-6 | 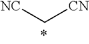 | 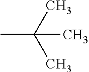 |
| II-2-7 | S | H |

In the above formulae, “*” represents a bonding position.

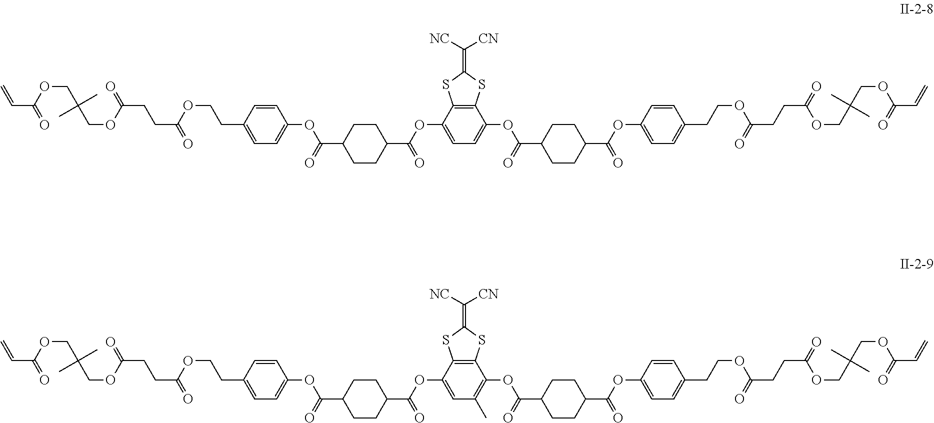

The group adjacent to the acryloyloxy group in Formulae II-2-8 and II-2-9 represents a propylene group (a group in which a methyl group is substituted with an ethylene group), and represents a mixture of regioisomers with different methyl group positions.

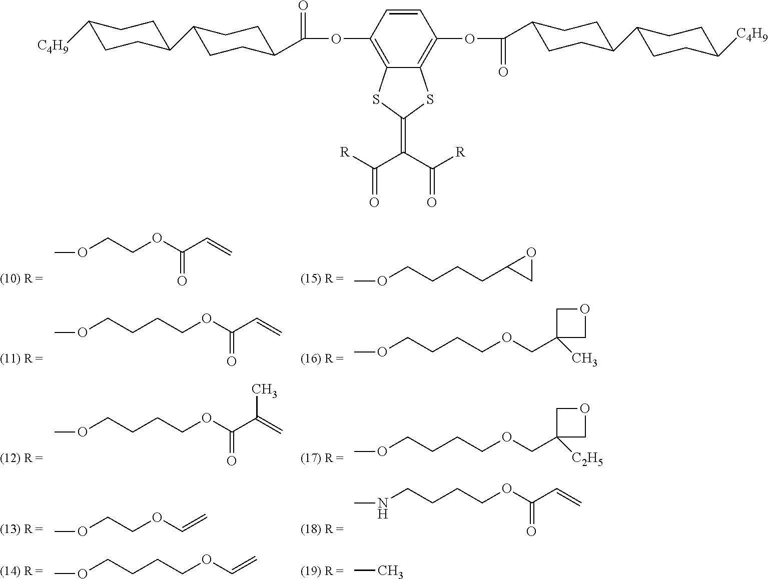

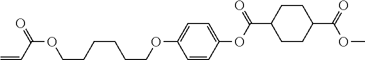 [SMILES: C=CC(=O)OCCCCCCOc1ccc(OC(=O)C2CCC(C(=O)OC)CC2)cc1]

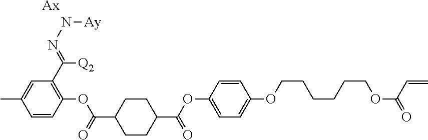

| No | Ax | Ay | Q2 |
|---|---|---|---|
| II-3-1 | 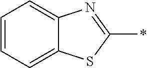 [SMILES: *c1nc2ccccc2s1] | H | H |
| II-3-2 | 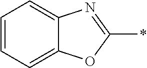 [SMILES: *c1nc2ccccc2o1] | H | H |
| II-3-3 | 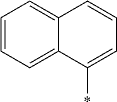 [SMILES: *c1cccc2ccccc12] | H | H |
| II-3-4 | Ph | Ph | H |
| II-3-5 | 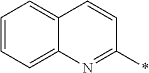 [SMILES: *c1ccc2ccccc2n1] | H | H |
| II-3-6 | 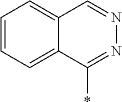 [SMILES: *c1nncc2ccccc12] | H | H |
| II-3-7 | 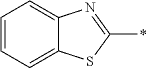 [SMILES: *c1nc2ccccc2s1] | CH₃ | H |
| II-3-8 | 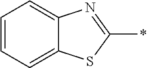 [SMILES: *c1nc2ccccc2s1] | C₄H₉ | H |
| II-3-9 | 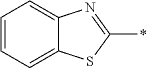 [SMILES: *c1nc2ccccc2s1] | C₆H₁₃ | H |
| II-3-10 | 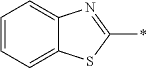 [SMILES: *c1nc2ccccc2s1] | 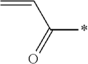 [SMILES: *C(=O)C=C] | H |
| II-3-11 | 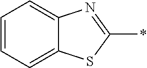 [SMILES: *c1nc2ccccc2s1] | 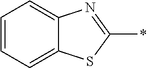 [SMILES: *c1nc2ccccc2s1] | H |
| II-3-12 | 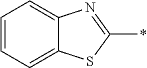 [SMILES: *c1nc2ccccc2s1] | CH₂CN | H |
| II-3-13 | 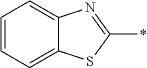 [SMILES: *c1nc2ccccc2s1] | 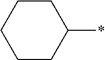 [SMILES: *C1CCCCC1] | H |
| II-3-14 | 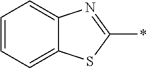 [SMILES: *c1nc2ccccc2s1] | 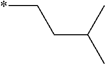 [SMILES: *CCC(C)C] | H |
| II-3-15 | 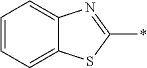 [SMILES: *c1nc2ccccc2s1] | CH₂CH₂OH | H |
| II-3-16 | 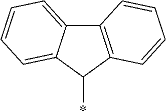 [SMILES: *C1c2ccccc2-c2ccccc21] | H | H |
| II-3-17 | 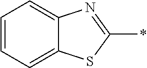 [SMILES: *c1nc2ccccc2s1] | CH₂CF₃ | H |
| II-3-18 | 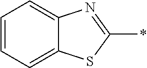 [SMILES: *c1nc2ccccc2s1] | H | CH₃ |
| II-3-19 | 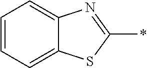 [SMILES: *c1nc2ccccc2s1] | 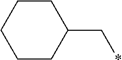 [SMILES: *CC1CCCCC1] | H |
| II-3-20 | 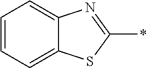 [SMILES: *c1nc2ccccc2s1] | 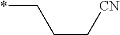 [SMILES: *CCCC#N] | H |
| II-3-21 | 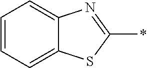 [SMILES: *c1nc2ccccc2s1] | 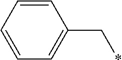 [SMILES: *Cc1ccccc1] | H |
| II-3-22 | 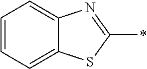 [SMILES: *c1nc2ccccc2s1] | 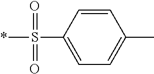 [SMILES: *S(=O)(=O)c1ccc(C)cc1] | H |
| II-3-23 | 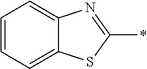 [SMILES: *c1nc2ccccc2s1] | 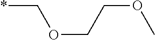 [SMILES: *COCCOC] | H |
| II-3-24 | 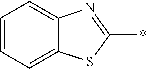 [SMILES: *c1nc2ccccc2s1] | 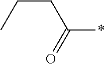 [SMILES: *C(=O)CCC] | H |
| II-3-25 | 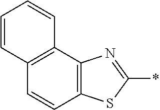 [SMILES: *c1nc2c(ccc3ccccc32)s1] | C₆H₁₃ | H |

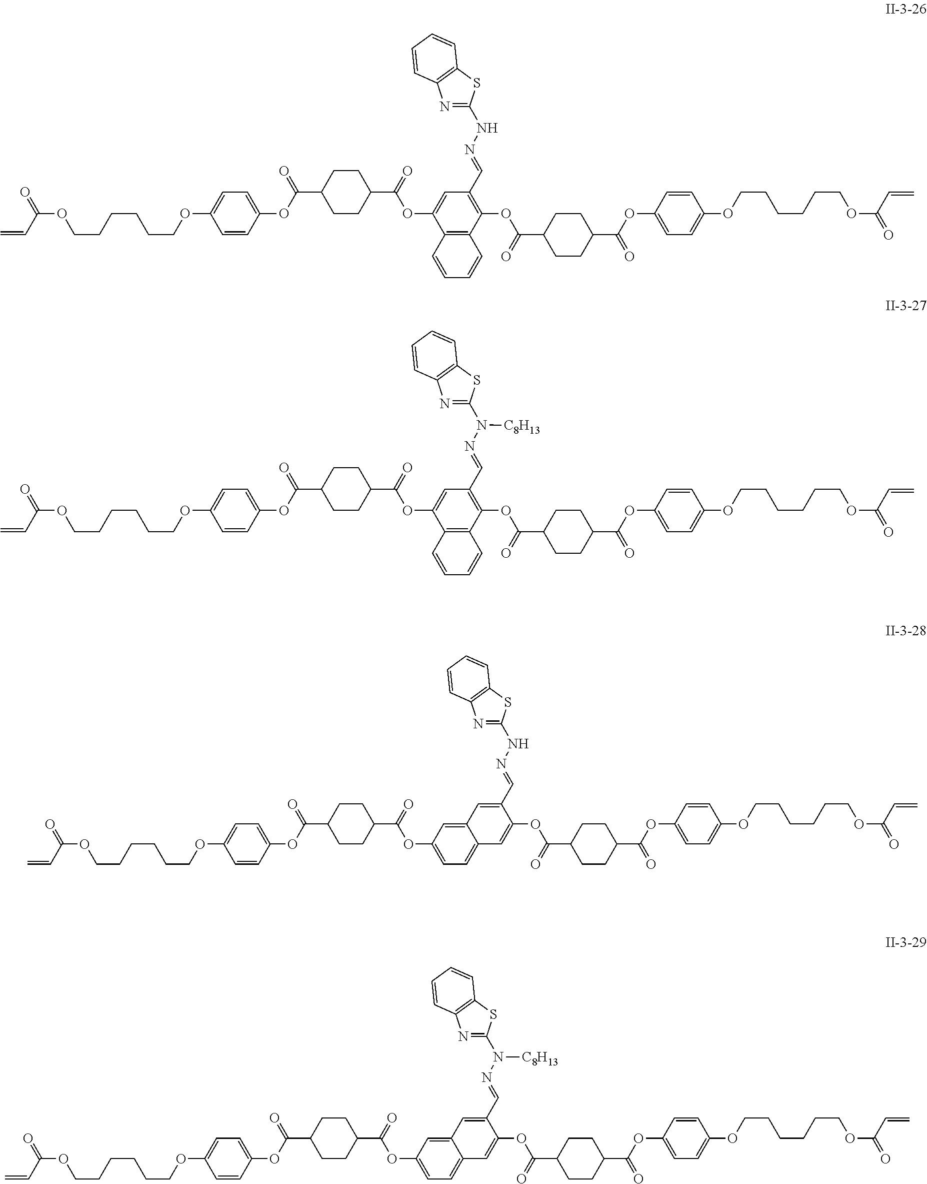

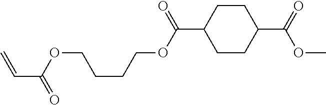 [SMILES: C=CC(=O)OCCCCOC(=O)C1CCC(C(=O)OC)CC1]

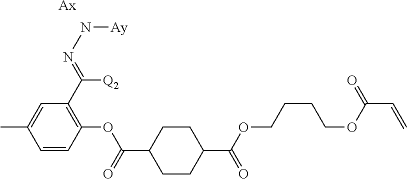

| No | Ax | Ay | Q2 |
|---|---|---|---|
| II-3-30 | 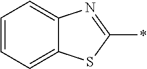 [SMILES: *c1nc2ccccc2s1] | H | H |
| II-3-31 | 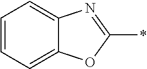 [SMILES: *c1nc2ccccc2o1] | H | H |
| II-3-32 | 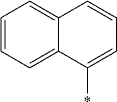 [SMILES: *c1cccc2ccccc12] | H | H |
| II-3-33 | Ph | Ph | H |
| II-3-34 | 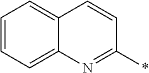 [SMILES: *c1ccc2ccccc2n1] | H | H |
| II-3-35 | 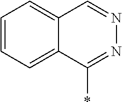 [SMILES: *c1nncc2ccccc12] | H | H |
| II-3-36 | 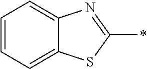 [SMILES: *c1nc2ccccc2s1] | CH₃ | H |
| II-3-37 | 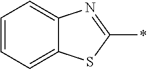 [SMILES: *c1nc2ccccc2s1] | C₄H₉ | H |
| II-3-38 | 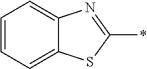 [SMILES: *c1nc2ccccc2s1] | C₆H₁₃ | H |
| II-3-39 | 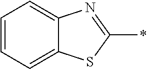 [SMILES: *c1nc2ccccc2s1] | 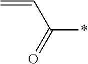 [SMILES: *C(=O)C=C] | H |
| II-3-40 | 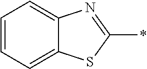 [SMILES: *c1nc2ccccc2s1] | 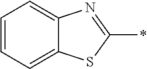 [SMILES: *c1nc2ccccc2s1] | H |
| II-3-41 | 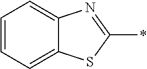 [SMILES: *c1nc2ccccc2s1] | CH₂CN | H |
| II-3-42 | 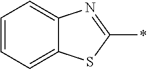 [SMILES: *c1nc2ccccc2s1] | 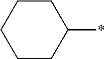 [SMILES: *C1CCCCC1] | H |
| II-3-43 | 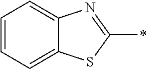 [SMILES: *c1nc2ccccc2s1] | 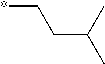 [SMILES: *CCC(C)C] | H |
| II-3-46 | 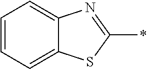 [SMILES: *c1nc2ccccc2s1] | CH₂CH₂OH | H |
| II-3-45 | 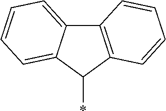 [SMILES: *C1c2ccccc2-c2ccccc21] | H | H |
| II-3-46 | 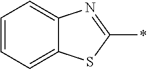 [SMILES: *c1nc2ccccc2s1] | CH₂CF₃ | H |
| II-3-47 | 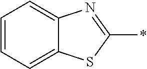 [SMILES: *c1nc2ccccc2s1] | H | CH₃ |
| II-3-48 | 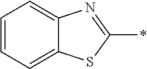 [SMILES: *c1nc2ccccc2s1] | 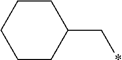 [SMILES: *CC1CCCCC1] | H |
| II-3-49 | 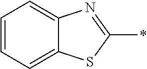 [SMILES: *c1nc2ccccc2s1] | 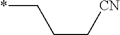 [SMILES: *CCCC#N] | H |
| II-3-50 | 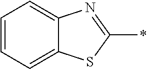 [SMILES: *c1nc2ccccc2s1] | 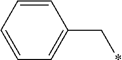 [SMILES: *Cc1ccccc1] | H |
| II-3-51 | 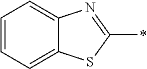 [SMILES: *c1nc2ccccc2s1] | 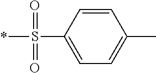 [SMILES: *S(=O)(=O)c1ccc(C)cc1] | H |
| II-3-52 | 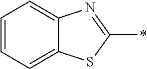 [SMILES: *c1nc2ccccc2s1] | 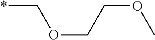 [SMILES: *COCCOC] | H |
| II-3-53 | 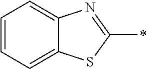 [SMILES: *c1nc2ccccc2s1] | 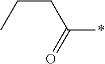 [SMILES: *C(=O)CCC] | H |
| II-3-54 | 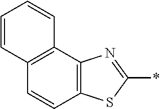 [SMILES: *c1nc2c(ccc3ccccc32)s1] | C₆H₁₃ | H |

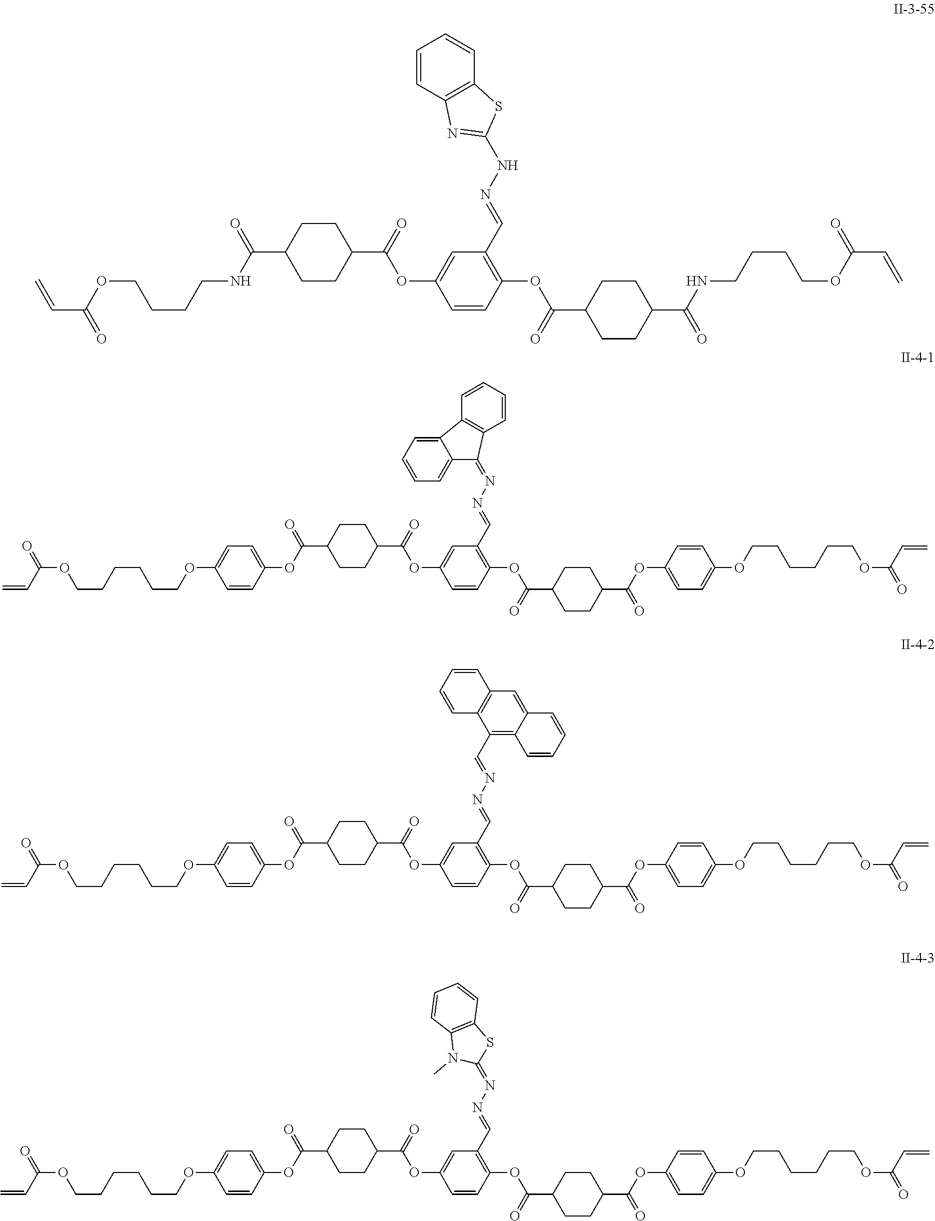

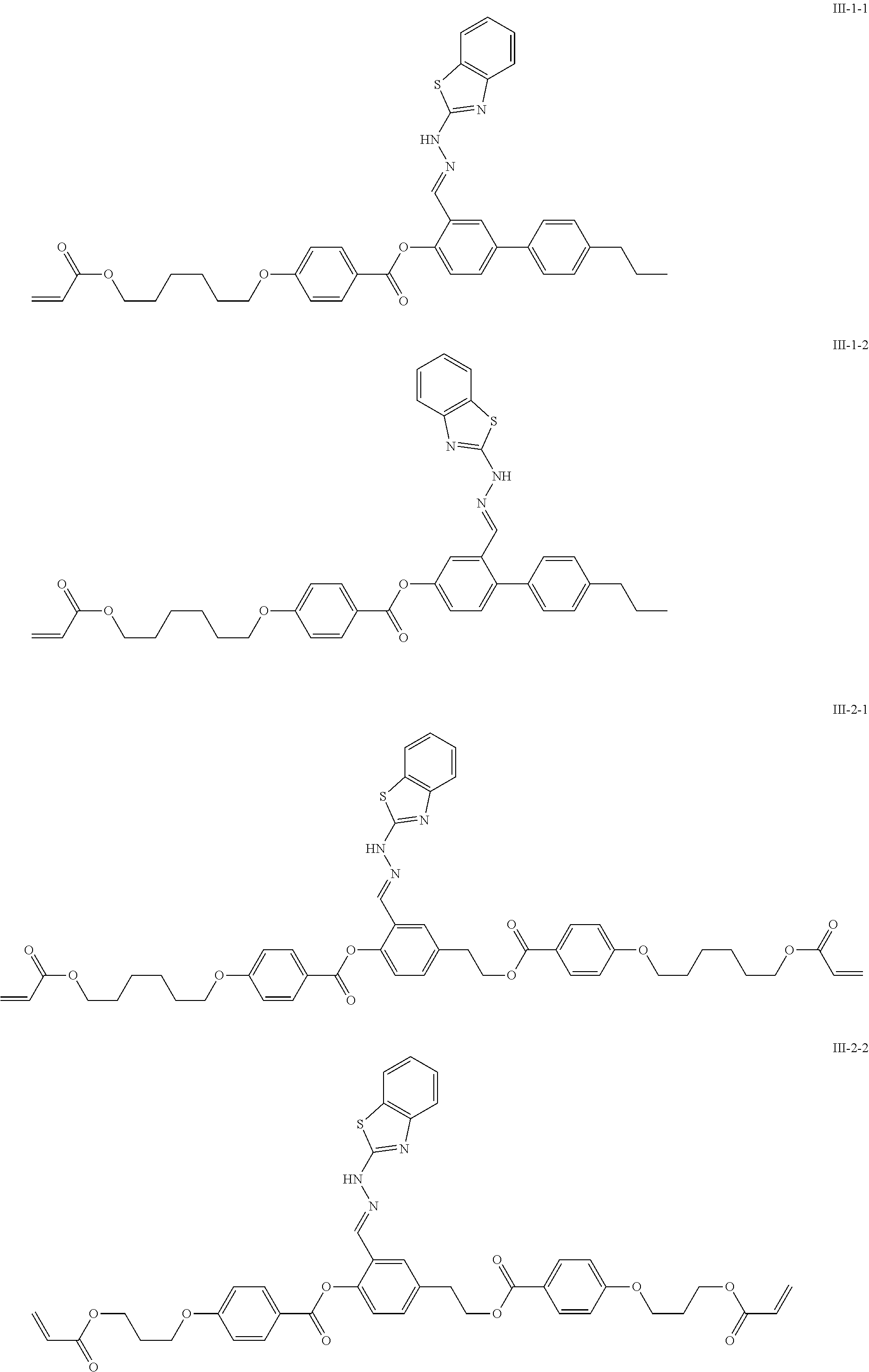

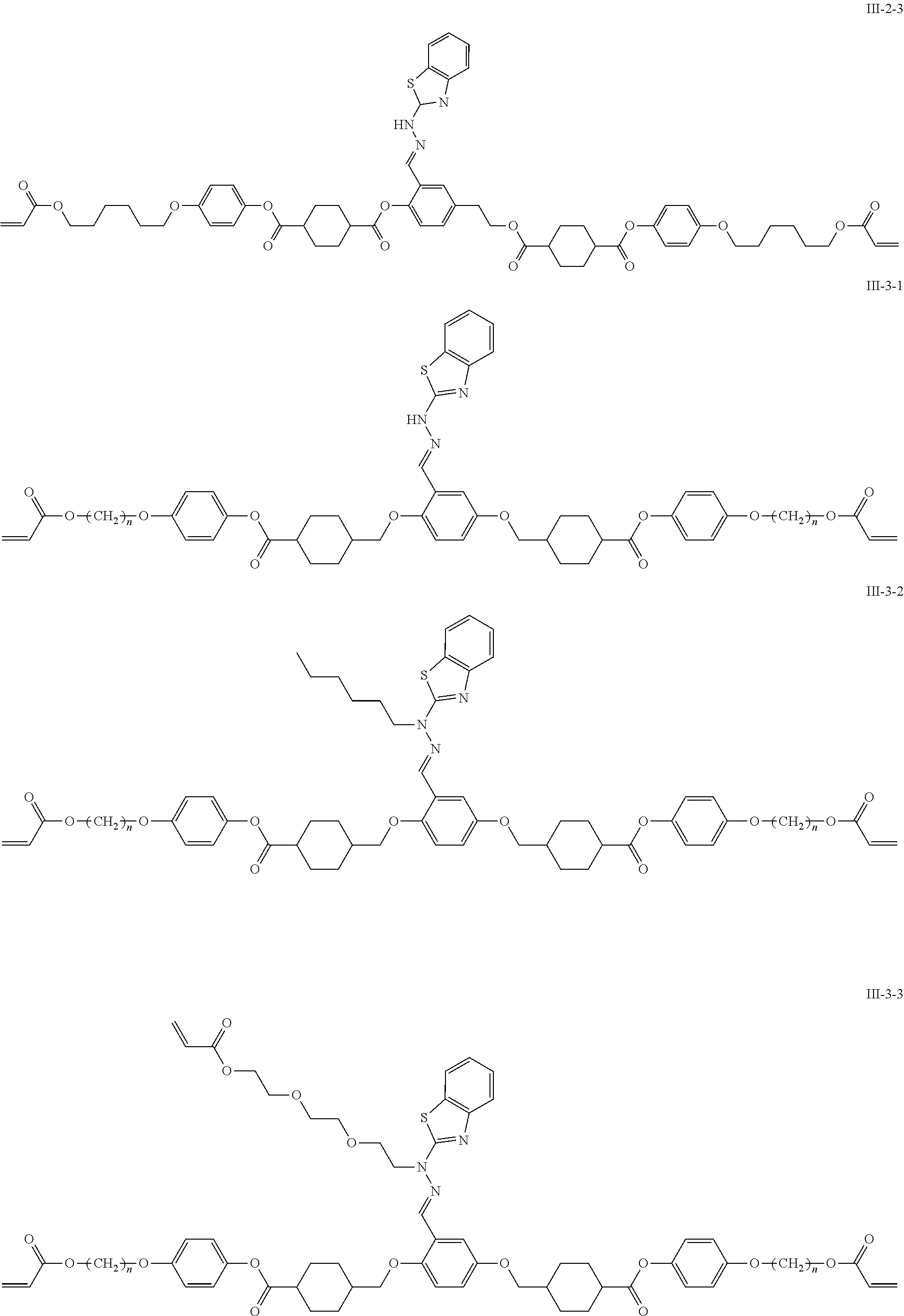

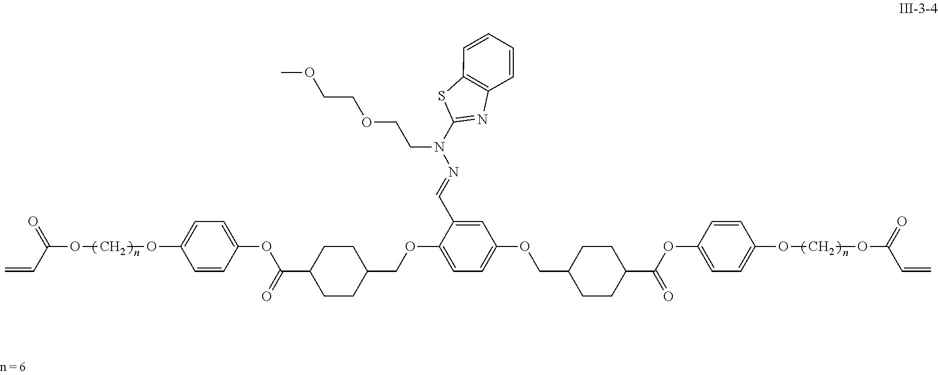

The content of the polymerizable liquid crystal compound represented by Formula (III) in the liquid crystal composition is not particularly limited, and is preferably 50% to 100% by mass and more preferably 70% to 99% by mass with respect to the total solid content in the liquid crystal composition.

The solid content means other components in the liquid crystal composition excluding a solvent, and the components are calculated as the solid content even in a case where the properties thereof are liquid.

The liquid crystal composition may contain a liquid crystal compound other than the polymerizable liquid crystal compound represented by Formula (III). Examples of the other liquid crystal compound include known liquid crystal compounds (a rod-like liquid crystal compound and a disk-like liquid crystal compound). The other liquid crystal compound may have a polymerizable group.

The content of the other liquid crystal compound in the liquid crystal composition is preferably 0% to 50% by mass and more preferably 10% to 40% by mass with respect to the total mass of the polymerizable liquid crystal compound represented by Formula (III).

The other liquid crystal compound is preferably a liquid crystal compound having, as a part, a cyclohexane ring in which one hydrogen atom is substituted with a linear alkyl group.

Here, the “cyclohexane ring in which one hydrogen atom is substituted with a linear alkyl group” refers to a cyclohexane ring in which one hydrogen atom of a cyclohexane ring present on a molecular terminal side is substituted with a linear alkyl group, for example, in a case of having two cyclohexane rings, as shown in Formula (2).

Examples of the above-mentioned compound include compounds having a group represented by Formula (2), among which a compound represented by Formula (3) having a (meth)acryloyl group is preferable from the viewpoint that a laminate having excellent thermal durability can be obtained.

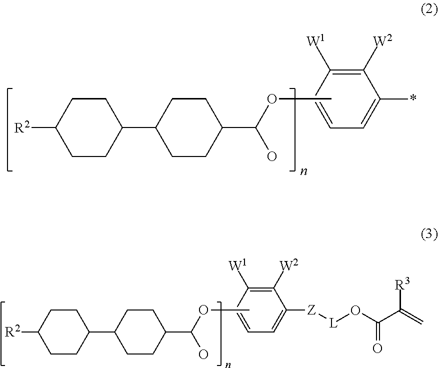

In Formula (2), * represents a bonding position.

In addition, in Formulae (2) and (3), R² represents an alkyl group having 1 to 10 carbon atoms, n represents 1 or 2, W¹ and W² each independently represent an alkyl group, an alkoxy group, or a halogen atom, and W¹ and W² may be bonded to each other to form a ring structure which may have a substituent.

In addition, in Formula (3), Z represents —COO—, L represents an alkylene group having 1 to 6 carbon atoms, and R³ represents a hydrogen atom or a methyl group.

Examples of the above-mentioned compound include compounds represented by Formulae A-1 to A-5. In Formula A-3, R represents an ethyl group or a butyl group.

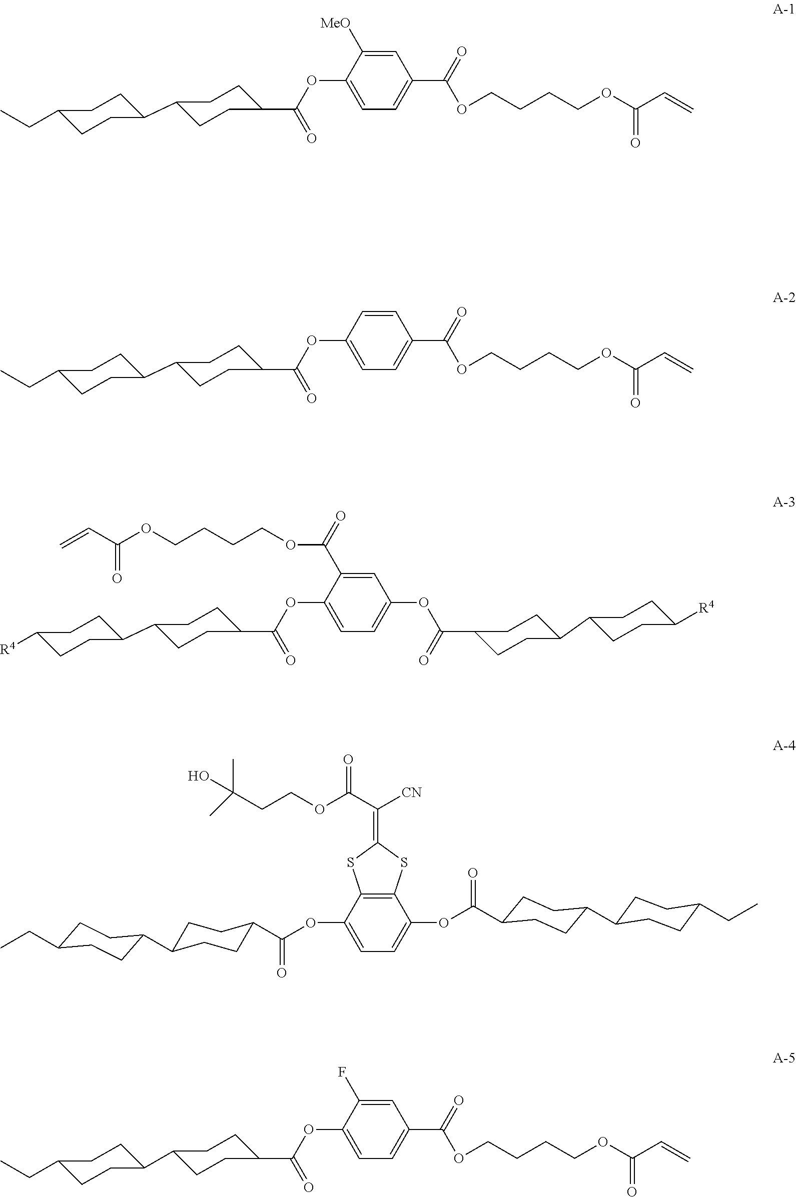

Examples of the other liquid crystal compound include a compound represented by Formula (M1), a compound represented by Formula (M2), and a compound represented by Formula (M3), described in paragraphs [0030] to [0033] of JP2014-077068A.

The liquid crystal composition may contain a polymerizable monomer other than the polymerizable liquid crystal compound represented by Formula (III) and the other liquid crystal compound having a polymerizable group. Above all, a polymerizable compound having two or more polymerizable groups (polyfunctional polymerizable monomer) is preferable from the viewpoint that the strength of an optically anisotropic layer is more excellent.

The polyfunctional polymerizable monomer is preferably a polyfunctional radically polymerizable monomer. Examples of the polyfunctional radically polymerizable monomer include polymerizable monomers described in paragraphs [0018] to [0020] in JP2002-296423A.

In addition, in a case where the liquid crystal composition contains a polyfunctional polymerizable monomer, the content of the polyfunctional polymerizable monomer is preferably 0.1% to 20% by mass, more preferably 0.1% to 10% by mass, and still more preferably 0.1% to 5% by mass with respect to the total solid content in the liquid crystal composition.

The liquid crystal composition may contain a polymerization initiator.

The polymerization initiator is preferably a photopolymerization initiator capable of initiating a polymerization reaction upon irradiation with ultraviolet rays.

Examples of the photopolymerization initiator include α-carbonyl compounds (as described in U.S. Pat. Nos. 2,367,661A and 2,367,670A), acyloin ethers (as described in U.S. Pat. No. 2,448,828A), α-hydrocarbon-substituted aromatic acyloin compounds (as described in U.S. Pat. No. 2,722,512A), polynuclear quinone compounds (as described in U.S. Pat. Nos. 3,046,127A and 2,951,758A), combinations of triarylimidazole dimers with p-aminophenyl ketones (as described in U.S. Pat. No. 3,549,367A), acridine and phenazine compounds (as described in JP1985-105667A (JP-S60-105667A) and U.S. Pat. No. 4,239,850A), oxadiazole compounds (as described in U.S. Pat. No. 4,212,970A), and acylphosphine oxide compounds (as described in JP1988-040799B (JP-S63-040799B), JP1993-029234B (JP-H05-029234B), JP1998-095788A (JP-H10-095788A), and JP1998-029997A (JP-H10-029997A)).

The polymerization initiator is preferably an oxime-type polymerization initiator and more preferably a compound represented by Formula (2).

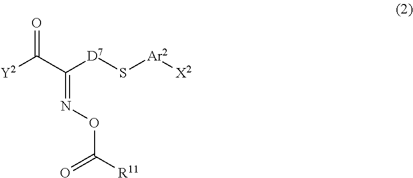

In Formula (2), X² represents a hydrogen atom or a halogen atom.

In addition, in Formula (2), Ar² represents a divalent aromatic group, and D⁷ represents a divalent organic group having 1 to 12 carbon atoms.

In addition, in Formula (2), R¹¹ represents an alkyl group having 1 to 12 carbon atoms, and Y² represents a monovalent organic group.

Examples of the halogen atom represented by X² in Formula (2) include a fluorine atom, a chlorine atom, a bromine atom, and an iodine atom, among which a chlorine atom is preferable.

In addition, examples of the divalent aromatic group represented by Ar² in Formula (2) include divalent groups which have an aromatic hydrocarbon ring such as a benzene ring, a naphthalene ring, an anthracene ring, or a phenanthroline ring; or an aromatic heterocyclic ring such as a furan ring, a pyrrole ring, a thiophene ring, a pyridine ring, a thiazole ring, or a benzothiazole ring.

In addition, examples of the divalent organic group having 1 to 12 carbon atoms represented by D⁷ in Formula (2) include a linear or branched alkylene group having 1 to 12 carbon atoms, specific examples of which include a methylene group, an ethylene group, and a propylene group.

In addition, examples of the alkyl group having 1 to 12 carbon atoms represented by R¹¹ in Formula (2) include a methyl group, an ethyl group, and a propyl group.

In addition, examples of the monovalent organic group represented by Y² in Formula (2) include a functional group containing a benzophenone skeleton ((C₆H₅)₂CO). Specifically, a functional group containing a benzophenone skeleton in which the terminal benzene ring is unsubstituted or monosubstituted is preferable such as a group represented by Formula (2a) and a group represented by Formula (2b). In Formula (2a) and Formula (2b), * represents a bonding position, that is, a bonding position to the carbon atom of the carbonyl group in Formula (2).

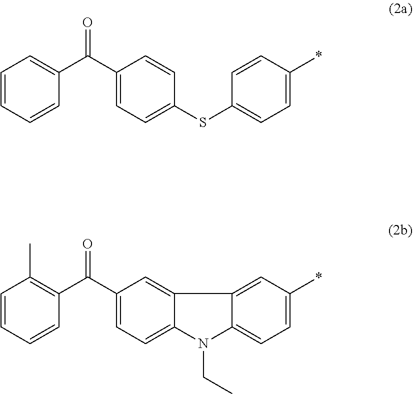 [SMILES: *c1ccc(Sc2ccc(C(=O)c3ccccc3)cc2)cc1 ; *c1ccc2c(c1)c1cc(C(=O)c3ccccc3C)ccc1n2CC]

Examples of the compound represented by Formula (2) include a compound represented by Formula S-1 and a compound represented by Formula S-2.

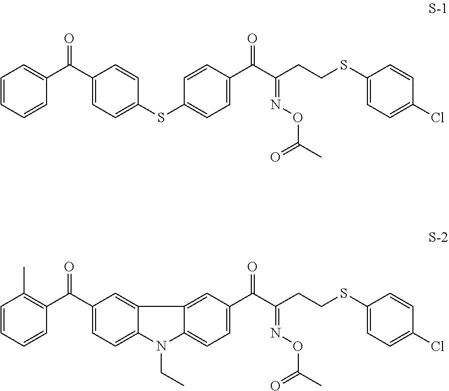 [SMILES: CC(=O)O/N=C(\CCSc1ccc(Cl)cc1)C(=O)c1ccc(Sc2ccc(C(=O)c3ccccc3)cc2)cc1 ; CCn1c2ccc(C(=O)/C(CCSc3ccc(Cl)cc3)=N/OC(C)=O)cc2c2cc(C(=O)c3ccccc3C)ccc21]

The content of the polymerization initiator in the liquid crystal composition is not particularly limited, and is preferably 0.01% to 20% by mass and more preferably 0.5% to 5% by mass with respect to the total solid content in the liquid crystal composition.

The liquid crystal composition may contain a solvent from the viewpoint of workability for forming an optically anisotropic layer.

Examples of the solvent include ketones (for example, acetone, 2-butanone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethyl formamide and dimethyl acetamide).

These solvent compounds may be used alone or in combination of two or more thereof.

The liquid crystal composition may contain a leveling agent from the viewpoint of keeping the surface of an optically anisotropic layer smooth.

The leveling agent is preferably a fluorine-based leveling agent or a silicon-based leveling agent from the viewpoint that the leveling effect is high relative to the amount added, and more preferably a fluorine-based leveling agent from the viewpoint that it is less likely to cause bleeding (bloom or bleed).

Examples of the leveling agent include the compounds described in paragraphs [0079] to [0102] of JP2007-069471A, the polymerizable liquid crystal compound represented by General Formula (II) described in JP2013-047204A (particularly, the compounds described in paragraphs [0020] to [0032]), the polymerizable liquid crystal compound represented by General Formula (III) described in JP2012-211306A (particularly, the compounds described in paragraphs [0022] to [0029]), the liquid crystal alignment accelerator represented by General Formula (III) described in JP2002-129162A (particularly, the compounds described in paragraphs [0076] to [0078] and [0082] to [0084]), and the compounds represented by General Formulae (I), (II), and (III) described in JP2005-099248A (particularly, the compounds described in paragraphs [0092] to [0096]). In addition, the leveling agent may also function as an alignment control agent which will be described later.

The liquid crystal composition may contain an alignment control agent, if necessary.

The alignment control agent can result in the formation of various alignment states such as homeotropic alignment (vertical alignment), tilt alignment, hybrid alignment, and cholesteric alignment in addition to homogeneous alignment, and makes it possible to achieve more uniform and more precise control of a specific alignment state.

As the alignment control agent which accelerates the homogeneous alignment, for example, a low molecular weight alignment control agent or a high molecular weight alignment control agent can be used.

With regard to the low molecular weight alignment control agent, reference can be made to the description in, for example, paragraphs [0009] to [0083] of JP2002-020363A, paragraphs [0111] to [0120] of JP2006-106662A, and paragraphs [0021] to [0029] of JP2012-211306A, the contents of which are incorporated herein by reference.

In addition, with regard to the high molecular weight alignment control agent, reference can be made to the description in, for example, paragraphs [0021] to [0057] of JP2004-198511A and paragraphs [0121] to [0167] of JP2006-106662A, the contents of which are incorporated herein by reference.

In addition, examples of the alignment control agent that forms or accelerates the homeotropic alignment include a boronic acid compound and an onium salt compound, and specifically, reference can be made to the compounds described in paragraphs [0023] to [0032] of JP2008-225281A, paragraphs [0052] to [0058] of JP2012-208397A, paragraphs [0024] to [0055] of JP2008-026730A, and paragraphs [0043] to [0055] of JP2016-193869A, the contents of which are incorporated herein by reference.

In a case where the liquid crystal composition contains an alignment control agent, the content of the alignment control agent is not particularly limited, and is preferably 0.01% to 10% by mass and more preferably 0.05% to 5% by mass with respect to the total solid content in the liquid crystal composition.

The liquid crystal composition may contain components other than the above-mentioned components, examples of which include a surfactant, a tilt angle control agent, an alignment assistant, a plasticizer, and a crosslinking agent.

(Method for Producing Optically Anisotropic Layer)

The method for producing an optically anisotropic layer is not particularly limited, and a known method can be mentioned.

For example, the liquid crystal composition is coated on a predetermined substrate (for example, a support layer which will be described later) to form a coating film, and the obtained coating film is subjected to a curing treatment (irradiation with active energy rays (light irradiation treatment) and/or heat treatment), whereby a cured coating film (optically anisotropic layer) can be produced. If necessary, an alignment layer which will be described later may be used.

The liquid crystal composition can be coated by a known method (for example, a wire bar coating method, an extrusion coating method, a direct gravure coating method, a reverse gravure coating method, or a die-coating method).

In the method for producing an optically anisotropic layer, it is preferable to carry out an alignment treatment of the liquid crystal compound contained in the coating film before subjecting the coating film to the curing treatment.

The alignment treatment can be carried out by drying or heating at room temperature (for example, 20° C. to 25° C.). In a case of a thermotropic liquid crystal compound, the liquid crystal phase formed by the alignment treatment can generally be transferred by a change in temperature or pressure. In a case of a liquid crystal compound having lyotropic properties, the liquid crystal phase formed by the alignment treatment can also be transferred by a composition ratio such as an amount of solvent.

In a case where the alignment treatment is a heat treatment, the heating time (heat aging time) is preferably 10 seconds to 5 minutes, more preferably 10 seconds to 3 minutes, and still more preferably 10 seconds to 2 minutes.

The above-mentioned curing treatment (irradiation with active energy rays (light irradiation treatment) and/or heat treatment) on the coating film can also be said to be an immobilization treatment for fixing the alignment of the liquid crystal compound.

The immobilization treatment is preferably carried out by irradiation with active energy rays (preferably ultraviolet rays), and the liquid crystal is immobilized by the polymerization of the liquid crystal compound.

(Characteristics of Optically Anisotropic Layer)

The optically anisotropic layer is a film formed by using the above-mentioned composition.

The optical characteristics of the optically anisotropic layer are not particularly limited, and it is preferable that the optically anisotropic layer functions as a λ/4 plate.

The λ/4 plate is a plate having a function of converting linearly polarized light having a certain specific wavelength into circularly polarized light (or converting circularly polarized light into linearly polarized light), and refers to a plate (optically anisotropic layer) in which an in-plane retardation Re (λ) at a specific wavelength λnm satisfies Re (λ)=λ/4. This expression may be achieved at any wavelength in a visible light range (for example, 550 nm), but the in-plane retardation Re (550) at a wavelength of 550 nm preferably satisfies a relationship of 110 nm≤Re (550)≤160 nm, and more preferably a relationship of 110 nm≤Re (550)≤150 nm.

It is preferable that Re (450), which is the in-plane retardation of the optically anisotropic layer measured at a wavelength of 450 nm, Re (550), which is the in-plane retardation of the optically anisotropic layer measured at a wavelength of 550 nm, and Re (650), which is the in-plane retardation of the optically anisotropic layer measured at a wavelength of 650 nm, have a relationship of Re (450)≤Re (550)≤Re (650). That is, it can be said that this relationship represents the reverse wavelength dispersibility.

The optically anisotropic layer may be an A-plate or a C-plate, and is preferably a positive A-plate.

The positive A-plate can be obtained, for example, by horizontally aligning the polymerizable liquid crystal compound represented by Formula (III).

The optically anisotropic layer may have a monolayer structure or a polylayer structure. In a case of a polylayer structure, an A-plate (for example, a positive A-plate) and a C-plate (for example, a positive C-plate) may be laminated.

In a case where the optically anisotropic layer has a polylayer structure, each layer corresponds to a layer formed by using the above-mentioned composition.

In the present specification, the positive A-plate is defined as follows. The positive A-plate (A-plate which is positive) satisfies the relationship of Expression (A1) in a case where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz. In addition, the positive A-plate has an Rth showing a positive value.

nx>ny≈nz Expression (A1)

Furthermore, the symbol “≈” encompasses not only a case where the both sides are completely the same as each other but also a case where the both sides are substantially the same as each other. The expression “substantially the same” means that, for example, a case where (ny−nz)×d (in which d is a thickness of a film) is −10 to 10 nm and preferably −5 to 5 nm is also included in “ny≈nz”.

In the present specification, the positive C-plate is defined as follows. The positive C-plate (C-plate which is positive) satisfies the relationship of Expression (A2) in a case where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz. In addition, the positive C-plate has an Rth showing a negative value.

nx≈ny<nz Expression (A2)

Furthermore, the symbol “≈” encompasses not only a case where the both sides are completely the same as each other but also a case where the both sides are substantially the same as each other. The expression “substantially the same” means that, for example, a case where (nx−ny)×d (in which d is a thickness of a film) is −10 to 10 nm and preferably −5 to 5 nm is also included in “nx≈ny”.

In addition, in the positive C-plate, Re≈0 according to the above definition.

The thickness of the optically anisotropic layer is not particularly limited, and is preferably 0.5 to 10 μm and more preferably 1.0 to 5 μm from the viewpoint of thinning.

In addition, the relationship between the transmission axis of the polarizer layer and the slow axis of the optically anisotropic layer in the laminate is not particularly limited.

In a case where the laminate is applied to antireflection applications, it is preferable that the optically anisotropic layer is a λ/4 plate and the angle formed by the transmission axis of the polarizer layer and the slow axis of the optically anisotropic layer is in a range of 45°±10° (35° to 55°).

In addition, in a case where the laminate is applied to an optical compensation application for an oblique viewing angle of an in-plane switching (IPS) liquid crystal, it is preferable that the optically anisotropic layer has a polylayer structure of a positive A-plate and a positive C-plate, each of which is a λ/4 plate, and the angle formed by the transmission axis of the polarizer layer and the slow axis of the optically anisotropic layer is in a range of 0°±100 (−10° to 10°) or 90°±10° (80° to 100°).

The laminate according to the embodiment of the present invention may have members other than the pressure sensitive adhesive layer and the optically anisotropic layer.

<Alignment Layer>

The laminate according to the embodiment of the present invention may have an alignment layer for aligning the above-mentioned liquid crystal.

Examples of the method for forming an alignment layer include methods such as rubbing treatment of a film surface of an organic compound (preferably a polymer), oblique vapor deposition of an inorganic compound, formation of a layer having microgrooves, and accumulation of an organic compound (for example, w-tricosanoic acid, dioctadecylmethylammonium chloride, or methyl stearate) by the Langmuir-Blodgett (LB) film method. Further, there is also known an alignment layer capable of expressing an alignment function by application of an electric field, application of a magnetic field, or light irradiation.

Above all, in the present invention, an alignment layer formed by the rubbing treatment is preferable from the viewpoint of easy control of the pretilt angle of the alignment layer, and a photoalignment layer formed by light irradiation is more preferable from the viewpoint of the uniformity of alignment, which is important for the present invention.

The polymer material used for the alignment layer formed by the rubbing treatment has been described in a large number of documents, and a large number of commercially available products can be obtained. In the present invention, a polyvinyl alcohol or polyimide and a derivative thereof are preferably used. For the alignment layer, reference can be made to the description on page 43, line 24 to page 49, line 8 of WO01/88574A1.

The thickness of the alignment layer is preferably 0.01 to 10 μm and more preferably 0.01 to 2 μm.

The photoalignment layer of the laminate according to the embodiment of the present invention is not particularly limited, and a known photoalignment layer can be used.

The material for forming the photoalignment layer is not particularly limited, and a compound having a photo-aligned group is usually used. The compound may be a polymer having a repeating unit containing a photo-aligned group.

The photo-aligned group is a functional group capable of imparting anisotropy to a film upon irradiation with light. More specifically, the photo-aligned group is a group whose molecular structure can be changed upon irradiation with light (for example, linearly polarized light). Typically, the photo-aligned group refers to a group that causes at least one photoreaction selected from a photoisomerization reaction, a photodimerization reaction, and a photodecomposition reaction upon irradiation with light (for example, linearly polarized light).

Among these photo-aligned groups, a group that causes a photoisomerization reaction (a group having a structure capable of photoisomerization) and a group that causes a photodimerization reaction (a group having a structure capable of photodimerization) are preferable, and a group that causes a photodimerization reaction is more preferable.

The photoisomerization reaction refers to a reaction that causes stereoisomerization or structural isomerization by the action of light. As a substance that causes such a photoisomerization reaction, for example, a substance having an azobenzene structure (K. Ichimura et al., Mol. Cryst. Liq. Cryst., 298, page 221 (1997)), a substance having a hydrazono-β-ketoester structure (S. Yamamura et al., Liquid Crystals, Vol. 13, No. 2, page 189 (1993)), a substance having a stilbene structure (J. G. Victor and J. M. Torkelson, Macromolecules, 20, page 2241 (1987)), and a substance having a spiropyran structure (K. Ichimura et al., Chemistry Letters, page 1063 (1992); K. Ichimura et al., Thin Solid Films, Vol. 235, page 101 (1993)) are known.

The group that causes the photoisomerization reaction is preferably a group containing a C═C bond or an N═N bond that causes a photoisomerization reaction, examples of which include a group having an azobenzene structure (skeleton), a group having a hydrazono-β-ketoester structure (skeleton), a group having a stilbene structure (skeleton), and a group having a spiropyran structure (skeleton).

The photodimerization reaction refers to a reaction in which an addition reaction occurs between two groups by the action of light and then a ring structure is typically formed. As a substance that causes such photodimerization, for example, a substance having a cinnamic acid structure (M. Schadt et al., J. Appl. Phys., Vol. 31, No. 7, page 2155 (1992)), a substance having a coumarin structure (M. Schadt et al., Nature, Vol. 381, page 212 (1996)), a substance having a chalcone structure (Toshihiro Ogawa et al., Pre-Text of Liquid Crystal Discussion Meeting, 2AB03 (1997)), and a substance having a benzophenone structure (Y. K. Jang et al., SID Int. Symposium Digest, P-53 (1997)) are known.

Examples of the group that causes the photodimerization reaction include a group having a cinnamic acid (cinnamoyl) structure (skeleton), a group having a coumarin structure (skeleton), a group having a chalcone structure (skeleton), a benzophenone structure (skeleton), and a group having an anthracene structure (skeleton). Among these groups, a group having a cinnamoyl structure or a group having a coumarin structure is preferable, and a group having a cinnamoyl structure is more preferable.

In addition, the compound having a photo-aligned group may further have a crosslinkable group.

The crosslinkable group is preferably a thermally crosslinkable group that causes a curing reaction by the action of heat or a photocrosslinkable group that causes a curing reaction by the action of light, and may be a crosslinkable group having both a thermally crosslinkable group and a photocrosslinkable group.

The crosslinkable group may be, for example, at least one selected from the group consisting of an epoxy group, an oxetanyl group, a group represented by —NH—CH₂—O—R (where R represents a hydrogen atom or an alkyl group having 1 to 20 carbon atoms), a group having an ethylenically unsaturated double bond, and a blocked isocyanate group. Of these, an epoxy group, an oxetanyl group, or a group having an ethylenically unsaturated double bond is preferable.

A 3-membered cyclic ether group is also referred to as the epoxy group, and the 4-membered cyclic ether group is also referred to as the oxetanyl group.

In addition, examples of the group having an ethylenically unsaturated double bond include a vinyl group, an allyl group, a styryl group, an acryloyl group, and a methacryloyl group, among which an acryloyl group or a methacryloyl group is preferable.

One of the suitable aspects of the photoalignment layer may be, for example, a photoalignment layer formed by using a composition for forming a photoalignment layer containing a polymer A having a repeating unit a1 containing a cinnamate group and a low-molecular-weight compound B having a cinnamate group and having a molecular weight smaller than that of the polymer A.

Here, in the present specification, the cinnamate group is a group having a cinnamic acid structure containing cinnamic acid or a derivative thereof as a basic skeleton, and refers to a group represented by Formula (I) or Formula (I).

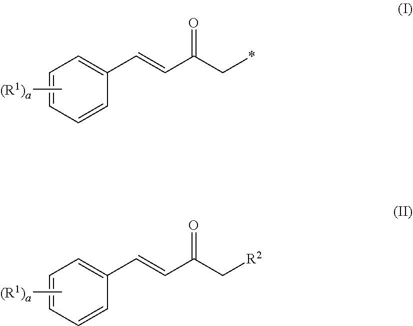

In the formulae, R¹ represents a hydrogen atom or a monovalent organic group, and R² represents a monovalent organic group. In Formula (I), a represents an integer of 0 to 5, and in Formula (I), a represents 0 to 4. In a case where a is 2 or more, a plurality of R¹'s may be the same or different from each other. * indicates that it is a bonding site.

The polymer A is not particularly limited as long as it is a polymer having the repeating unit a1 containing a cinnamate group, and a conventionally known polymer can be used.

The weight-average molecular weight of the polymer A is preferably 1000 to 500,000, more preferably 2000 to 300,000, and still more preferably 3,000 to 200,000.

Here, the weight-average molecular weight is defined as a value in terms of polystyrene (PS) by GPC measurement. The measurement by GPC in the present invention can be carried out using HLC-8220 GPC (manufactured by Tosoh Corporation) and using TSKgel Super HZM-H, HZ4000, and HZ2000 as columns.

Examples of the repeating unit a1 containing a cinnamate group contained in the polymer A include repeating units represented by Formulae (A1) to (A4).

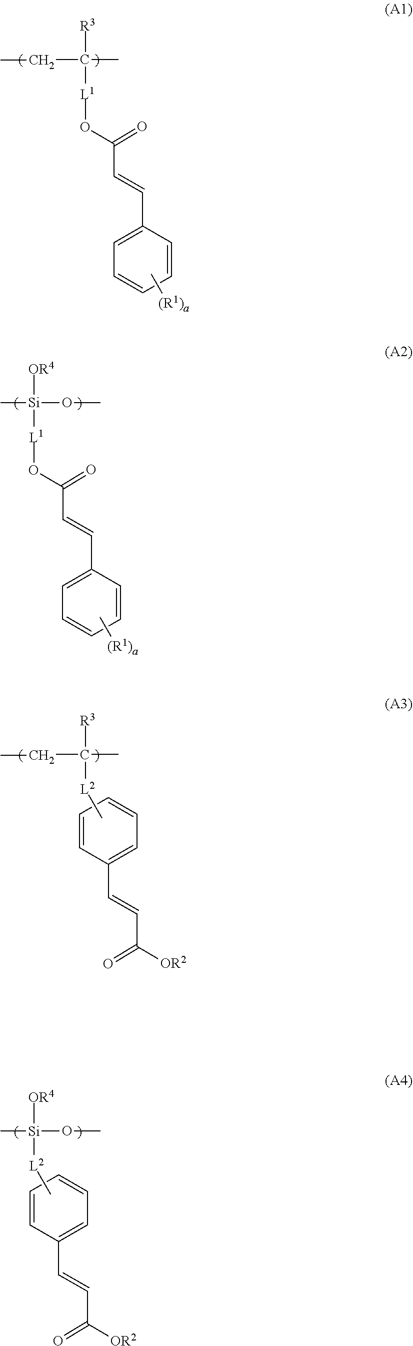

Here, in Formula (A1) and Formula (A3), R³ represents a hydrogen atom or a methyl group, and in Formula (A2) and Formula (A4), R⁴ represents an alkyl group having 1 to 6 carbon atoms.

In Formula (A1) and Formula (A2), L¹ represents a single bond or a divalent linking group, a represents an integer of 0 to 5, and R¹ represents a hydrogen atom or a monovalent organic group.

In Formula (A3) and Formula (A4), L² represents a divalent linking group and R² represents a monovalent organic group.

In addition, examples of L¹ include —CO—O-Ph-, —CO-Ph-Ph-, —CO—O—(CH₂)ₙ—, —CO—O—(CH₂)ₙ-Cy-, and —(CH₂)ₙ—Cy-. Here, Ph represents a divalent benzene ring (for example, a phenylene group) which may have a substituent, Cy represents a divalent cyclohexane ring (for example, cyclohexane-1,4-diyl group) which may have a substituent, and n represents an integer of 1 to 4.

In addition, examples of L² include —O—CO— and —O—CO—(CH₂)ₘ—O—. Here, m represents an integer of 1 to 6.

In addition, examples of the monovalent organic group of R^{t} include a chain-like or cyclic alkyl group having 1 to 20 carbon atoms, an alkoxy group having 1 to 20 carbon atoms, and an aryl group having 6 to 20 carbon atoms which may have a substituent.

In addition, examples of the monovalent organic group of R² include a chain-like or cyclic alkyl group having 1 to 20 carbon atoms and an aryl group having 6 to 20 carbon atoms which may have a substituent.

In addition, a is preferably 1 and R¹ is preferably in a para position.

In addition, examples of the substituent that the Ph, Cy, and aryl group may have include an alkyl group, an alkoxy group, a hydroxyl group, a carboxyl group, and an amino group.

The polymer A preferably further has a repeating unit a2 containing a crosslinkable group from the viewpoint of further improving the aligning properties of the liquid crystal compound and further improving the adhesiveness to the optically anisotropic layer.

The definition and suitable aspect of the crosslinkable group are as described above.

Above all, the repeating unit a2 containing a crosslinkable group is preferably a repeating unit having an epoxy group, an oxetanyl group, or a group having an ethylenically unsaturated double bond.

Preferred specific examples of the repeating unit having an epoxy group, an oxetanyl group, or a group having an ethylenically unsaturated double bond include the following repeating units. It should be noted that R³ and R⁴ have the same definition as in R³ and R⁴ in Formula (A1) and Formula (A2), respectively.

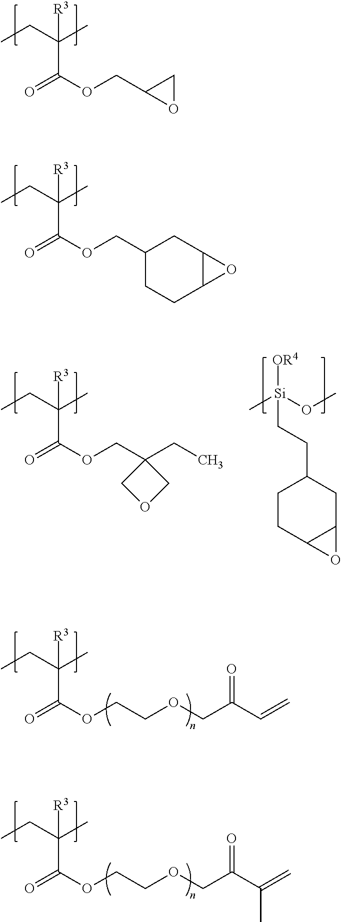

The polymer A may have a repeating unit other than the repeating unit a1 and the repeating unit a2.

Examples of the monomer forming the other repeating unit include an acrylic acid ester compound, a methacrylic acid ester compound, a maleimide compound, an acrylamide compound, an acrylonitrile, a maleic acid anhydride, a styrene compound, and a vinyl compound.

The content of the polymer A in the composition for forming a photoalignment layer is preferably 0.1 to 50 parts by mass and more preferably 0.5 to 10 parts by mass with respect to 100 parts by mass of the solvent in a case where an organic solvent which will be described later is contained.

The low-molecular-weight compound B is a compound having a cinnamate group and having a molecular weight smaller than that of the polymer A. Using the low-molecular-weight compound B improves the aligning properties of the photoalignment layer to be prepared.

The molecular weight of the low-molecular-weight compound B is preferably 200 to 500 and more preferably 200 to 400, from the viewpoint of further improving the aligning properties of the photoalignment layer.

Examples of the low-molecular-weight compound B include a compound represented by Formula (B1).

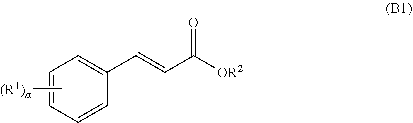

In Formula (B1), a represents an integer of 0 to 5, R¹ represents a hydrogen atom or a monovalent organic group, and R² represents a monovalent organic group. In a case where a is 2 or more, a plurality of R¹'s may be the same or different from each other.

In addition, examples of the monovalent organic group of R¹ include a chain-like or cyclic alkyl group having 1 to 20 carbon atoms, an alkoxy group having 1 to 20 carbon atoms, and an aryl group having 6 to 20 carbon atoms which may have a substituent, among which an alkoxy group having 1 to 20 carbon atoms is preferable, an alkoxy group having 1 to 6 carbon atoms is more preferable, and a methoxy group or an ethoxy group is still more preferable.

In addition, examples of the monovalent organic group of R² include a chain-like or cyclic alkyl group having 1 to 20 carbon atoms and an aryl group having 6 to 20 carbon atoms which may have a substituent, among which a chain-like alkyl group having 1 to 20 carbon atoms is preferable, and a branched alkyl group having 1 to 10 carbon atoms is more preferable.

In addition, a is preferably 1 and R¹ is preferably in a para position.

In addition, examples of the substituent that the aryl group may have include an alkyl group, an alkoxy group, a hydroxyl group, a carboxyl group, and an amino group.

The content of the low-molecular-weight compound B in the composition for forming a photoalignment layer is preferably 10% to 500% by mass and more preferably 30% to 300% by mass with respect to the mass of the repeating unit a1 of the polymer A.

The composition for forming a photoalignment layer preferably contains a crosslinking agent C having a crosslinkable group in addition to the polymer A having the repeating unit a2 containing a crosslinkable group, from the viewpoint of further improving the aligning properties.

The molecular weight of the crosslinking agent C is preferably 1,000 or less and more preferably 100 to 500.

Examples of the crosslinking agent C include a compound having two or more epoxy groups or oxetanyl groups in a molecule thereof, a blocked isocyanate compound (a compound having a protected isocyanato group), and an alkoxymethyl group-containing compound.

Of these, a compound having two or more epoxy groups or oxetanyl groups in a molecule thereof, or a blocked isocyanate compound is preferable.

In a case where the composition for forming a photoalignment layer contains the crosslinking agent C, the content of the crosslinking agent C is preferably 1 to 1,000 parts by mass and more preferably 10 to 500 parts by mass with respect to 100 parts by mass of the repeating unit a1 of the polymer A.

The composition for forming a photoalignment layer preferably contains a solvent, from the viewpoint of workability for preparing the photoalignment layer. Examples of the solvent include water and an organic solvent.

Examples of the organic solvent include ketones (for example, acetone, 2-butanone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethyl formamide and dimethyl acetamide).

The solvents may be used alone or in combination of two or more thereof.

The composition for forming a photoalignment layer may contain components other than the above-mentioned components, examples of which include a crosslinking catalyst, an adhesion improver, a leveling agent, a surfactant, and a plasticizer.

(Method for Forming Photoalignment Layer)

The method for forming a photoalignment layer is not particularly limited. For example, the photoalignment layer can be produced by a production method including a coating step of coating the above-mentioned composition for forming a photoalignment layer on a surface of a support and a light irradiation step of irradiating the coating film of the composition for forming a photoalignment layer with polarized light or with non-polarized light from an oblique direction with respect to the surface of the coating film.

Examples of the support include a glass substrate and a polymer film.

Examples of the polymer film material include cellulose-based polymers; acrylic polymers; thermoplastic norbornene-based polymers; polycarbonate-based polymers; polyester-based polymers such as polyethylene terephthalate and polyethylene naphthalate; styrene-based polymers such as polystyrene and acrylonitrile-styrene copolymer; polyolefin-based polymers such as polyethylene, polypropylene, and ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; allylate-based polymers; polyoxymethylene-based polymers; epoxy-based polymers; and polymers in which these polymers are mixed.

The thickness of the support is not particularly limited, and is preferably 5 to 60 μm and more preferably 5 to 30 μm.

<Polarizer Layer>

The laminate preferably has a polarizer layer (light absorption anisotropic layer). The polarizer layer is a so-called linear polarizer having a function of converting light into specific linearly polarized light.

The polarizer layer generally includes, but is not limited to, a polyvinyl alcohol-based resin and a dichroic substance.

The polyvinyl alcohol-based resin is a resin containing a repeating unit of —CH₂—CHOH—, and examples thereof include a polyvinyl alcohol and an ethylene-vinyl alcohol copolymer.

The polyvinyl alcohol-based resin can be obtained, for example, by saponifying a polyvinyl acetate-based resin. Examples of the polyvinyl acetate-based resin include polyvinyl acetate, which is a homopolymer of vinyl acetate, and a copolymer of vinyl acetate and another monomer copolymerizable therewith.

Examples of the other monomer copolymerizable with vinyl acetate include unsaturated carboxylic acids, olefins, vinyl ethers, unsaturated sulfonic acids, and acrylamides having an ammonium group.

The saponification degree of the polyvinyl alcohol-based resin is not particularly limited, and is preferably 85 to 100 mol % and more preferably 95.0 to 99.95 mol %. The saponification degree can be determined according to JIS K 6726-1994.

The average degree of polymerization of the polyvinyl alcohol-based resin is not particularly limited, and is preferably 100 to 10,000 and more preferably 1,500 to 8,000. The average degree of polymerization can be determined according to JIS K 6726-1994 in the same manner as the saponification degree.

The content of the polyvinyl alcohol-based resin in the polarizer layer is not particularly limited, and it is preferable that the polyvinyl alcohol-based resin is contained as the main component in the polarizer layer. The main component means that the content of the polyvinyl alcohol-based resin is 50% by mass or more with respect to the total mass of the polarizer layer. The content of the polyvinyl alcohol-based resin is preferably 90% by mass or more with respect to the total mass of the polarizer layer. The upper limit of the content of the polyvinyl alcohol-based resin is not particularly limited, and is often 99.9% by mass or less.

The polarizer layer preferably further contains a dichroic substance. The dichroic substance is preferably iodine, and an organic dye (dichroic coloring agent) can also be used. That is, it is preferable that the polarizer contains a polyvinyl alcohol-based resin as a main component and iodine as a dichroic substance.

The method for producing the polarizer layer is not particularly limited, and a known method can be mentioned. For example, there is a method of adsorbing a dichroic substance on a substrate containing a polyvinyl alcohol-based resin and stretching the thus-treated substrate.

The thickness of the polarizer layer is not particularly limited, and is often 20 μm or less and more often 15 μm or less. The lower limit of the thickness of the polarizer layer is not particularly limited, and is often 2 μm or more and more often 3 μm or more. For example, the thickness of the polarizer layer is preferably 2 to 15 μm.

It is also a preferred aspect that the polarizer layer of the laminate according to the embodiment of the present invention contains a dichroic coloring agent.

The dichroic coloring agent is not particularly limited, and a conventionally known dichroic coloring agent can be used.

Examples of the dichroic coloring agent include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-014883A, paragraphs [0012] to [0029] of JP2013-109090A, paragraphs [0009] to [0017] of JP2013-101328A, paragraphs [0051] to [0065] of JP2013-037353A, paragraphs [0049] to [0073] of JP2012-063387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0051] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0022] to [0080] of JP2015-001425, paragraphs [0005] to [0051] of JP2016-006502, paragraphs [0005] to [0041] of WO2016/060173A, paragraphs [0008] to [0062] of WO 2016/136561A, paragraphs [0014] to [0033] of JP2016-044909, paragraphs [0014] to [0033] of JP2016-044910, paragraphs [0013] to [0037] of JP2016-095907, and paragraphs [0014] to [0034] of JP2017-045296.

In the present invention, two or more dichroic coloring agents may be used in combination. For example, it is preferable to use at least one dichroic coloring agent having a maximal absorption wavelength in a wavelength range of 370 to 550 nm and at least one dichroic coloring agent having a maximal absorption wavelength in a wavelength range of 500 to 700 nm in combination.

The dichroic coloring agent preferably has a crosslinkable group.

Examples of the crosslinkable group include an acryloyl group, a methacryloyl group, an epoxy group, an oxetanyl group, and a styryl group, among which an acryloyl group or a methacryloyl group is preferable.

In a case where the polarizer layer contains a dichroic coloring agent, the content of the dichroic coloring agent is preferably 2% to 40% by mass and more preferably 5% to 30% by mass with respect to the total mass (solid content) of the polarizer layer.

Since the dichroic coloring agent is an organic compound and therefore may be decomposed by light, a layer configuration in which a specific compound is present on the outside light side of the layer in which the dichroic coloring agent is present is preferable.

Since the light resistance of the dichroic coloring agent is inferior particularly in a case where the content of the dichroic coloring agent with respect to the solid content is 10% by mass or less, it is more preferable that a sufficient amount of a specific compound is present on the outside light side of the layer in which the dichroic coloring agent is present.

The polarizer layer is preferably a layer formed by a coating method, and is specifically more preferably a layer formed by coating a composition containing a dichroic coloring agent and the like (hereinafter, also referred to simply as “composition for forming a light absorption anisotropic layer”).

In addition, as another name for the polarizer layer formed by coating, it is also referred to as a light absorption anisotropic layer below.

The composition for forming a light absorption anisotropic layer preferably contains a liquid crystal compound, from the viewpoint of aligning the dichroic coloring agent. The liquid crystal compound is a liquid crystal compound that does not exhibit dichroism.

The liquid crystal compound preferably exhibits a smectic alignment from the viewpoint of improving the alignment degree of the light absorption anisotropic layer.

Both a low molecular weight liquid crystal compound and a high molecular weight liquid crystal compound can be used as the liquid crystal compound. Here, the “low molecular weight liquid crystal compound” refers to a liquid crystal compound having no repeating unit in a chemical structure thereof. In addition, the “high molecular weight liquid crystal compound” refers to a liquid crystal compound having a repeating unit in a chemical structure thereof.

Examples of the low molecular weight liquid crystal compound include liquid crystal compounds described in JP2013-228706A.

Examples of the high molecular weight liquid crystal compound include thermotropic liquid crystalline polymers described in JP2011-237513A. In addition, the high molecular weight liquid crystal compound may have a crosslinkable group (for example, an acryloyl group and a methacryloyl group) at a terminal thereof.

The liquid crystal compounds may be used alone or in combination of two or more thereof.

The content of the liquid crystal compound is preferably 25 to 2,000 parts by mass, more preferably 33 to 1,000 parts by mass, and still more preferably 50 to 500 parts by mass with respect to 100 parts by mass of the content of the dichroic coloring agent in the composition for forming a light absorption anisotropic layer.

The composition for forming a light absorption anisotropic layer may contain a polymerization initiator, a solvent, and the like.

Specific examples of these components include those described in the above-mentioned liquid crystal composition.

Examples of the coating method of the composition for forming a light absorption anisotropic layer include known methods such as a roll coating method, a gravure printing method, a spin coating method, a wire bar coating method, an extrusion coating method, a direct gravure coating method, a reverse gravure coating method, a die-coating method, a spray method, and an ink jet method.

In a case where the composition for forming a light absorption anisotropic layer contains the above-mentioned dichroic coloring agent and liquid crystal compound, the composition may be subjected to an alignment treatment for aligning these components after coating.

The alignment treatment may have a drying step. Components such as a solvent can be removed from the coating film by the drying step. The drying step may be carried out by a method of allowing the coating film to stand at room temperature for a predetermined time (for example, natural drying), or by a method of heating and/or blowing air on the coating film.

In addition, the alignment treatment preferably has a heating step. As a result, the dichroic coloring agent contained in the coating film is more aligned, and therefore the alignment degree of the obtained light absorption anisotropic layer becomes higher. The heating step is preferably carried out at 10° C. to 250° C. and more preferably 25° C. to 190° C. from the viewpoint of manufacturing suitability and the like. In addition, the heating time is preferably 1 to 300 seconds and more preferably 1 to 60 seconds.

In addition, the alignment treatment may have a cooling step which is carried out after the heating step. The cooling step is a treatment of cooling the heated coating film to about room temperature (20° C. to 25° C.). As a result, the alignment of the dichroic coloring agent contained in the coating film is more fixed, and therefore the alignment degree of the obtained light absorption anisotropic layer becomes higher. The cooling means is not particularly limited and the cooling can be carried out by a known method.

In the present invention, the thickness of the light absorption anisotropic layer is not particularly limited, and is preferably 0.1 to 5.0 μm and more preferably 0.3 to 1.5 μm.

<Adhesive Layer>

The laminate according to the embodiment of the present invention may have an adhesive layer.

The adhesive contained in the adhesive layer exhibits adhesiveness by drying or reaction after bonding.

The adhesive is preferably a polyvinyl alcohol-based adhesive (PVA-based adhesive). The PVA-based adhesive develops adhesiveness by drying, and makes it possible to bond materials together.

Specific examples of the curable adhesive that develops adhesiveness by reaction include an active energy ray-curable adhesive such as a (meth)acrylate-based adhesive and a cationic polymerization curable adhesive. The (meth)acrylate means acrylate and/or methacrylate. Examples of the curable component in the (meth)acrylate-based adhesive include a compound having a (meth)acryloyl group and a compound having a vinyl group.

In addition, examples of the cationic polymerization curable adhesive include compounds having an epoxy group or an oxetanyl group. The compound having an epoxy group is not particularly limited as long as it is a compound having at least two epoxy groups in a molecule thereof, and various generally known curable epoxy compounds can be used. Examples of a preferred epoxy compound include a compound having at least two epoxy groups and at least one aromatic ring in a molecule thereof (aromatic epoxy compound), and a compound that has at least two epoxy groups in a molecule thereof, at least one of which is formed between two adjacent carbon atoms constituting an alicyclic ring (alicyclic epoxy compound).

<Pressure Sensitive Adhesive Layer>

The laminate according to the embodiment of the present invention may have a pressure sensitive adhesive layer containing no specific compound used in the present invention, from the viewpoint of bonding the above-mentioned optically anisotropic layer, polarizer layer, and other functional layers.

Examples of the pressure sensitive adhesive contained in the pressure sensitive adhesive layer include a rubber-based pressure sensitive adhesive, a (meth)acrylic pressure sensitive adhesive, a silicone-based pressure sensitive adhesive, an urethane-based pressure sensitive adhesive, a vinyl alkyl ether-based pressure sensitive adhesive, a polyvinyl alcohol-based pressure sensitive adhesive, a polyvinyl pyrrolidone-based pressure sensitive adhesive, a polyacrylamide-based pressure sensitive adhesive, and a cellulose-based pressure sensitive adhesive.

Of these, a (meth)acrylic pressure sensitive adhesive is preferable from the viewpoint of transparency, weather fastness, heat resistance, and the like.

The pressure sensitive adhesive layer can be formed by, for example, a method in which a solution of a pressure sensitive adhesive is coated and dried on a release sheet, and then transferred to a surface of a transparent resin layer; or a method in which a solution of a pressure sensitive adhesive is directly coated and dried on a surface of a transparent resin layer.

The solution of a pressure sensitive adhesive is prepared as a solution of about 10% to 40% by mass of the pressure sensitive adhesive in which the pressure sensitive adhesive is dissolved or dispersed in a solvent such as toluene or ethyl acetate.

Examples of the coating method include a roll coating method such as reverse coating or gravure coating, a spin coating method, a screen coating method, a fountain coating method, a dipping method, and a spray method.

In addition, examples of the release sheet include appropriate thin sheet bodies, for example, synthetic resin films such as polyethylene, polypropylene, and polyethylene terephthalate; rubber sheets; paper; cloth; nonwoven fabrics; networks; foamed sheets; and metal foils.

The thickness of the optional pressure sensitive adhesive layer is not particularly limited, and is preferably 3 to 50 μm, more preferably 4 to 40 μm, and still more preferably 5 to 30 μm.

The laminate according to the embodiment of the present invention may have a surface protective layer, in addition to the above-mentioned components.

The surface protective layer is a layer arranged on the outermost surface side of the laminate.

The configuration of the surface protective layer is not particularly limited, and may be, for example, a so-called transparent support or hard coat layer, or a laminate of the transparent support and the hard coat layer.

<Use>

In a case where the laminate according to the embodiment of the present invention has a polarizer layer, the laminate can be used as a polarizing element (polarizing plate), and can be used, for example, as a circularly polarizing plate having an antireflection function.

(Image Display Apparatus)

The image display apparatus according to the embodiment of the present invention has the above-mentioned laminate according to the embodiment of the present invention.

The display element used in the image display apparatus according to the embodiment of the present invention is not particularly limited, and examples thereof include a liquid crystal cell, an organic EL display panel, and a plasma display panel.

Of these, a liquid crystal cell or an organic EL display panel is preferable, and a liquid crystal cell is more preferable. That is, the image display apparatus according to the embodiment of the present invention is preferably a liquid crystal display device using a liquid crystal cell as the display element or an organic EL display device using an organic EL display panel as the display element, and more preferably a liquid crystal display device.

(Liquid Crystal Display Device)

The liquid crystal display device which is an example of the image display apparatus according to the embodiment of the present invention is a liquid crystal display device having the above-mentioned laminate according to the embodiment of the present invention and a liquid crystal cell.

In the present invention, with regard to the laminates provided on both sides of the liquid crystal cell, it is preferable that the laminate according to the embodiment of the present invention is used as a front-side polarizing element and it is more preferable that the laminate according to the embodiment of the present invention is used as a front-side polarizing element and a rear-side polarizing element.

Hereinafter, the liquid crystal cell constituting the liquid crystal display device will be described in detail.

The liquid crystal cell used for the liquid crystal display device is preferably in a vertical alignment (VA) mode, an optically compensated bend (OCB) mode, an in-plane-switching (IPS) mode, or a twisted nematic (TN) mode, but the present invention is not limited thereto.

In a TN mode liquid crystal cell, rod-like liquid crystalline molecules (rod-like liquid crystal compound) are substantially horizontally aligned in a case where no voltage is applied and are further twist-aligned at 60 to 120°. The TN mode liquid crystal cell is most often used as a color TFT liquid crystal display device and has been described in many documents.

In a VA mode liquid crystal cell, rod-like liquid crystalline molecules are substantially vertically aligned in a case where no voltage is applied. The concept of the VA mode liquid crystal cell includes (1) a narrowly-defined VA mode liquid crystal cell in which rod-like liquid crystalline molecules are substantially vertically aligned in a case where no voltage is applied and are substantially horizontally aligned in a case where a voltage is applied (described in JP1990-176625A (JP-H02-176625A)), (2) a multi-domain vertical alignment (MVA) mode liquid crystal cell in which the VA mode is made into multi-domains in order to expand a viewing angle (SID97, described in Digest of Tech. Papers (proceedings) 28 (1997) 845), (3) an axially symmetric aligned microcell (n-ASM) mode liquid crystal cell in which rod-like liquid crystalline molecules are substantially vertically aligned in a case where no voltage is applied and are twist-aligned in multi-domains in a case where a voltage is applied (described in proceedings of Japanese Liquid Crystal Conference, pp. 58 to 59 (1998)), and (4) a SURVIVAL mode liquid crystal cell (presented at Liquid Crystal Display (LCD) International 98). In addition, the liquid crystal cell may be any of a patterned vertical alignment (PVA) type, a photoalignment (optical alignment) type, and a polymer-sustained alignment (PSA) type. The details of these modes are described in JP2006-215326A and JP2008-538819A.

In an IPS mode liquid crystal cell, rod-like liquid crystalline molecules are aligned substantially parallel with respect to a substrate, and the liquid crystalline molecules respond in a planar manner in a case where a voltage parallel to the substrate surface is applied. The IPS mode displays black in a case where no voltage is applied, and absorption axes of a pair of upper and lower polarizing plates are orthogonal to each other. A method of reducing leakage light during black display in an oblique direction to improve a viewing angle using an optical compensation sheet is disclosed in JP1998-054982A (JP-H10-054982A), JP1999-202323A (JP-H11-202323A), JP1997-292522A (JP-H09-292522A), JP1999-133408A (JP-111-133408A), JP1999-305217A (JP-H11-305217A), and JP1998-307291A (JP-H10-307291A).

(Organic EL Display Device)

The organic EL display device which is an example of the image display apparatus according to the embodiment of the present invention is suitably an aspect of a display device having the above-mentioned laminate according to the embodiment of the present invention (including a pressure sensitive adhesive layer and a λ/4 plate) and an organic EL display panel in this order from the visual recognition side. In this case, a pressure sensitive adhesive layer provided as needed, a barrier layer provided as needed, a cured layer provided as needed, a polarizer layer, a pressure sensitive adhesive layer, and a λ/4 plate (optically anisotropic layer) are arranged in this order in the laminate from the visual recognition side.

In addition, the organic EL display panel is a display panel configured by using an organic EL display element in which an organic light emitting layer (organic EL layer) is interposed between electrodes (between a cathode and an anode). The configuration of the organic EL display panel is not particularly limited, and a known configuration is adopted.

### EXAMPLES

Hereinafter, the present invention will be specifically described with reference to Examples. The materials, reagents, substance amounts and ratios thereof, operations, and the like shown in the following examples can be appropriately changed without departing from the spirit of the present invention. Therefore, the present invention is not limited to the following examples.

### Polymerization Example 1

A mixed solution of ethyl acetate (81.8 parts by mass) as a solvent, butyl acrylate (70.4 parts by mass), methyl acrylate (20.0 parts by mass), and 2-phenoxyethyl acrylate (8.0 parts by mass) as a monomer (A-1), and 2-hydroxyethyl acrylate (1.0 parts by mass) and acrylic acid (0.6 parts by mass) as a monomer (A-2) was charged in a reaction container equipped with a cooling pipe, a nitrogen introduction pipe, a thermometer, and a stirrer, and the internal temperature of the reaction container was raised to 55° C. while substituting the air in the reaction container with nitrogen gas to make it oxygen-free. Then, a total solution of 2,2′-azobisisobutyronitrile (polymerization initiator, 0.14 parts by mass) dissolved in ethyl acetate (10 parts by mass) was added to the mixed solution. After the addition of the polymerization initiator, the temperature was maintained at this temperature for 1 hour, and then ethyl acetate was continuously added into the reaction container at an addition rate of 17.3 parts by mass/hr while maintaining the internal temperature at 54° C. to 56° C. In a case where the concentration of the produced acrylic resin reached 35% by mass, the addition of ethyl acetate was stopped, and the temperature was maintained at this temperature until 12 hours had passed from the start of the addition of ethyl acetate. Finally, ethyl acetate was added to adjust the concentration of the acrylic resin to 20% by mass to prepare an ethyl acetate solution of the acrylic resin.

The obtained acrylic resin had a weight-average molecular weight Mw of 1,420,000 in terms of polystyrene and Mw/Mn of 5.2, as measured by GPC. The obtained acrylic resin is referred to as acrylic resin A.

### Polymerization Example 2

A mixed solution of ethyl acetate (81.8 parts by mass) as a solvent, butyl acrylate (96.0 parts by mass) as a monomer (A-1), and acrylic acid (4.0 parts by mass) as a monomer (A-2) was charged in a reaction container equipped with a cooling pipe, a nitrogen introduction pipe, a thermometer, and a stirrer, and the internal temperature of the reaction container was raised to 55° C. while substituting the air in the reaction container with nitrogen gas to make it oxygen-free. Then, a total solution of 2,2′-azobisisobutyronitrile (polymerization initiator, 0.14 parts by mass) dissolved in ethyl acetate (10 parts by mass) was added to the mixed solution. After the addition of the polymerization initiator, the temperature was maintained at this temperature for 1 hour, and then ethyl acetate was continuously added into the reaction container at an addition rate of 17.3 parts by mass/hr while maintaining the internal temperature at 54° C. to 56° C. In a case where the concentration of the produced acrylic resin reached 35% by mass, the addition of ethyl acetate was stopped, and the temperature was maintained at this temperature until 12 hours had passed from the start of the addition of ethyl acetate. Finally, ethyl acetate was added to adjust the concentration of the acrylic resin to 20% by mass to prepare an ethyl acetate solution of the acrylic resin.

The obtained acrylic resin had a weight-average molecular weight Mw of 756,000 in terms of polystyrene and Mw/Mn of 4.1, as measured by GPC. The obtained acrylic resin is referred to as acrylic resin B.

<Preparation of Pressure-Sensitive Adhesive Sheets 1 to 17>

As shown in Table 1 below, an acrylic resin (“A” represents an acrylic resin A, and “B” represents an acrylic resin B), a crosslinking agent, a silane-based compound, and a specific compound were mixed to prepare compositions 1 to 17 for forming a pressure sensitive adhesive layer, respectively. The number of parts to be added of each component is shown in Table 1 as the number of parts by mass with respect to 100 parts by mass of the solid content in the acrylic resin prepared in each of Polymerization Examples 1 and 2. Here, 2-butanone was added to the components shown in Table 1 such that the concentration of solid contents of each of compositions 1 to 17 for forming a pressure sensitive adhesive layer was 14% by mass. Then, the obtained mixture was stirred and mixed using a stirrer (THREE-ONE MOTOR BL-300, manufactured by Yamato Scientific Co., Ltd.) at 300 rpm for 30 minutes to prepare compositions 1 to 17 for forming a pressure sensitive adhesive layer.

The various components used are shown below.

Specific compounds UV-1 to UV-7

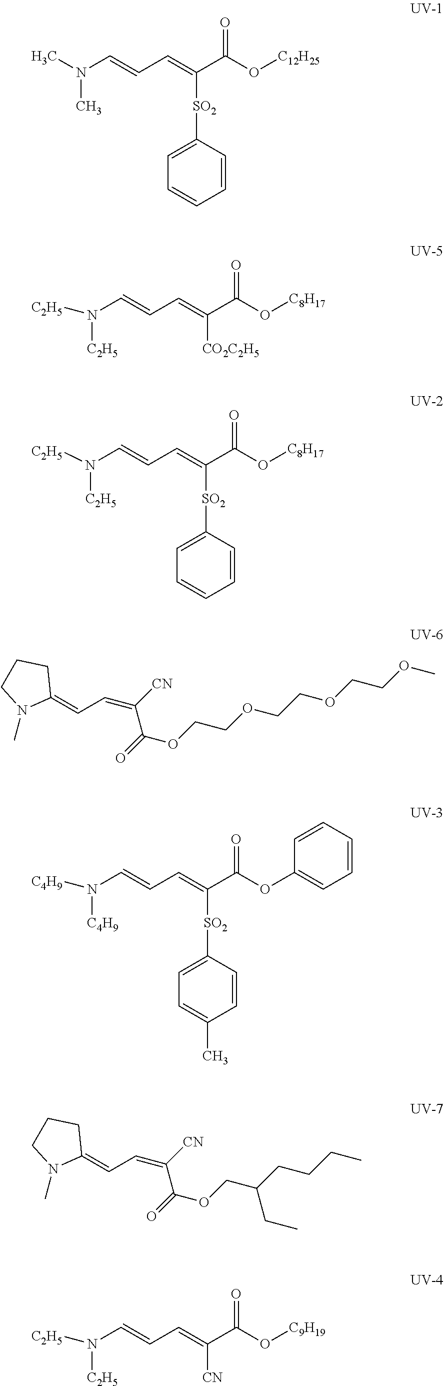

(Crosslinking Agent)

CORONATE L: an ethyl acetate solution of a trimethylolpropane adduct of tolylene diisocyanate (concentration of solid contents: 75% by mass), manufactured by Nippon Polyurethane Industry Co., Ltd.

(Silane-Based Compound)

KBM-403: 3-glycidoxypropyltrimethoxysilane, manufactured by Shin-Etsu Chemical Co., Ltd.

Each of compositions 1 to 17 for forming a pressure sensitive adhesive layer prepared above was coated on a release-treated surface of a polyethylene terephthalate film (SP-PLR382050, manufactured by Lintec Corporation, hereinafter referred to simply as a separator) that has been subjected to a release treatment using an applicator such that the thickness of the pressure sensitive adhesive layer after drying was 5 μm. This was followed by drying at 100° C. for 1 minute to prepare pressure-sensitive adhesive sheets 1 to 17.

(Evaluation of Crystal Precipitation)

The pressure-sensitive adhesive sheets 1 to 17 were subjected to a heat shock resistance test that repeats a process of heating to 70° C., lowering to −40° C., and then raising to 70° C. as one cycle (30 minutes) for a total of 100 cycles. The pressure-sensitive adhesive sheet after the test was visually observed, and the presence or absence of crystal precipitation in the sheet was evaluated according to the following standards. The evaluation results are shown in Table 1.

[Evaluation Standards for Crystal Precipitation]

A: Almost no change in appearance such as turbidity due to crystal precipitation is observed.

B: Changes in appearance such as turbidity due to crystal precipitation are significantly observed.

TABLE 1

| | | | Crosslinking | | | | Crystal |
|---|---|---|---|---|---|---|---|
| Pressure-sensitive | Acrylic resin | | agent | Silane compound | Specific compound | | precipitation |
| adhesive sheet | Designation | Amount | Amount | Amount | Designation | Amount | evaluation |
| 1 | A | 100 | 1 | 0.2 | UV-1 | 2.8 | A |
| 2 | B | 100 | 1 | 0.2 | UV-1 | 5.5 | A |
| 3 | A | 100 | 1 | 0.2 | UV-1 | 11 | A |
| 4 | B | 100 | 1 | 0.2 | UV-1 | 12 | A |
| 5 | A | 100 | 1 | 0.2 | UV-2 | 1.8 | A |
| 6 | B | 100 | 1 | 0.2 | UV-2 | 2.8 | A |
| 7 | B | 100 | 1 | 0.2 | UV-2 | 5.5 | A |
| 8 | B | 100 | 1 | 0.2 | UV-3 | 8.6 | A |
| 9 | B | 100 | 1 | 0.2 | UV-4 | 1.8 | A |
| 10 | B | 100 | 1 | 0.2 | UV-4 | 5.2 | B |
| 11 | B | 100 | 1 | 0.2 | UV-5 | 1.5 | A |
| 12 | B | 100 | 1 | 0.2 | UV-5 | 5.1 | B |
| 13 | B | 100 | 1 | 0.2 | UV-6 | 1.4 | A |
| 14 | B | 100 | 1 | 0.2 | UV-6 | 4.5 | B |
| 15 | B | 100 | 1 | 0.2 | UV-7 | 1.3 | A |
| 16 | B | 100 | 1 | 0.2 | UV-7 | 4.8 | B |
| 17 | B | 100 | 1 | 0.2 | — | None | A |

The specific compounds of UV-1 to UV-3 used in the present invention did not cause crystal precipitation even in a case where the compound was used in an amount of 5.5 parts by mass or more with respect to 100 parts by mass of the acrylic resin, but the specific compounds of UV-4 to WV-7 caused crystal precipitation even in a case where the compound was used in an amount of less than 5.5 parts by mass.

Although crystal precipitation was suppressed in the pressure-sensitive adhesive sheet 9, the pressure-sensitive adhesive sheet 11, the pressure-sensitive adhesive sheet 13, and the pressure-sensitive adhesive sheet 15, the light resistance was not sufficient as shown in Table 2 which will be given later.

### Preparation Examples 1 to 13

(Preparation of Optically Anisotropic Film 1)

The following composition was put into a mixing tank and stirred to prepare a cellulose acetate solution to be used as a core layer cellulose acylate dope.

Core layer cellulose acylate dope

| | | |
|---|---|---|
| Cellulose acetate having an acetyl substitution | 100 | parts by mass |
| degree of 2.88 | | |
| Polyester compound B described in Examples of | 12 | parts by mass |
| JP2015-227955A | | |
| Compound G shown below | 2 | parts by mass |
| Methylene chloride (first solvent) | 430 | parts by mass |
| Methanol (second solvent) | 64 | parts by mass |

Compound G

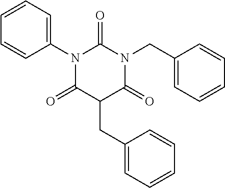 [SMILES: O=C1C(Cc2ccccc2)C(=O)N(c2ccccc2)C(=O)N1Cc1ccccc1]

10 parts by mass of the following matte agent solution were added to 90 parts by mass of the core layer cellulose acylate dope to prepare a cellulose acetate solution to be used as an outer layer cellulose acylate dope.

Matte agent solution

| | | |
|---|---|---|
| Silica particles having an | 2 | parts by mass |
| average particle size of 20 nm | | |
| (AEROSIL R972, manufactured | | |
| by Nippon Aerosil Co., Ltd.) | | |
| Methylene chloride (first solvent) | 76 | parts by mass |
| Methanol (second solvent) | 11 | parts by mass |
| Core layer cellulose acylate | 1 | parts by mass |
| dope described above | | |

After filtering the core layer cellulose acylate dope and the outer layer cellulose acylate dope through a filter paper having an average pore size of 34 μm and a sintered metal filter having an average pore size of 10 μm, the core layer cellulose acylate dope and the outer layer cellulose acylate dope on both sides thereof were simultaneously cast in three layers on a drum at 20° C. from a casting port (band casting machine). The film was peeled off from the drum with a solvent content of about 20% by mass, both ends of the film in a width direction were fixed with tenter clips, and the film was dried while being stretched in a transverse direction at a stretching ratio of 1.1 times. Then, the obtained film was transported between rolls of a heat treatment apparatus to be further dried to prepare a transparent resin film 1 having a thickness of 40 μm. The Re (550) of the obtained transparent resin film 1 was 0 nm.

A coating liquid 1 for forming an alignment layer, which will be described later, was continuously coated on the transparent resin film 1 with a wire bar of #2.4. The support on which the coating film was formed was dried with hot air at 140° C. for 120 seconds, and then the coating film was irradiated with polarized ultraviolet rays (10 mJ/cm², using an ultra-high pressure mercury lamp) to form a photoalignment layer 1, thereby obtaining a TAC film with the photoalignment layer 1.

Coating liquid 1 for forming an alignment layer

| | | |
|---|---|---|
| Polymer PA-1 shown below | 100.00 | parts by mass |
| Acid generator PAG-1 shown below | 1.00 | parts by mass |
| Isopropyl alcohol | 16.50 | parts by mass |
| Butyl acetate | 1072.00 | parts by mass |
| Methyl ethyl ketone | 268.00 | parts by mass |

Polymer PA-1 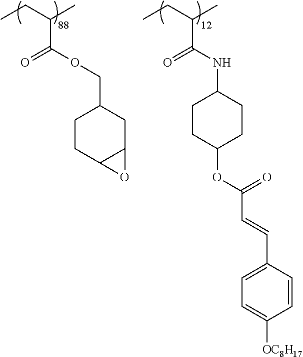
Acid generator PAG-1

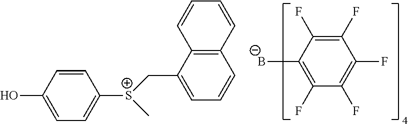

Subsequently, the following coating liquid A-1 for forming a positive A-plate was prepared.

Coating liquid A-1 for forming a positive A-plate

| | | |
|---|---|---|
| Liquid crystal compound L-1 shown below | 70.00 | parts by mass |
| Liquid crystal compound L-2 shown below | 30.00 | parts by mass |
| Polymerization initiator S-1 shown below | 0.60 | parts by mass |
| Leveling agent (compound T-1 shown below) | 0.10 | parts by mass |
| Methyl ethyl ketone (solvent) | 200.00 | parts by mass |
| Cyclopentanone (solvent | 200.00 | parts by mass |

Liquid crystal compound L-1 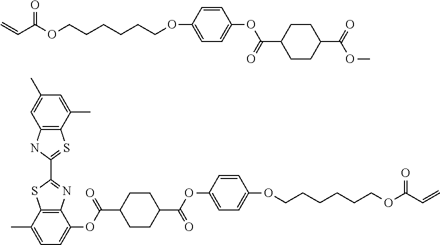
Liquid crystal compound L-2

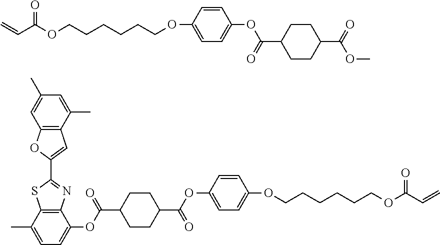

The leveling agent LT-1 (The numerical value in each repeating unit represents the content (% by mass) with respect to all the repeating units, the content of the repeating unit on the left side is 32.5% by mass, and the content of the repeating unit on the right side is 67.5% by mass.)

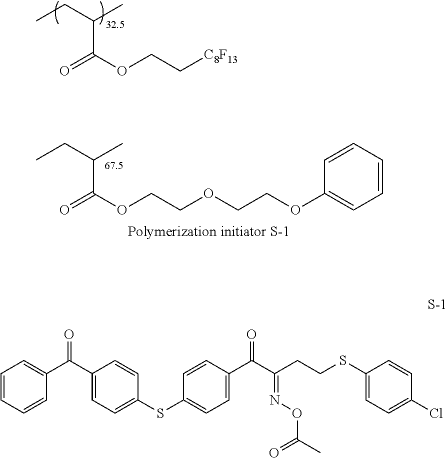

Next, the coating liquid A-1 for forming a positive A-plate was coated on the photoalignment layer 1 using a bar coater. The obtained coating film was heat-aged at a film surface temperature of 100° C. for 20 seconds, cooled to 90° C., and then irradiated with ultraviolet rays of 300 mJ/cm² using an air-cooled metal halide lamp (manufactured by Eye Graphics Co., Ltd.) under air to immobilize the nematic alignment state to form an optically anisotropic layer 1 (positive A-plate A1), thereby obtaining an optically anisotropic film 1.

The formed optically anisotropic layer 1 had a Re (550) of 150 nm, a Re (550)/Re (450) of 1.18, a Re (650)/Re (550) of 1.03 and a tilt angle of an optical axis of 0°, and the liquid crystal compound had a homogeneous alignment.

(Preparation of Optically Anisotropic Film 2)

An optically anisotropic film 2 was prepared according to the same procedure as in the section of (Preparation of optically anisotropic film 1), except that a coating liquid A-2 for forming a positive A-plate shown below was used instead of the coating liquid A-1 for forming a positive A-plate.

Coating liquid A-2 for forming a positive A-plate

| | | |
|---|---|---|
| Liquid crystal compound L-3 shown below | 100.00 | parts by mass |
| Polymerization initiator S-1 described above | 0.60 | parts by mass |
| Leveling agent (compound T-1 described above) | 0.10 | parts by mass |
| Methyl ethyl ketone (solvent) | 200.00 | parts by mass |
| Cyclopentanone (solvent) | 200.00 | parts by mass |

Liquid crystal compound L-3

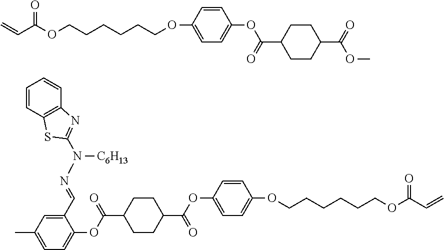

(Preparation of Optically Anisotropic Film 3)

An optically anisotropic film 3 was prepared according to the same procedure as in the section of (Preparation of optically anisotropic film 1), except that a coating liquid A-3 for forming a positive A-plate shown below was used instead of the coating liquid A-1 for forming a positive A-plate.

Coating liquid A-3 for forming a positive A-plate

| | | |
|---|---|---|
| Liquid crystal compound L-4 shown below | 100.00 | parts by mass |
| Polymerization initiator S-1 described above | 0.60 | parts by mass |
| Leveling agent (compound T-1 described above) | 0.10 | parts by mass |
| Methyl ethyl ketone (solvent) | 200.00 | parts by mass |
| Cyclopentanone (solvent) | 200.00 | parts by mass |

Liquid crystal compound L-4

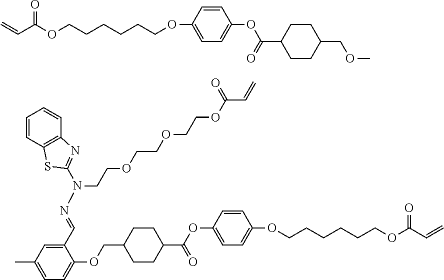

(Preparation of Optically Anisotropic Film 4)

An optically anisotropic film 4 was prepared according to the same procedure as in the section of (Preparation of optically anisotropic film 1), except that a coating liquid A-4 for forming a positive A-plate shown below was used instead of the coating liquid A-1 for forming a positive A-plate.

Coating liquid A-4 for forming a positive A-plate

| | | |
|---|---|---|
| Liquid crystal compound L-5 shown below | 25.00 | parts by mass |
| Liquid crystal compound L-6 shown below | 25.00 | parts by mass |
| Liquid crystal compound L-7 shown below | 25.00 | parts by mass |
| Liquid crystal compound L-8 shown below | 25.00 | parts by mass |
| Polymerization initiator S-1 described above | 0.60 | parts by mass |
| Leveling agent (compound T-1 described above) | 0.10 | parts by mass |
| Methyl ethyl ketone (solvent) | 200.00 | parts by mass |
| Cyclopentanone (solvent) | 200.00 | parts by mass |

Liquid crystal compound L-5 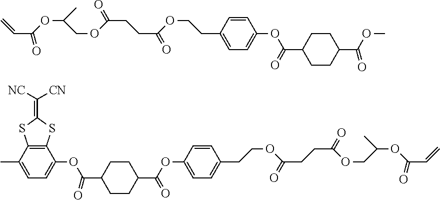
Liquid crystal compound L-6 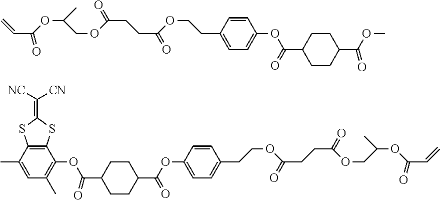
Liquid crystal compound L-7 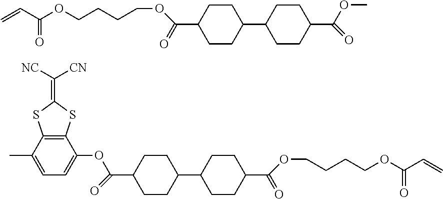
Liquid crystal compound L-8

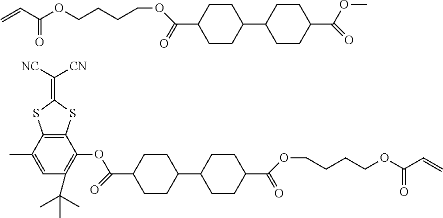

(Preparation of Pressure-Sensitive Adhesive Sheet)

Each of the pressure-sensitive adhesive sheets was prepared according to the same procedure as in the section of <Preparation of pressure-sensitive adhesive sheets 1 to 17>, except that the type of the acrylic resin (“A” represents the acrylic resin A, and “B” represents the acrylic resin B), the amount of the specific compound used, and the thickness of the pressure-sensitive adhesive sheet were adjusted as shown in Table 2.

The amount of the specific compound shown in Table 2 represents parts by mass with respect to 100 parts by mass of the solid content in the acrylic resin.

Next, each of the obtained pressure-sensitive adhesive sheets was attached to the optically anisotropic layer side of each of the optically anisotropic films 1 to 4 to prepare laminates 1B to 13B.

(Preparation of Polarizing Plate)

A polyvinyl alcohol film having a thickness of 30 μm (average degree of polymerization of about 2,400, saponification degree of 99.9 mol % or more) was monoaxially stretched about 4 times by dry stretching, immersed in pure water at 40° C. for 40 seconds while maintaining a state of tension, and then immersed in a dyeing aqueous solution having a mass ratio of iodine/potassium iodide/water of 0.044/5.7/100 at 28° C. for 30 seconds for a dyeing treatment. Then, the obtained film was immersed in a boric acid aqueous solution having a mass ratio of potassium iodide/boric acid/water of 11.0/6.2/100 at 70° C. for 120 seconds. Subsequently, the obtained film was washed with pure water at 8° C. for 15 seconds, and then dried at 60° C. for 50 seconds and then at 75° C. for 20 seconds while being held at a tension of 300 N to obtain a polarizer layer having a thickness of 12 μm in which iodine was adsorbed and aligned on the polyvinyl alcohol film.

A water-based adhesive was injected between the obtained polarizer layer and the cycloolefin polymer film (COP film, ZF-4 manufactured by Zeon Corporation (having no UV absorption characteristics), thickness: 30 μm), followed by bonding with a nip roll. While maintaining the tension of the obtained bonded structure at 430 N/m, the bonded structure was dried at 60° C. for 2 minutes to obtain a 42 μm polarizing plate having a COP film as a protective film on one side thereof.

The water-based adhesive was prepared by adding a carboxyl group-modified polyvinyl alcohol (KURARAY POVAL KL318, manufactured by Kuraray Co., Ltd.) (3 parts by mass) and a water-soluble polyamide epoxy resin (SUMIREZ RESIN 650; an aqueous solution having a concentration of solid contents of 30% by mass, manufactured by Sumika Chemtex Co., Ltd.) (1.5 parts by mass) to water (100 parts by mass).

(Preparation of Laminates 1 to 13)

The polarizer layer side of the above prepared polarizing plate on which the COP film was arranged on one side thereof was corona-treated, and the pressure sensitive adhesive layer of each of the laminates 1B to 13B was bonded to prepare laminates 1 to 13.

At this time, the bonding was carried out such that the angle formed by the absorption axis of the polarizer layer and the slow axis of the positive A-plate contained in the optically anisotropic film contained in each of the laminates 1B to 13B was 45°.

(Evaluation of Light Resistance)

Under the following light resistance evaluation conditions, the light resistance was evaluated by irradiation with light from the COP film side of the laminates 1 to 13.

Testing machine: low temperature cycle xenon weather meter (XL75, manufactured by Suga Test Instruments Co., Ltd.)

Irradiation conditions: 100 lux (40 W/m²)

Temperature and humidity: 23° C., 50% RH

Irradiation time: 5 days

Using an AxoScan (OPMF-1, manufactured by Axometrics, Inc.), the durability of the in-plane retardation (Re) at a wavelength of 550 nm was evaluated by the following indicator.

AA: The rate of change of Re is less than 1.5%

A: The rate of change of Re is 1.5% or more and less than 3%

B: The rate of change of Re is 3% or more

In Table 2, “Liquid crystal” in the column of “Optically anisotropic layer” represents the type of liquid crystal compound used. All of the liquid crystal compounds used correspond to liquid crystal compounds exhibiting reverse wavelength dispersibility.

TABLE 2

| | Pressure sensitive adhesive layer | | | | Optically | Light | |
|---|---|---|---|---|---|---|---|
| | Thickness | Acrylic | Specific compound | | anisotropic layer | resistance | |
| Laminate | (μm) | resin | Designation | Amount | Liquid crystal | evaluation | Remarks |
| 1 | 5 | B | UV-1 | 5.5 | L-1/L-2 | A | Inventive |
| 2 | 5 | B | UV-2 | 5.5 | L-1/L-2 | A | Inventive |
| 3 | 10 | B | UV-2 | 2.8 | L-1/L-2 | A | Inventive |
| 4 | 20 | B | UV-2 | 5.5 | L-1/L-2 | AA | Inventive |
| 5 | 5 | B | UV-3 | 5.5 | L-1/L-2 | A | Inventive |
| 6 | 5 | B | UV-4 | 1.8 | L-1/L-2 | B | Comparative |
| 7 | 5 | B | UV-5 | 1.5 | L-1/L-2 | B | Comparative |
| 8 | 5 | B | UV-6 | 1.4 | L-1/L-2 | B | Comparative |
| 9 | 5 | B | UV-7 | 1.3 | L-1/L-2 | B | Comparative |
| 10 | 5 | B | UV-2 | 5.5 | L-3 | A | Inventive |
| 11 | 5 | B | UV-2 | 5.5 | L-4 | A | inventive |
| 12 | 10 | B | UV-2 | 5.5 | L-5/L-6/L-7/L-8 | AA | Inventive |
| 13 | 5 | A | UV-2 | 5.5 | L-1/L-2 | A | Inventive |

The amount of the specific compound in Table 2 represents parts by mass with respect to 100 parts by mass of the acrylic resin which is a pressure sensitive adhesive.

Since the specific compounds of UV-1 to UV-3 used in the present invention could be used at high concentrations, the laminate according to the embodiment of the present invention had excellent light resistance even in a case where the thickness of the pressure sensitive adhesive layer was less than 20 μm. In a case where the thickness of the pressure sensitive adhesive layer was 20 μm (laminate 4), a laminate having particularly excellent light resistance could be provided.

The haze was evaluated for the laminates 1 to 5 and 10 to 13 according to the embodiment of the present invention, and the results showed a haze of 0.5% or less in each case, which was not a problem.

### Preparation Example 14

(Preparation of Positive C-Plate C1)

The transparent resin film 1 was used as a temporary support.

After passing the transparent resin film 1 through a dielectric heating roll at a temperature of 60° C. to raise the film surface temperature to 40° C., an alkaline solution having the composition shown below was coated on one side of the film using a bar coater at a coating amount of 14 ml/m², followed by heating to 110° C., and transportation under a steam type far-infrared heater manufactured by Noritake Company Limited for 10 seconds.

Next, pure water was coated on the film at 3 ml/m² using the same bar coater.

Next, after repeating washing with water with a fountain coater and draining with an air knife three times, the film was transported to a drying zone at 70° C. for 10 seconds and dried to prepare a transparent resin film 1 subjected to an alkali saponification treatment.

Alkaline solution

| | | |
|---|---|---|
| Potassium hydroxide | 4.7 | parts by mass |
| Water | 15.8 | parts by mass |
| Isopropanol | 63.7 | parts by mass |
| Fluorine-based surfactant SF-1 | 1.0 | parts by mass |
| (C₁₄H₂₉O(CH₂CH₂₀)₂₀H) | | |
| Propylene glycol | 14.8 | parts by mass |

A coating liquid 2 for forming an alignment layer having the following composition was continuously coated on the transparent resin film 1 which had been subjected to an alkali saponification treatment, using a wire bar of #8. The obtained film was dried with hot air at 60° C. for 60 seconds and further with hot air at 100° C. for 120 seconds to form an alignment layer.

Coating liquid 2 for forming an alignment layer

| | | |
|---|---|---|
| Polyvinyl alcohol (PVA103, | 2.4 | parts by mass |
| manufactured by Kuraray Co., Ltd.) | | |
| Isopropyl alcohol | 1.6 | parts by mass |
| Methanol | 36 | parts by mass |
| Water | 60 | parts by mass |

A coating liquid C1 for forming a positive C-plate, which will be described later, was coated on the alignment layer. The obtained coating film was aged at 60° C. for 60 seconds, and then irradiated with ultraviolet rays of 1,000 mJ/cm² using an air-cooled metal halide lamp (manufactured by Eye Graphics Co., Ltd.) of 70 mW/cm² under air to immobilize an alignment state thereof to bring the liquid crystal compound into vertical alignment to prepare an optical film 1 containing a positive C-plate C1 having a thickness of 0.5 μm.

The Rth (550) of the obtained positive C-plate was −60 nm.

Coating liquid C1 for forming a positive C-plate

| | | |
|---|---|---|
| Liquid crystal compound L-11 shown below | 80 | parts by mass |
| Liquid crystal compound L-12 shown below | 20 | parts by mass |
| Liquid crystal compound vertical alignment agent | 1 | part by mass |
| (S01) shown below | | |
| Ethylene oxide-modified trimethylolpropane | 8 | parts by mass |
| triacrylate (V# 360, manufactured by Osaka | | |
| Organic Chemical Industry Ltd.) | | |
| IRGACURE 907 (manufactured by BASF SE) | 3 | parts by mass |
| KAYACURE DETX (manufactured by Nippon | 1 | part by mass |
| Kayaku Co., Ltd.) | | |
| Compound B03 shown below | 0.4 | parts by mass |
| Methyl ethyl ketone | 170 | parts by mass |
| Cyclohexanone | 30 | parts by mass |

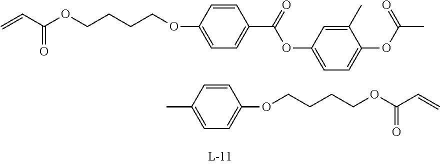

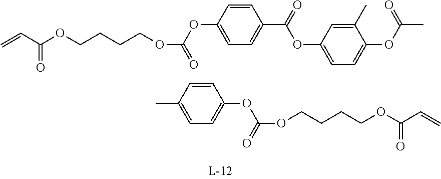

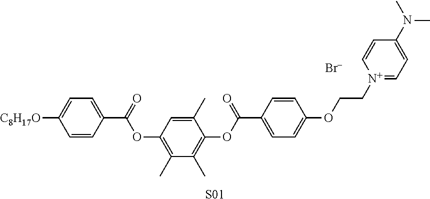

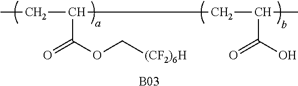

The above a and b represent the content (% by mass) of each repeating unit with respect to all the repeating units, a represents 90% by mass, and b represents 10% by mass.

(Preparation of UV Adhesive)

The following UV adhesive was prepared.

UV adhesive

| | | |
|---|---|---|
| CEL2021P (manufactured by Daicel | 70 | parts by mass |
| Corporation) | | |
| 1,4-Butanediol diglycidyl ether | 20 | parts by mass |
| 2-Ethylhexyl glycidyl ether | 10 | parts by mass |
| CPI-100P | 2.25 | parts by mass |

CPI-100P

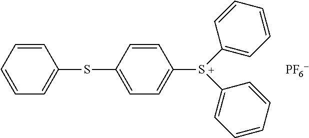

(Preparation of Retardation Plate 1)

The optically anisotropic layer side of the optically anisotropic film 1 and the positive C-plate C1 side of the optical film 1 were bonded to each other by UV light irradiation of 600 md/cm² using the UV adhesive. Hereinafter, the UV adhesive was used under the same conditions. The thickness of the IV adhesive layer was 1 μm. The surfaces to be bonded with the UV adhesive were each subjected to a corona treatment (the same applies hereinafter). Next, the photoalignment layer 1 on the optically anisotropic film 1 side and the transparent resin film 1 were removed to obtain a retardation plate 1.

(Preparation of Polarizing Film 1 Using Dichroic Coloring Agent)

A composition E1 for forming a photoalignment layer was prepared with the following composition, dissolved for 1 hour with stirring, and filtered through a 0.45 μm filter.

Composition E1 for forming a photoalignment layer

| | | |
|---|---|---|
| Photoactive compound E-4 shown below | 5.0 | parts by mass |
| Cyclopentanone | 95.0 | parts by mass |

Photoactive compound E-4 (weight-average molecular weight: 51,000)

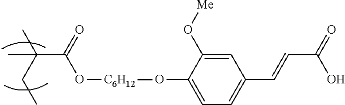

A composition P1 for forming a light absorption anisotropic layer was prepared with the following composition, dissolved by heating at 80° C. for 2 hours with stirring, and filtered through a 0.45 μm filter.

Composition P1 for forming a light absorption anisotropic layer

| | | |
|---|---|---|
| Dichroic coloring agent D1 shown below | 2.7 | parts by mass |
| Dichroic coloring agent D2 shown below | 2.7 | parts by mass |
| Dichroic coloring agent D3 shown below | 2.7 | parts by mass |
| Liquid crystal compound M1 shown below | 100.0 | parts by mass |
| Polymerization initiator IRGACURE 369 | 3.0 | parts by mass |
| (manufactured by BASF SE) | | |
| BYK361N (manufactured by BYK-Chemie | 0.9 | parts by mass |
| Japan KK) | | |
| Cyclopentanone | 925.0 | parts by mass |

Dichroic coloring agent D1 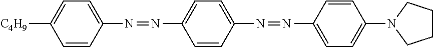
Dichroic coloring agent D2 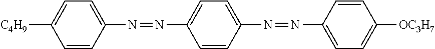
Dichroic coloring agent D3 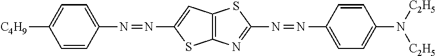
Liquid crystal compound M1 (mixture of compound A/compound B = 75/25)
(Compound A) 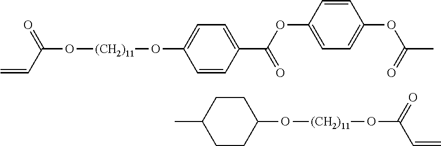
(Compound B)

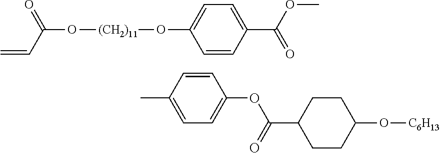

The composition E1 for forming a photoalignment layer was coated on the transparent resin film 1 and dried at 60° C. for 2 minutes. Then, the obtained coating film was irradiated with linearly polarized ultraviolet rays (illuminance: 4.5 mW, irradiation amount: 500 mJ/cm²) using a polarized ultraviolet exposure device to prepare a photoalignment layer E1.

The composition P1 for forming a light absorption anisotropic layer was coated on the obtained photoalignment layer E1 with a wire bar. Next, the obtained coating film was heated at 120° C. for 60 seconds and cooled to room temperature.

Then, a light absorption anisotropic layer P1 having a thickness of 1.7 μm was formed by irradiating with a high-pressure mercury lamp for 60 seconds under an irradiation condition of an illuminance of 28 mW/cm².

It was confirmed that the liquid crystal of the light absorption anisotropic layer was a smectic B phase.

(Formation of Protective Layer)

A solution (composition for forming a protective layer), which was prepared by dissolving dipentaerythritol hexaacrylate (ARONIX M-403, manufactured by Toagosei Co., Ltd.) (50 parts by mass), an acrylate resin (EBECRYL 4858, manufactured by Daicel-UCB Co., Ltd.) (50 parts by mass), and 2-[4-(methylthio)benzoyl]-2-(4-morpholinyl)propane (IRGACURE 907, manufactured by BASF SE) (3 parts by mass) in isopropanol (250 parts by mass), was coated on the formed light absorption anisotropic layer P1 by a bar coating method, and heated and dried in a drying oven at 50° C. for 1 minute.

The obtained coating film was irradiated with ultraviolet rays using an ultraviolet (UV) irradiation device (SPOT CURE SP-7, manufactured by Ushio Inc.) at an exposure amount of 400 mJ/cm² (365 nm standard) to form a protective layer on the light absorption anisotropic layer P1 to prepare a polarizing film 1 containing the light absorption anisotropic layer P1.

(Preparation of Laminate of Preparation Example 14)

The protective layer side of the polarizing film 1 was bonded to the support side of a low-reflection surface film CV-LC5 (manufactured by FUJIFILM Corporation) using the pressure-sensitive adhesive sheet 7. Next, the transparent resin film 1 of the polarizing film 1 and the photoalignment layer E1 were removed, and the removed surface and the positive A-plate A1 side of the retardation plate 1 were bonded to each other using the pressure-sensitive adhesive sheet 7 to prepare a laminate 14 having the low-reflection surface film CV-LC5, the pressure-sensitive adhesive sheet 7, the protective layer, the light absorption anisotropic layer P1, the pressure-sensitive adhesive sheet 7, the positive A-plate A1, and the positive C-plate C1 in this order. At this time, the bonding was carried out such that the angle formed by the absorption axis of the light absorption anisotropic layer and the slow axis of the positive A-plate A1 was 45°.

### Preparation Example 15

The protective layer side of the polarizing film 1 was bonded to the support side of a low-reflection surface film CV-LC5 (manufactured by FUJIFILM Corporation) using the pressure-sensitive adhesive sheet 17. Next, the transparent resin film 1 of the polarizing film 1 and the photoalignment layer E1 were removed, and the removed surface and the positive A-plate A1 side of the retardation plate 1 were bonded to each other using the pressure-sensitive adhesive sheet 7 to prepare a laminate 15 having the low-reflection surface film CV-LC5, the pressure-sensitive adhesive sheet 17, the protective layer, the light absorption anisotropic layer P1, the pressure-sensitive adhesive sheet 7, the positive A-plate A1, and the positive C-plate C1 in this order. At this time, the bonding was carried out such that the angle formed by the absorption axis of the light absorption anisotropic layer and the slow axis of the positive A-plate A1 was 45°.

### Preparation Example 16

A coating liquid PA1 for forming an alignment layer, which will be described later, was continuously coated on the transparent resin film 1 with a wire bar. The support on which the coating film was formed was dried with hot air at 140° C. for 120 seconds, and then the coating film was irradiated with polarized ultraviolet rays (10 mJ/cm², using an ultra-high pressure mercury lamp) to form a photoalignment layer PA1, thereby obtaining a TAC film with the photoalignment layer PA1.

The film thickness of the photoalignment layer PA1 was 1.0 μm.

Coating liquid PA1 for forming an alignment layer

| | | |
|---|---|---|
| Polymer PA-1 shown below | 100.00 | parts by mass |
| Acid generator PAG-1 shown below | 5.00 | parts by mass |
| Acid generator CPI-110TF shown below | 0.005 | parts by mass |
| Xylene | 1220.00 | parts by mass |
| Methyl isobutyl ketone | 122.00 | parts by mass |

Polymer PA-1

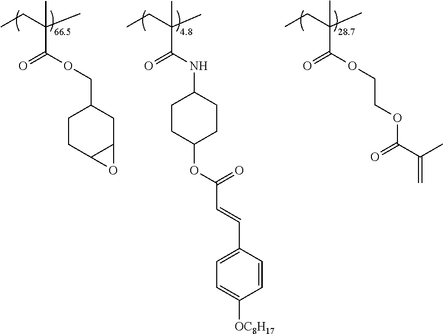

In the above formulae, the numerical value in each repeating unit represents the content (% by mass) with respect to all the repeating units, the content of the repeating unit on the left side is 66.5% by mass, the content of the repeating unit in the middle is 4.8% by mass, and the content of the repeating unit on the right side is 28.7% by mass.

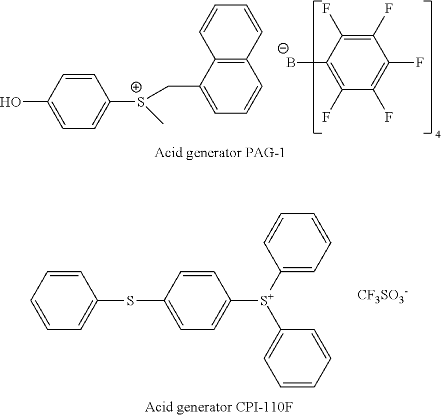

The following composition P2 for forming a light absorption anisotropic layer was continuously coated on the obtained photoalignment layer PA1 with a wire bar to form a coating film P2.

Next, the coating film P2 was heated at 140° C. for 30 seconds, and then the coating film P2 was cooled to room temperature (23° C.).

Next, the obtained coating film P2 was heated at 90° C. for 60 seconds and cooled again to room temperature.

Then, a light absorption anisotropic layer P2 was prepared on the photoalignment layer PA1 by irradiating with a light emitting diode (LED) lamp (central wavelength: 365 nm) for 2 seconds under an irradiation condition of an illuminance of 200 mW/cm².

The film thickness of the light absorption anisotropic layer P2 was 0.4 μm.

Composition P2 for forming a light absorption anisotropic layer

| | | |
|---|---|---|
| Dichroic coloring agent D-4 shown below | 0.36 | parts by mass |
| Dichroic coloring agent D-5 shown below | 0.53 | parts by mass |
| Dichroic coloring agent D-6 shown below | 0.31 | parts by mass |
| High molecular weight liquid crystal compound | 3.58 | parts by mass |
| P-1 shown below | | |
| Polymerization initiator IRGACURE OXE-02 | 0.050 | parts by mass |
| (manufactured by BASF SE) | | |
| Surfactant F-1 shown below | 0.026 | parts by mass |
| Cyclopentanone | 45.00 | parts by mass |
| Tetrahydrofuran | 45.00 | parts by mass |
| Benzyl alcohol | 5.00 | parts by mass |

Dichroic coloring agent D-4 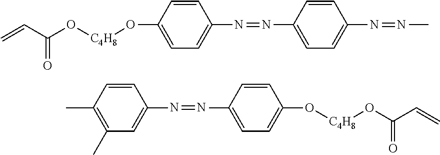
Dichroic coloring agent D-5 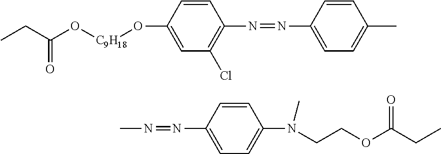
Dichroic coloring agent D-6 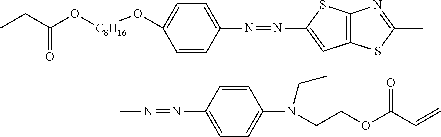
High molecular weight liquid crystal compound P-1

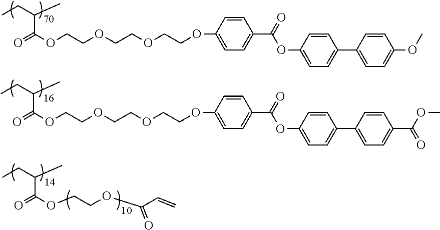

In the above formulae, the numerical value in each repeating unit represents the content (% by mass) with respect to all the repeating units, the content of the top repeating unit is 70% by mass, the content of the middle repeating unit is 16% by mass, and the content of the bottom repeating unit is 14% by mass.

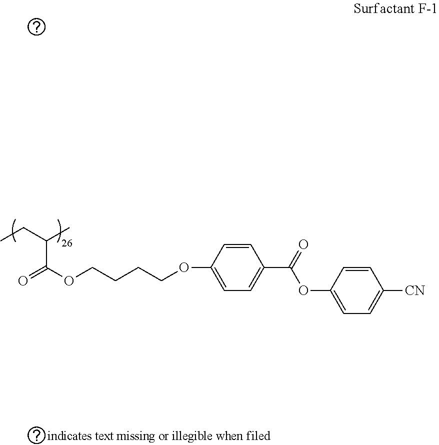

In the above formulae, the numerical value in each repeating unit represents the content (% by mass) with respect to all the repeating units, the content of the repeating unit on the left side is 74% by mass, and the content of the repeating unit on the right side is 26% by mass.

The following composition N1 for forming a cured layer was continuously coated on the obtained light absorption anisotropic layer P2 with a wire bar to form a coating film.

Next, the coating film was dried at room temperature, and then irradiated for 15 seconds under an irradiation condition of an illuminance of 28 mW/cm² using a high-pressure mercury lamp to prepare a cured layer N1 on the light absorption anisotropic layer P2.

The film thickness of the cured layer N1 was 0.05 μm.

Composition N1 for forming a cured layer

| | | |
|---|---|---|
| Mixture L1 of rod-like liquid | 2.61 | parts by mass |
| crystal compounds shown below | | |
| Modified trimethylolpropane | 0.11 | parts by mass |
| triacrylate shown below | | |
| Photopolymerization initiator | 0.05 | parts by mass |
| I-1 shown below | | |
| Surfactant F-3 shown below | 0.21 | parts by mass |
| Methyl isobutyl ketone | 297 | parts by mass |

Mixture L1 of rod-like liquid crystal compounds (The numerical value in the following formulae represents % by mass, and R represents a group bonded through an oxygen atom.)

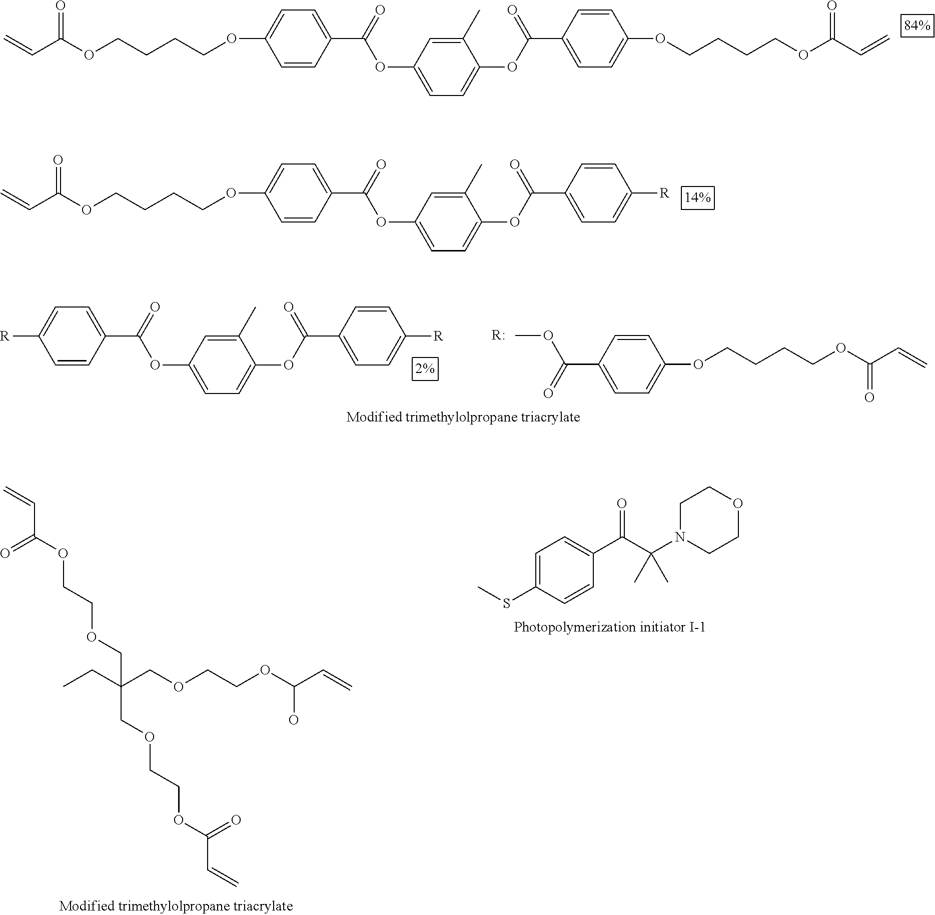

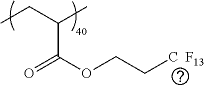

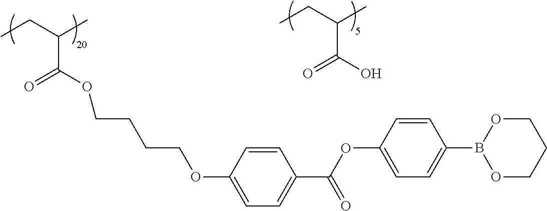

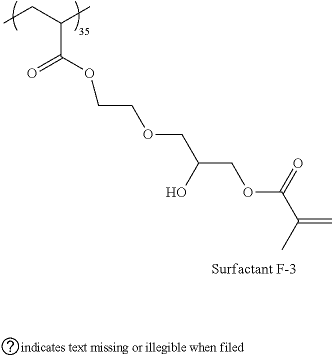

In the above formulae, the numerical value in each repeating unit represents the content (% by mass) with respect to all the repeating units, and the content of each repeating unit is 40% by mass, 20% by mass, 5% by mass, and 35% by mass from the left side.

The following composition B1 for forming an oxygen blocking layer was continuously coated on the cured layer N1 with a wire bar. This was followed by drying with hot air at 100° C. for 2 minutes to prepare a polarizing film 2 having an oxygen blocking layer having a thickness of 1.0 μm formed on the cured layer N1.

Composition B1 for forming an oxygen blocking layer

| | | |
|---|---|---|
| Modified polyvinyl alcohol shown below | 3.80 | parts by mass |
| Initiator Irg2959 | 0.20 | parts by mass |
| Water | 70 | parts by mass |
| Methanol | 30 | parts by mass |

Modified polyvinyl alcohol

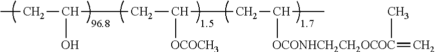

The oxygen blocking layer side of the polarizing film 2 was bonded to the support side of a low-reflection surface film CV-LC5 (manufactured by FUJIFILM Corporation) using the pressure-sensitive adhesive sheet 7. Next, only the transparent resin film 1 of the polarizing film 2 was removed, and the removed surface and the positive A-plate A1 side of the retardation plate 1 were bonded to each other using the pressure-sensitive adhesive sheet 7 to prepare a laminate 16 having the low-reflection surface film CV-LC5, the pressure-sensitive adhesive sheet 7, the oxygen blocking layer, the cured layer N1, the light absorption anisotropic layer P2, the photoalignment layer PA1, the pressure-sensitive adhesive sheet 7, the positive A-plate A1, and the positive C-plate C1 in this order. At this time, the bonding was carried out such that the angle formed by the absorption axis of the light absorption anisotropic layer and the slow axis of the positive A-plate A1 was 45°.

### Preparation Example 17

The oxygen blocking layer side of the polarizing film 2 was bonded to the support side of a low-reflection surface film CV-LC5 (manufactured by FUJIFILM Corporation) using the pressure-sensitive adhesive sheet 17. Next, only the transparent resin film 1 of the polarizing film 2 was removed, and the removed surface and the positive A-plate A1 side of the retardation plate 1 were bonded to each other using the pressure-sensitive adhesive sheet 7 to prepare a laminate 17 having the low-reflection surface film CV-LC5, the pressure-sensitive adhesive sheet 17, the oxygen blocking layer, the cured layer N1, the light absorption anisotropic layer P2, the photoalignment layer PA1, the pressure-sensitive adhesive sheet 7, the positive A-plate A1, and the positive C-plate C1 in this order. At this time, the bonding was carried out such that the angle formed by the absorption axis of the light absorption anisotropic layer and the slow axis of the positive A-plate A1 was 45°.

<Evaluation>

(Preparation of Organic EL Display Device)

The SAMSUNG GALAXY S4 equipped with an organic EL display panel (organic EL display element) was disassembled, a touch panel with a circularly polarizing plate was peeled off from the organic EL display device, and the circularly polarizing plate was further peeled off from the touch panel to isolate the organic EL display element, the touch panel, and the circularly polarizing plate, respectively. Next, the isolated touch panel was bonded again to the organic EL display element, and each of the laminates of Preparation Examples 14 to 17 was further bonded to the touch panel using the pressure-sensitive adhesive sheet N1 prepared by the following procedure, whereby organic EL display devices 14 to 17 were prepared.

At this time, the optically anisotropic layer was arranged closer to the organic EL display panel than the light absorption anisotropic layer.

(Preparation of Pressure-Sensitive Adhesive Sheet N1)

Next, an acrylate-based polymer was prepared according to the following procedure.

Butyl acrylate (95 parts by mass) and acrylic acid (5 parts by mass) were polymerized by a solution polymerization method in a reaction container equipped with a cooling pipe, a nitrogen introduction pipe, a thermometer, and a stirrer to obtain an acrylate-based polymer (A1) having an average molecular weight of 2,000,000 and a molecular weight distribution (Mw/Mn) of 3.0.

Next, the obtained acrylate-based polymer (A1) (100 parts by mass), an isocyanate-based crosslinking agent (1 part by mass) shown below, and a silane coupling agent (0.2 parts by mass) were mixed to prepare a composition. This composition was coated on a separate film surface-treated with a silicone-based release agent using a die coater, and the obtained coating film was dried in an environment of 90° C. for 1 minute to obtain a pressure-sensitive adhesive sheet N1. The film thickness of the pressure-sensitive adhesive sheet N1 was 25 μm.

Isocyanate-based crosslinking agent: trimethylolpropane-modified tolylene diisocyanate

(“CORONATE L” manufactured by Nippon Polyurethane Industry Co., Ltd.)

Silane coupling agent: 3-glycidoxypropyltrimethoxysilane (“KBM-403” manufactured by Shin-Etsu Chemical Co., Ltd.)

(Evaluation of reflectivity)

In order to exclude the influence of surface reflection, the value measured by pasting a black glue (containing carbon black) having a high absorbance and not reflecting at all on the support side of a low-reflection surface film CV-LC5 (manufactured by FUJIFILM Corporation) was taken as the surface reflectivity.

The reflectivity (total reflection) of the organic EL display devices 14 to 17 was measured, and the value obtained by subtracting the surface reflectivity therefrom was taken as the effective reflectivity. This effective reflectivity serves as an indicator of an antireflection function of a circularly polarizing plate consisting of the light absorption anisotropic layer and the optically anisotropic layer.

For the total reflectivity, using a spectrophotometric colorimeter (manufactured by Konica Minolta, Inc.), the Y value of a display system under an observation condition of visual field of 10° and an observation light source of D65 was taken as the total reflectivity.

(Evaluation of Photodurability)

Using a Super Xenon Weather Meter SX75 (manufactured by Suga Test Instruments Co., Ltd.), and in an environment of 60° C. and 50% RH, xenon irradiation for 150 hours at 150 W/m² was carried out on the laminates 14 to 17 from the low-reflection surface film side. Then, the effective reflectivity was evaluated in the same manner as above and the difference in effective reflectivity before and after xenon irradiation was evaluated according to the following standards.

A: The reflectivity difference is 0.2% or less

B: The reflectivity difference is greater than 0.2% and 0.5% or less

C: The reflectivity difference is greater than 0.5%

The amount of the specific compound in Table 3 represents parts by mass with respect to 100 parts by mass of the acrylic resin of the pressure sensitive adhesive layer.

TABLE 3

| | First pressure | | | Light | Second pressure | | | Optically | |
|---|---|---|---|---|---|---|---|---|---|
| | sensitive adhesive | | | absorption | sensitive adhesive | | | anisotropic | |
| | layer | | | anisotropic | layer | | | layer | |
| | Thickness | Specific compound | | layer | Thickness | Specific compound | | Liquid | Photodurability |
| Laminate | (μm) | Designation | Amount | Designation | (μm) | Designation | Amount | crystal | evaluation |
| 14 | 5 | UV-2 | 5.5 | P1 | 5 | UV-2 | 5.5 | L-1/L-2 | A |
| 15 | 5 | — | | P1 | 5 | UV-2 | 5.5 | L-1/L-2 | C |
| 16 | 5 | UV-2 | 5.5 | P2 | 5 | UV-2 | 5.5 | L-1/L-2 | A |
| 17 | 5 | — | | P2 | 5 | UV-2 | 5.5 | L-1/L-2 | B |

It was found that the antireflection function of the circularly polarizing plate can be maintained even after xenon irradiation, by arranging the pressure sensitive adhesive layer containing the specific compound used in the present invention on the low-reflection surface film side of the light absorption anisotropic layer, as shown in the laminates 14 and 16. The effect of the pressure sensitive adhesive layer containing the specific compound used in the present invention was more significant on the light absorption anisotropic layer P1 having a low concentration of solid contents of the dichroic coloring agent.

### EXPLANATION OF REFERENCES

100, 200, 300: laminate
1: pressure sensitive adhesive layer
2: optically anisotropic layer
3: polarizer layer
4: pressure sensitive adhesive layer
5: surface protective layer

What is claimed is:

1. A laminate comprising:
a pressure sensitive adhesive layer; and
an optically anisotropic layer,
wherein the pressure sensitive adhesive layer contains a (meth)acrylic pressure sensitive adhesive and a compound represented by Formula (I), and
the optically anisotropic layer is a layer formed of a composition containing a polymerizable liquid crystal compound exhibiting reverse wavelength dispersibility, 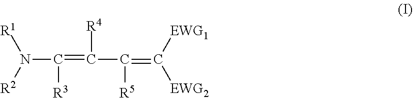
in Formula (I), one of EWG₁ and EWG₂ represents COOR⁶, the other of EWG₁ and EWG₂ represents SO₂R⁷, R⁶ represents an alkyl group, an aryl group, or a heteroaryl group, R⁷ represents an aryl group or a heteroaryl group, R¹ and R² each independently represent an alkyl group, an aryl group, or a heteroaryl group, and R³, R⁴, and R⁵ each independently represent a hydrogen atom or a substituent.

2. The laminate according to claim 1,
wherein the polymerizable liquid crystal compound includes a polymerizable liquid crystal compound having a partial structure represented by Formula (II),
*-D₁-Ar-D₂-* (II)
in Formula (II),
D₁ and D₂ each independently represent a single bond, —O—, —CO—, —CO—O—, —C(═S)O—, —CR¹R²—, —CR¹R²—CR³R—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R—, —CR¹R²—CO—O—CR³R⁴—, —NR¹—CR²R³—, or —CO—NR¹—,
R¹, R², R³, and R⁴ each independently represent a hydrogen atom, a fluorine atom, or an alkyl group having 1 to 4 carbon atoms, and in a case where there are a plurality of each of R¹'s, R²'s, R³'s, and R⁴'s, the plurality of R¹'s, the plurality of R²'s, the plurality of R³'s, and the plurality of R⁴'s each may be the same as or different from each other, and
Ar represents any aromatic ring selected from the group consisting of groups represented by Formulae (Ar-1) to (Ar-7), 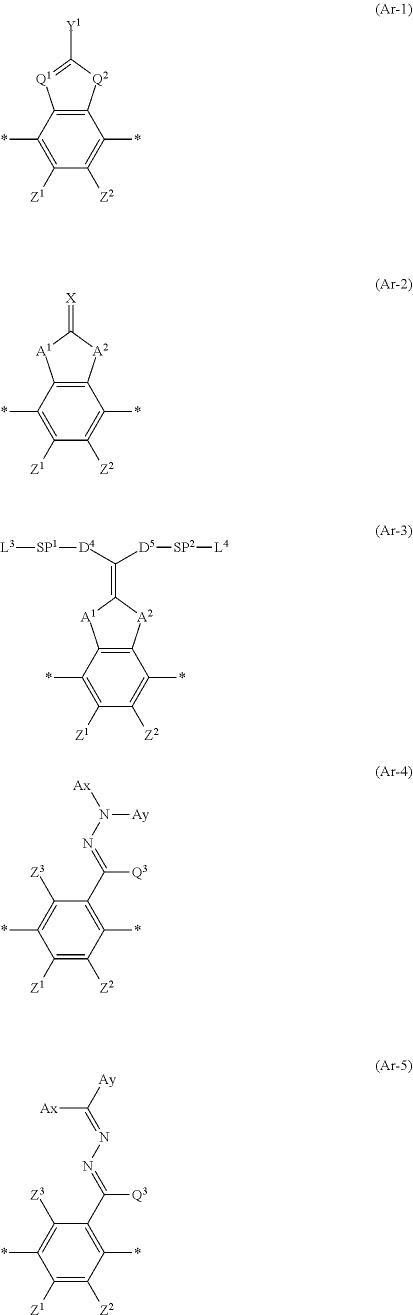 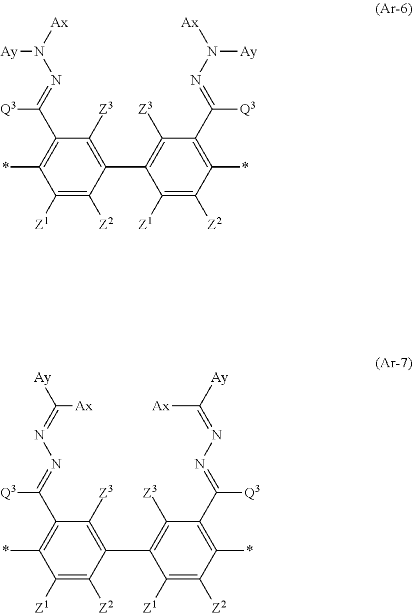
Q¹ represents N or CH,
Q² represents —S—, —O—, or —N(R⁷)—, and R⁷ represents a hydrogen atom or an alkyl group having 1 to 6 carbon atoms,
Y¹ represents an aromatic hydrocarbon group having 6 to 12 carbon atoms or an aromatic heterocyclic group having 3 to 12 carbon atoms, which may have a substituent,
Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —OR⁸, —NR⁹R¹⁰, or —SR¹¹, R⁸ to R¹¹ each independently represent a hydrogen atom or an alkyl group having 1 to 6 carbon atoms, and Z¹ and Z² may be bonded to each other to form an aromatic ring,
A¹ and A² each independently represent a group selected from the group consisting of —O—, —N(R¹²)—, —S—, and —CO—, and R¹² represents a hydrogen atom or a substituent,
X represents a non-metal atom of Groups 14 to 16 to which a hydrogen atom or a substituent may be bonded,
D⁴ and D⁵ each independently represent a single bond or —CO—, —O—, —S—, —C(═S)—, —CR^{1a}R^{2a}—, —CR^{3a}═CR^{4a}—, —NR^{5a}—, or a divalent linking group consisting of two or more combinations of these groups, and R^{1a} to R^{5a} each independently represent a hydrogen atom, a fluorine atom, or an alkyl group having 1 to 4 carbon atoms,
SP¹ and SP² each independently represent a single bond, a linear or branched alkylene group having 1 to 12 carbon atoms, or a divalent linking group in which one or more of —CH₂— constituting a linear or branched alkylene group having 1 to 12 carbon atoms are substituted with —O—, —S—, —NH—, —N(Q)-, or —CO—, and Q represents a substituent,
L³ and L⁴ each independently represent a monovalent organic group,
Ax represents an organic group having 2 to 30 carbon atoms which has at least one aromatic ring selected from the group consisting of an aromatic hydrocarbon ring and an aromatic heterocyclic ring,
Ay represents a hydrogen atom, an alkyl group having 1 to 12 carbon atoms which may have a substituent, or an organic group having 2 to 30 carbon atoms which has at least one aromatic ring selected from the group consisting of an aromatic hydrocarbon ring and an aromatic heterocyclic ring,
the aromatic rings in Ax and Ay may have a substituent, and Ax and Ay may be bonded to each other to form a ring,
Q³ represents a hydrogen atom or an alkyl group having 1 to 6 carbon atoms which may have a substituent, and
* represents a bonding position.

3. The laminate according to claim 1,
wherein a content of the compound represented by Formula (I) is 2.5% to 30% by mass with respect to a total mass of the (meth)acrylic pressure sensitive adhesive.

4. The laminate according to claim 1,
wherein a content of the compound represented by Formula (I) is 5.3% to 30% by mass with respect to a total mass of the (meth)acrylic pressure sensitive adhesive.

5. The laminate according to claim 1,
wherein the (meth)acrylic pressure sensitive adhesive is obtained by reacting a copolymer having a repeating unit derived from a (meth)acrylic acid ester monomer represented by Formula (A-1) and a repeating unit derived from an unsaturated monomer having a polar functional group with a crosslinking agent having a functional group capable of reacting with the polar functional group,
a content of the repeating unit derived from the (meth)acrylic acid ester monomer represented by Formula (A-1) is 50% to 99.9% by mass with respect to all the repeating units of the copolymer,
a content of the repeating unit derived from the unsaturated monomer having a polar functional group is 0.1% to 50% by mass with respect to all the repeating units of the copolymer,
a weight-average molecular weight of the copolymer is 500,000 to 2,000,000, and
a content of the crosslinking agent with respect to 100 parts by mass of the copolymer is 0.01 to 10 parts by mass, 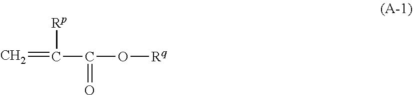
in Formula (A-1), R^{p} represents a hydrogen atom or a methyl group, R^{q} represents an alkyl group having 1 to 20 carbon atoms or an aralkyl group having 1 to 20 carbon atoms, a hydrogen atom constituting the alkyl group and the aralkyl group may be substituted with —O—(C₂H₄O)ₙ—R^{r}, n represents an integer of 0 to 4, and R^{r} represents an alkyl group having 1 to 12 carbon atoms or an aryl group having 1 to 12 carbon atoms.

6. The laminate according to claim 1,
wherein a thickness of the pressure sensitive adhesive layer is less than 20 μm.

7. The laminate according to claim 1,
wherein a thickness of the pressure sensitive adhesive layer is less than 10 μm.

8. The laminate according to claim 1,
wherein a thickness of the pressure sensitive adhesive layer is 5 μm or less.

9. The laminate according to claim 1, further comprising a polarizer layer.

10. The laminate according to claim 9,
wherein the laminate has the polarizer layer, the pressure sensitive adhesive layer, and the optically anisotropic layer in this order.

11. The laminate according to claim 9,
wherein the polarizer layer is a polarizer layer having a dichroic coloring agent.

12. The laminate according to claim 9,
wherein the laminate has a first pressure sensitive adhesive layer, the polarizer layer, a second pressure sensitive adhesive layer, and the optically anisotropic layer in this order, and
at least one of the first pressure sensitive adhesive layer or the second pressure sensitive adhesive layer is the pressure sensitive adhesive layer.

13. A display device comprising the laminate according to claim 1.

14. An organic electroluminescent display device comprising the laminate according to claim 1.

15. The laminate according to claim 2,
wherein a content of the compound represented by Formula (I) is 2.5% to 30% by mass with respect to a total mass of the (meth)acrylic pressure sensitive adhesive.

16. The laminate according to claim 2,
wherein a content of the compound represented by Formula (I) is 5.3% to 30% by mass with respect to a total mass of the (meth)acrylic pressure sensitive adhesive.

17. The laminate according to claim 2,
wherein the (meth)acrylic pressure sensitive adhesive is obtained by reacting a copolymer having a repeating unit derived from a (meth)acrylic acid ester monomer represented by Formula (A-1) and a repeating unit derived from an unsaturated monomer having a polar functional group with a crosslinking agent having a functional group capable of reacting with the polar functional group,
a content of the repeating unit derived from the (meth)acrylic acid ester monomer represented by Formula (A-1) is 50% to 99.9% by mass with respect to all the repeating units of the copolymer,
a content of the repeating unit derived from the unsaturated monomer having a polar functional group is 0.1% to 50% by mass with respect to all the repeating units of the copolymer,
a weight-average molecular weight of the copolymer is 500,000 to 2,000,000, and
a content of the crosslinking agent with respect to 100 parts by mass of the copolymer is 0.01 to 10 parts by mass, 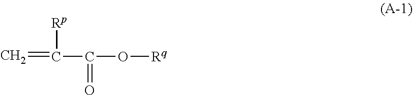
in Formula (A-1), R^{p} represents a hydrogen atom or a methyl group, R^{q} represents an alkyl group having 1 to 20 carbon atoms or an aralkyl group having 1 to 20 carbon atoms, a hydrogen atom constituting the alkyl group and the aralkyl group may be substituted with —O—(C₂H₄O)ₙ—R^{r}, n represents an integer of 0 to 4, and R^{r} represents an alkyl group having 1 to 12 carbon atoms or an aryl group having 1 to 12 carbon atoms.

18. The laminate according to claim 2,
wherein a thickness of the pressure sensitive adhesive layer is less than 20 μm.

19. The laminate according to claim 2,
wherein a thickness of the pressure sensitive adhesive layer is less than 10 μm.

20. The laminate according to claim 3,
wherein the (meth)acrylic pressure sensitive adhesive is obtained by reacting a copolymer having a repeating unit derived from a (meth)acrylic acid ester monomer represented by Formula (A-1) and a repeating unit derived from an unsaturated monomer having a polar functional group with a crosslinking agent having a functional group capable of reacting with the polar functional group,
a content of the repeating unit derived from the (meth)acrylic acid ester monomer represented by Formula (A-1) is 50% to 99.9% by mass with respect to all the repeating units of the copolymer,
a content of the repeating unit derived from the unsaturated monomer having a polar functional group is 0.1% to 50/a by mass with respect to all the repeating units of the copolymer,
a weight-average molecular weight of the copolymer is 500,000 to 2,000,000, and
a content of the crosslinking agent with respect to 100 parts by mass of the copolymer is 0.01 to 10 parts by mass, 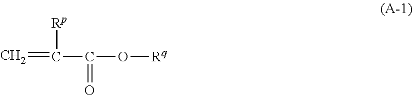
in Formula (A-1), R^{p} represents a hydrogen atom or a methyl group, R^{q} represents an alkyl group having 1 to 20 carbon atoms or an aralkyl group having 1 to 20 carbon atoms, a hydrogen atom constituting the alkyl group and the aralkyl group may be substituted with —O—(C₂H₄O)ₙ—R^{r}, n represents an integer of 0 to 4, and R^{r} represents an alkyl group having 1 to 12 carbon atoms or an aryl group having 1 to 12 carbon atoms.
